(19) United States
(12) Patent Application Publication
(10) Pub. No.: US 2023/0250112 A1
(43) Pub. Date: Aug. 10, 2023

(54) ORGANIC COMPOUNDS AND APPLICATIONS THEREOF IN OPTOELECTRONIC FIELD

(71) Applicant: Zhejiang Brilliant Optoelectronic Technology Co.,Ltd., Taizhou (CN)

(72) Inventors: Junyou PAN, Taizhou (CN); Xiang CHEN, Taizhou (CN); Hong HUANG, Taizhou (CN)

(73) Assignee: Zhejiang Brilliant Optoelectronic Technology Co.,Ltd., Taizhou (CN)

(21) Appl. No.: 18/300,760

(22) Filed: Apr. 14, 2023

Related U.S. Application Data
(63) Continuation of application No. PCT/CN2021/123757, filed on Oct. 14, 2021.

(30) Foreign Application Priority Data
Oct. 14, 2020 (CN) 202011099557.7
Apr. 7, 2021 (CN) 202110370910.9

(51) Int. Cl. C07F 5/02; H10K 85/60

(52) U.S. Cl. CPC C07F 5/027; H10K 85/658

(57) ABSTRACT

Disclosed are organic compounds, including at least one structural unit of formula (1) or (2), and containing a cross-linkable group are disclosed. Also provided are formulations and organic functional material films containing these organic compounds. Further provided are optoelectronic device that utilize these organic compounds or organic functional material films.

### CROSS-REFERENCE TO RELATED APPLICATIONS

This application is a continuation of International Application No. PCT/CN2021/123757, filed on Oct. 14, 2021, which claims priority to Chinese Patent Application No. CN202110370910.9, filed on Apr. 7, 2021 and Chinese Patent Application No. CN202011099557.7, filed on Oct. 14, 2020. All of the aforementioned applications are incorporated herein by reference in their entireties.

### TECHNICAL FIELD

The present disclosure relates to the field of organic optoelectronic materials and technologies, and in particularly to organic compounds, formulations, and applications thereof in the optoelectronics field.

### BACKGROUND

According to the principles of colorimetry, the narrower the full width at half maximum (FWHM) of the lights perceived by human eyes is, the higher the color purity, and thus the more vivid the color display would be. Display devices with narrow-FWHM red, green and blue primary light are able to show vivid views with high color gamut and high visual quality.

The current mainstream full-color displays are mainly realized in two ways. The first method is to actively emit red, green and blue lights, typically such as RGB-OLED display. The current mature technology fabricating light-emitting devices with three colors is by vacuum evaporation with fine metal masks, which is complex, high cost and difficult to achieve high-resolution display over 600 ppi. The second method is using color converters to convert the single-color light from the light-emitting devices into different colors, thereby achieving a full-color display. For example, Samsung combines blue OLEDs with red and green quantum dots (QD) films as the color converters. In this case, the fabrication of the light-emitting devices is much simpler, and thus higher yield. Furthermore, the manufacture of color converters can be achieved by different technologies, such as ink-jet printing, transfer printing and photolithography, etc., applicable to a variety of display products with different resolution requirements from low resolution large-size TV (around only 50 ppi) to high resolution silicon-based micro-display (over 3000 ppi).

Currently, there are mainly two types of color conversion materials used in mainstream color converters. The first one is organic dye, comprising various organic conjugated small molecules with chromophores. Due to the intra-molecular thermal relaxation and the large vibrational energy in organic molecules, this kind of material usually has the large FWHM (typically over 60 nm) of its emission spectrum. The second one is inorganic nanocrystal, commonly known as quantum dot, which is a nanoparticle of inorganic semiconductor material (InP, CdSe, CdS, ZnSe, etc.) with a diameter of 2-8 nm. The small size of this material leads to quantum confinement effects, resulting in photoluminescent emissions with a specific frequency, which is highly dependent on the particle size. In this sense, the color of its emission can be readily tuned by adjusting the size. Limited by the current synthesis and separation technology of quantum dots, the FWHM of Cd-containing quantum dots typically ranges from 25 to 40 nm, which meets the display requirements of NTSC for color purity. Meanwhile, Cd-free quantum dots generally come with larger FWHM of 35 to 75 nm. Since Cd is considered highly hazardous to environment and human health, most countries have prohibited the use of Cd-containing quantum dots to produce electronic products. In addition, because the extinction coefficient of inorganic quantum dots is generally quite low, the rather thick film is required. Typically the film of 10 m or more can achieve complete absorption of blue light, which is a relatively large challenge for mass production processes.

Therefore, new materials still need to be further developed.

### SUMMARY

In one aspect, the present disclosure provides an organic compound having a structural unit of formula (1) or (2),

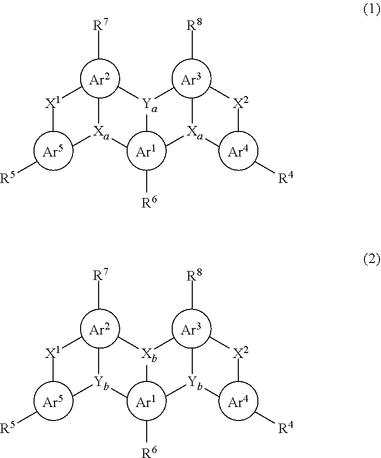

wherein:

each of Ar¹, Ar², Ar³ is independently an aromatic group containing 5 to 24 ring atoms, or a heteroaromatic group containing 5 to 24 ring atoms;

each of Ar⁴ and Ar⁵ is independently null, an aromatic group containing 5 to 24 ring atoms, or a heteroaromatic group containing 5 to 24 ring atoms;

each of Yₐ and Y_{b} is independently B, P═O, C(R⁹), Si(R⁹);

when neither Ar⁴ nor Ar⁵ is null, each of Xₐ and X_{b} is independently N, C(R⁹), or Si(R⁹);

when Ar⁴ and/or Ar⁵ is null, each of the corresponding Xₐ and Y_{b} is independently N(R⁹), C(R⁹R¹⁰), Si(R⁹R¹⁰), C═O, O, C═N(R⁹), C═C(R⁹R¹⁰), P(R⁹), P(═O)R⁹, S, S═O, or SO₂;

each of X¹, X² is independently null or a bridging group;

R⁴ to R¹⁰ are independently selected from the group consisting of —H, -D, —F, —Cl, —Br, —I, —CN, —NO₂, —CF₃, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group or an isothiocyanate group, a hydroxyl group, a nitro group, a trifluoromethyl group, Cl, Br, F, a substituted/unsubstituted aromatic/heteroaromatic group containing 5 to 40 ring atoms, an aryloxy/heteroaryloxy group containing 5 to 40 ring atoms, an arylamine/heteroarylamine group containing 5 to 40 ring atoms, a disubstituted unit in any position of the above substituents and any combination thereof, wherein one or more of the substituent groups can form a monocyclic or polycyclic aliphatic or aromatic ring system with each other and/or with the ring bonded to the groups;

wherein the organic compound comprises at least one cross-linkable group.

In another aspect, the present disclosure also provides a formulation, comprising at least one organic compound as described herein, and at least one organic solvent.

In yet another aspect, the present disclosure further provides an organic functional material film, comprising an organic compound as described herein, or prepared from a formulation as described herein. The preferred organic functional material film is a color conversion film.

In yet another aspect, the present disclosure further provides an optoelectronic device, comprising an organic compound or an organic functional material film as described herein.

Beneficial effects: an organic compound as described herein has a relatively narrow FWHM and a relatively high extinction coefficient. The organic compound as a color conversion material to be used for the realisation of the display device with high color gamut.

### DETAILED DESCRIPTION

The present disclosure provides an organic compound and the applications thereof in the optoelectronic devices. In order to facilitate understanding of the present disclosure, the present disclosure will be described in details below. However, the present disclosure may be implemented in many different forms and is not limited to the embodiments described herein. On the contrary, the purpose of providing these embodiments is to make the understanding of of the present disclosure more thorough and comprehensive.

Unless otherwise defined, all technical and scientific terms used herein have the same meaning as commonly understood by one of ordinary skill in the art belonging to the present disclosure. The terms used herein in the description of the present disclosure are used only for the purpose of describing specific embodiments and are not intended to be limiting of the present disclosure. As used herein, the term “and/or” includes any and all combinations of one or more of the relevant listed items.

As used herein, the terms “host material”, “matrix material” have the same meaning, and they are interchangeable with each other.

As used herein, the terms “formulation”, “printing ink”, and “inks” have the same meaning, and they are interchangeable with each other.

In one aspect, the present disclosure provides an organic compound having a structural unit of formula (1) or (2),

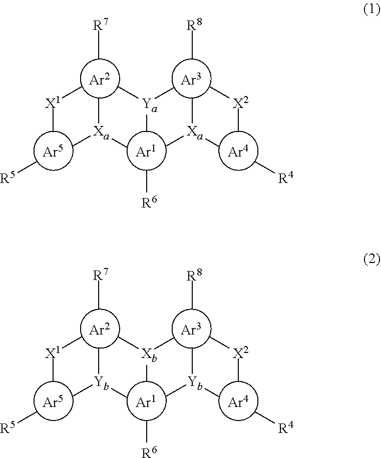

wherein:

each of Ar¹, Ar²′ Ar³ is independently an aromatic group containing 5 to 24 ring atoms, or a heteroaromatic group containing 5 to 24 ring atoms;

each of Ar⁴ and Ar⁵ is independently null, an aromatic group containing 5 to 24 ring atoms, or a heteroaromatic group containing 5 to 24 ring atoms;

each of Yₐ and Y_{b} is independently B, P═O, C(R⁹), Si(R⁹);

when neither Ar⁴ nor Ar⁵ is null, each of Xₐ and X_{b} is independently N, C(R⁹), Si(R⁹);

when Ar⁴ and/or Ar⁵ is null, each of the corresponding Xₐ and Y_{b} is independently N(R⁹), C(R⁹R¹⁰), Si(R⁹R¹⁰), C═O, O, C═N(R⁹), C═C(R⁹R¹⁰), P(R⁹), P(═O)R⁹, S, S═O or SO₂;

each of X¹, X² is independently null or a bridging group;

R⁴ to R¹⁰ are independently selected from the group consisting of —H, -D, —F, —Cl, —Br, —I, —CN, —NO₂, —CF₃, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group or an isothiocyanate group, a hydroxyl group, a nitro group, a trifluoromethyl group, Cl, Br, F, a substituted/unsubstituted aromatic/heteroaromatic group containing 5 to 40 ring atoms, an aryloxy/heteroaryloxy group containing 5 to 40 ring atoms, an arylamine/heteroarylamine group containing 5 to 40 ring atoms, a disubstituted units of the above substituents and any combination thereof, wherein one or more of the substituent groups can form a monocyclic or polycyclic aliphatic or aromatic ring system with each other and/or with the ring bonded to the groups;

wherein the organic compound comprises at least one cross-linkable group.

Preferably, R⁴ to R¹⁰ are each independently selected from the group consisting of —H, -D, a C₁-C₁₀ linear alkyl group, a C₁-C₁₀ linear alkoxy group, a C₁-C₁₀ linear thioalkoxy group, a C₃-C₁₀ branched/cyclic alkyl group, a C₃-C₁₀ branched/cyclic alkoxy group, a C₃-C₁₀ branched/cyclic thioalkoxy group, a C₃-C₁₀ branched/cyclic silyl group, a C₁-C₁₀ ketone group, a C₂-C₁₀ alkoxycarbonyl group, a C₇-C₁₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group or an isothiocyanate group, a hydroxyl group, a nitro group, a trifluoromethyl group, Cl, Br, F, a substituted/unsubstituted aromatic/heteroaromatic group containing 5 to 20 ring atoms, an aryloxy/heteroaryloxy group containing 5 to 20 ring atoms, an arylamine/heteroarylamine group containing 5 to 20 ring atoms, and any combination thereof, wherein one or more of the substituent groups can form a monocyclic or polycyclic aliphatic or aromatic ring system with each other and/or with the ring bonded to the groups.

In some embodiments, the organic compound comprises at least two cross-linkable groups.

In some embodiments, the organic compound comprises at least three cross-linkable groups.

In some embodiments, at least one of X¹ or X² is null; particularly preferably, both are null, in which case the organic compound comprises a structural unit of formula (1b) or (2b):

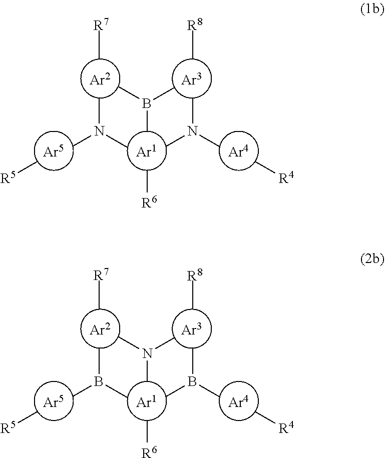

In some embodiments, at least one of X¹ or X² is a single bond; particularly preferably, both are single bonds, and the organic compound comprises a structural unit of formula (1c) or (2c):

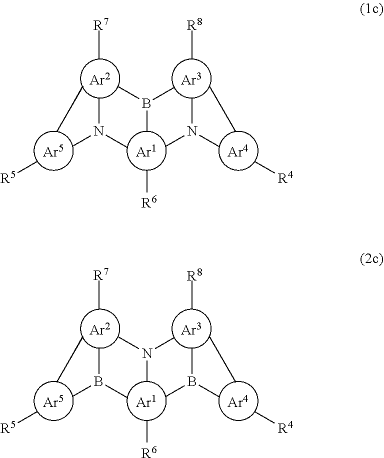

In some embodiments, X¹, X² at each occurrence are the same or different di-bridging group, the preferred di-bridging groups are selected form the following formulas:

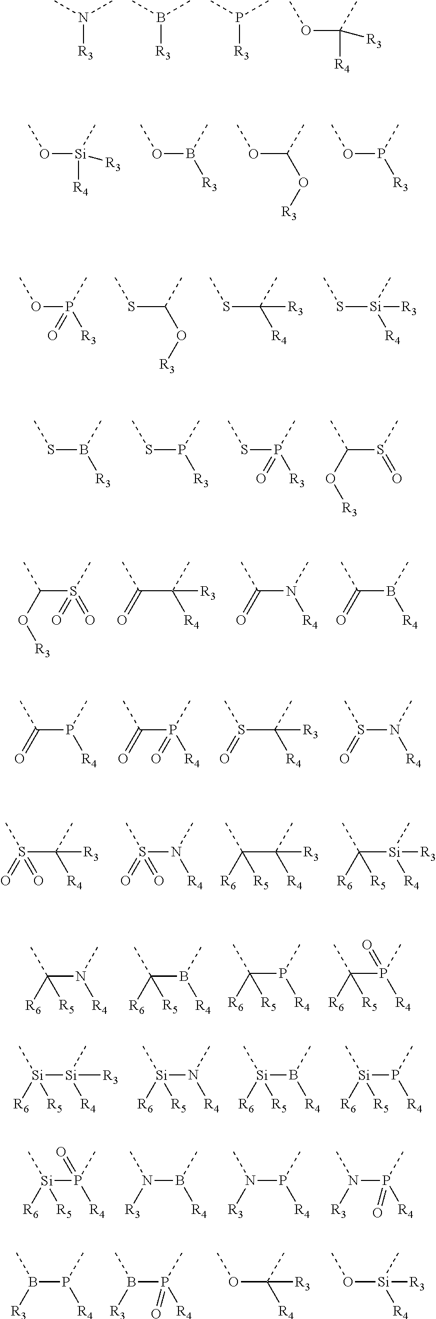

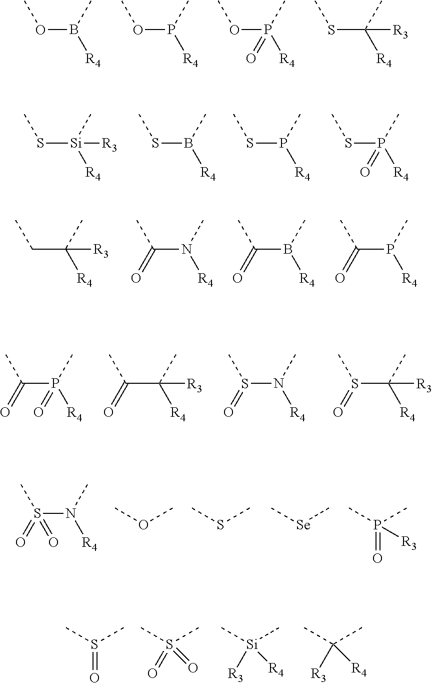

wherein R₃, R₄, R₅ and R₆ are identically defined as the above-mentioned R⁴, and the dashed bonds refer to the covalent bonds connecting to the adjacent structural units.

For the purposes of the present invention, the aromatic ring systems contain 5 to 10 carbon atoms, the heteroaromatic ring systems contain 1 to 10 carbon atoms and at least one heteroatom, while the total number of the carbon atoms and the heteroatoms is at least 4. The heteroatoms are preferably selected from Si, N, P, O, S and/or Ge, particularly preferably selected from Si, N, P, O and/or S. For the purposes of the present invention, the aromatic ring groups or heteroaromatic ring groups contain not only aromatic or heteroaromatic systems, but also a plurality of aromatic or heteroaromatic groups are interconnected by short non-aromatic units (for example by <10% of non-H atoms, more specifically <5% of non-H atoms, such as C, N or O atoms). Therefore, systems such as 9,9′-spirobifluorene, 9,9-diarylfluorene, triarylamine, diaryl ether, and the like are also considered to be aromatic ring systems for the purposes of this invention.

For the purposes of the present disclosure, the any H atom on the compound may be optionally substituted with a R⁴ group, wherein the preferred R⁴ may be selected from the group consisting of: (1) a C₁-C₁₀ alkyl group, particularly preferably the following groups: methyl, ethyl, n-propyl, isopropyl, cyclopropyl, n-butyl, isobutyl, sec-butyl, t-butyl, cyclobuty, 2-methylbutyl, n-pentyl, n-hexyl, cyclohexy, n-heptyl, cycloheptyl, n-octyl, cyclobutyl, 2-methylheptyl, trifluoromethyl, pentafluoroethyl, 2,2,2-trifluoroethyl, vinyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexyne, and octenyl; (2) a C₁-C₁₀ alkoxy group, particularly preferably methoxy, ethoxy, n-propoxy, isopropoxy, n-butoxy, isobutoxy, sec-butoxy, tert-butoxy and 2-methylbutoxy; (3) a C₂-C₁₀ aryl or heteroaryl group, which may be monovalent or divalent depending on the application, and in each case can also be optionally substituted with the R⁴ group mentioned above or may be attached, at any desired position, to an aromatic or heteroaromatic ring, particularly preferably selected from the group consisting of benzene, naphthalene, anthracene, dihydropyrene, chrysene, pyrene, fluoranthene, naphthacene, pentacene, benzopyrene, furan, benzofuran, isobenzofuran, dibenzofuran, thiophene, benzothiophene, isobenzothiophene, thiofluorene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, pyrazole, indazole, imidazole, benzimidazole, naphthimidazole, phenimidazole, pyrazine-imidazole, quinoxaline-imidazole, oxazole, benzoxazole, naphthoxazole, anthracenazole, phenoxazole, isoxazole, 1,2-thiazole, 1,3-thiazole, benzothiazole, pyridazine, benzopyridazine, pyrimidine, benzopyrimidine, quinoxaline, pyrazine, phenazine, 1,5-naphthyridine, carbazole, benzocholine, phenanhroline, 1,2,3-triazole, 1,2,4-triazole, benzotriazole, 1,2,3-oxadiazole, 1,2,4-oxadiazole, 1,2,5-oxadiazole, 1,3,4-oxadiaazole, 1,2,3-thinadiazole, 1,2,4-thiadiazole, 1,2,5-thiadiazole, 1,3,4-thiadiazole, 1,3,5-triazine, 1,2,4-triazine, 1,2,3-triazine, tetrazole. 1,2,4,5-tetrazine, 1,2,3,4-tetrazine, 1,2,3,5-tetrazine, purine, pteridine, indolizine, and benzothiadiazole. For the purposes of the present disclosure, aromatic and heteroaromatic ring systems are particularly considered to be, in addition to the above-mentioned aryl and heteroaryl groups, also refer to biphenylene, terphenylene, fluorene, spirobifluorene, dihydrophenanthrene, tetrahydropyrene, and cis- or trans-indenofluorene.

In some embodiments, the compounds as described herein, wherein Ar¹ to Ar⁵ may be the same or different, at each occurrence, are independently selected from the group consisting of aromatic/heteroaromatic groups containing 5 to 20 ring atoms; preferably from the aromatic/heteroaromatic groups containing 5 to 18 ring atoms; more preferably from the aromatic/heteroaromatic groups containing 5 to 15 ring atoms; and most preferably from aromatic/heteroaromatic groups containing 5 to 10 ring atoms; they may be unsubstituted or further substituted by one or two R⁴ groups. Preferred aromatic/heteraromatic groups include benzene, naphthalene, anthracene, phenanthrene, pyridine, pyrene, and thiophene.

In some embodiments, Ar¹ to Ar⁵ comprises the following structural formulas, which may each be substituted by one or more R⁴ groups.

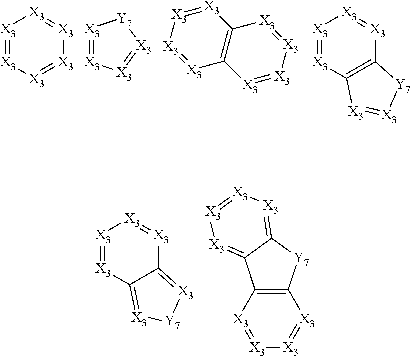

Each X₃ is CR⁶ or N; each Y₇ is CR⁷R⁸, SiR⁹R¹⁰, NR⁶, C(═O), S, or O.

Further, Ar¹, Ar², Ar³, Ar⁴, Ar⁵ are each independently selected from one of the following structural formulas or any combination thereof, which can be further arbitrarily substituted:

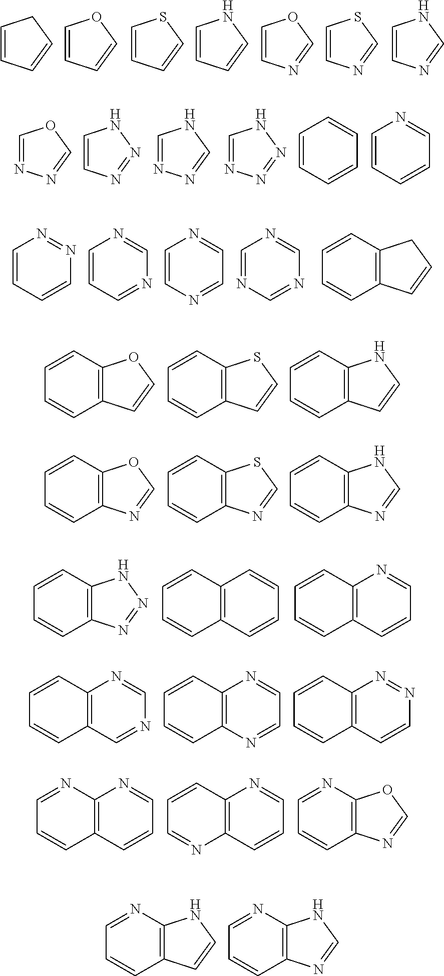

For the purposes of the present disclosure, in some embodiments, in the structural unit according to the formulas (1)-(1e) or (2)-(2e), Ar¹ to Ar⁵ are all phenyl groups.

In some embodiments, the organic compound comprises a structural unit of formula (1a) or (2a):

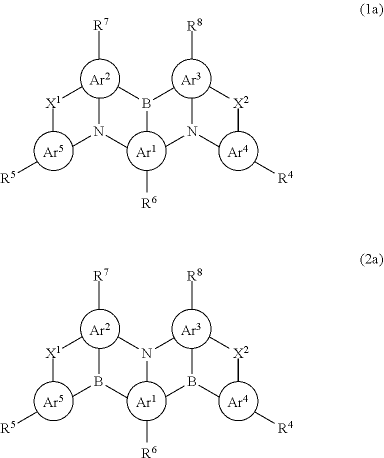

wherein each of X¹ and X² is O or S; and particularly preferably is O.

In some embodiments, the organic compound comprises a structural unit represented by one of the following formulas (1d), (2d), (1e), (2e).

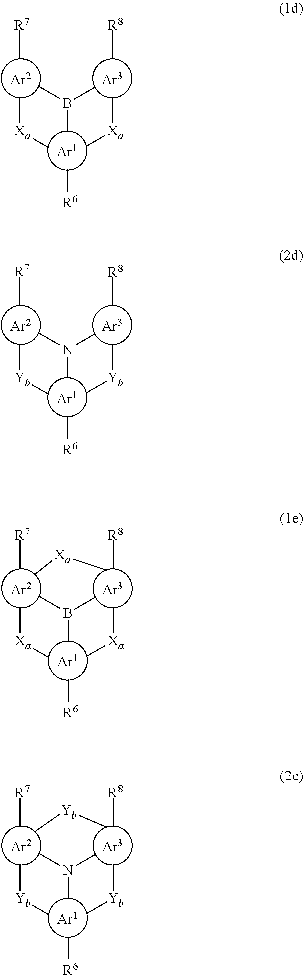

Preferably, each Y_{b} in the formulas (2d) and (2e) is independently C═O, O, P(═O)R⁹, S═O, or SO₂; and particularly preferably is C═O.

Preferably, each Xₐ in the formulas (1d) and (1e) is independently N(R⁹), C(R⁹R¹⁰), Si(R⁹R¹⁰), O, S.

In some embodiments, the structural units according to formulas (1), (2), (1a)-(1e), (2a)-(2e), wherein R⁴ to R⁸ may be same or different, at each occurrence, comprising the following structural units or any combination thereof:

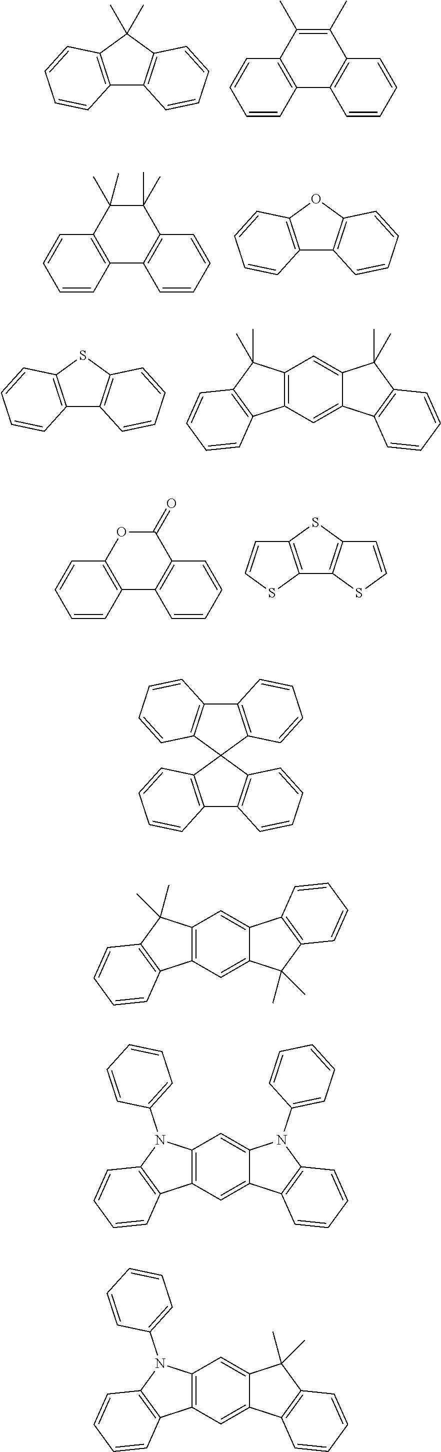

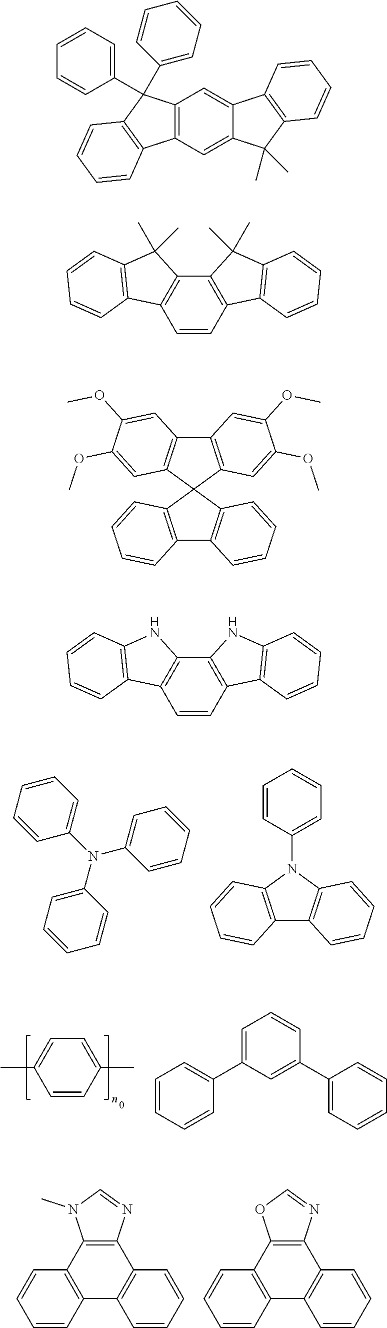

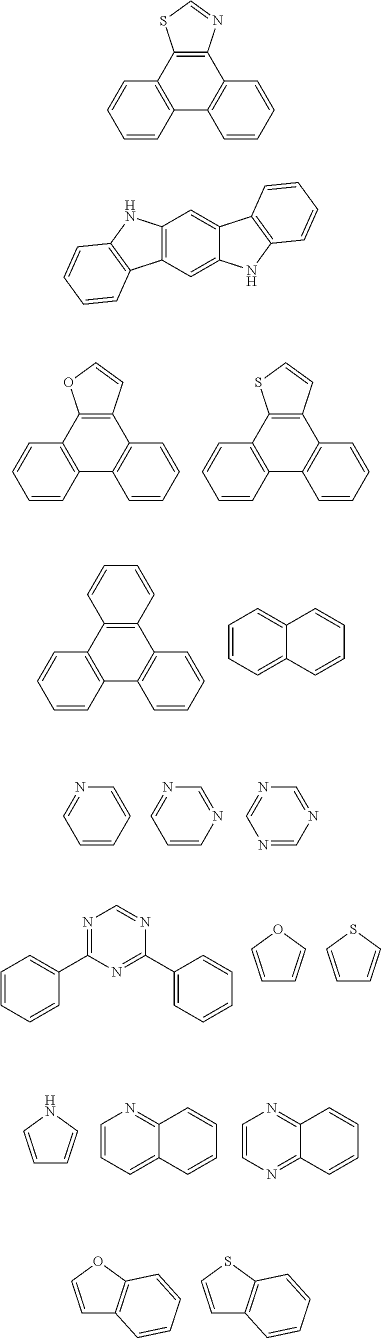

wherein no is 1, or 2, or 3, or 4.

In some embodiments, the structure of the organic compound is shown below:

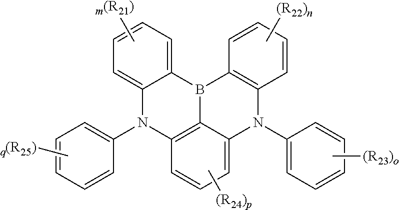

wherein R₂₁ to R₂₅ are independently selected from the group consisting of —H, -D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group or an isothiocyanate group, a hydroxyl group, a nitro group, a trifluoromethyl group, Cl, Br, F, a substituted/unsubstituted aromatic/heteroaromatic group containing 5 to 40 ring atoms, an aryloxy/heteroaryloxy group containing 5 to 40 ring atoms, and any combination thereof, wherein one or more of the substituent groups can form a monocyclic or polycyclic aliphatic or aromatic ring system with each other and/or with the ring bonded to the groups; and at least one of R₂₁ to R₂₅ contains a cross-linkable group.

m and n are integers from 0 to 4; o and q are integers from 0 to 5; p is an integer from 0 to 3.

Preferably, R₂₁ to R₂₅ are independently selected from the group consisting of —H, -D, a C₁-C₁₀ linear alkyl group, a C₁-C₁₀ linear alkoxy group, a C₁-C₁₀ linear thioalkoxy group, a C₃-C₁₀ branched/cyclic alkyl group, a C₃-C₁₀ branched/cyclic alkoxy group, a C₃-C₁₀ branched/cyclic thioalkoxy group, a C₃-C₁₀ branched/cyclic silyl group, a C₁-C₁₀ ketone group, a C₂-C₁₀ alkoxycarbonyl group, a C₇-C₁₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group or an isothiocyanate group, a hydroxyl group, a nitro group, a trifluoromethyl group, Cl, Br, F, a substituted/unsubstituted aromatic/heteroaromatic group containing 5 to 20 ring atoms, an aryloxy/heteroaryloxy group containing 5 to 20 ring atoms, and any combination thereof, wherein one or more of the substituent groups can form a monocyclic or polycyclic aliphatic or aromatic ring system with each other and/or with the ring bonded to the groups.

In the embodiments of the present disclosure, triplet energy level (T1), singlet energy level (Si), highest occupied molecular orbital (HOMO), and lowest unoccupied molecular orbital (LUMO) play key roles in the energy level structure of the organic material. The determination of these energy levels is introduced as follows.

HOMO and LUMO energy levels can be measured by photoelectric effect, for example by XPS (X-ray photoelectron spectroscopy), UPS (UV photoelectron spectroscopy), or by cyclic voltammetry (hereinafter referred to as CV). Recently, quantum chemical methods, such as density functional theory (hereinafter referred to as DFT), are becoming an effective method for calculating the molecular orbital energy levels.

The triplet energy level T1 of the organic material can be measured by low-temperature time-resolved spectroscopy, or calculated by quantum simulation (for example, by Time-dependent DFT), for instance with the commercial software Gaussian 03W (Gaussian Inc.).

The singlet energy level S1 of the organic material can be determined by the absorption spectrum or the emission spectrum, and can also be calculated by quantum simulation (such as Time-dependent DFT).

It should be noted that the absolute values of HOMO, LUMO, T1 and Si may varies, depending on the measurement method or calculation method used. Even for the same method, different ways of evaluation, for example, using either the onset or peak value of a CV curve as reference, may result in different (HOMO/LUMO) values. Therefore, reasonable and meaningful comparison should be carried out by using the same measurement and evaluation methods. In the embodiments of the present disclosure, the values of HOMO, LUMO, T1 and S1 are based on the Time-dependent DFT simulation, which however should not exclude the applications of other measurement or calculation methods.

In some embodiments, the S1-T1 of the organic compound as described herein ≤0.30 eV, preferably ≤0.25 eV, more preferably ≤0.20 eV, particularly preferably ≤0.15 eV, and most preferably ≤0.10 eV.

In some embodiments, in the organic compound as described herein, the cross-linkable group is selected from the group consisting of: 1) linear/cyclic alkenyl, linear dienyl, linear alkynyl; 2) enoxy, dienoxy; 3) acrylic; 4) propylene oxide, ethylene oxide; 5) silanyl; 6) cyclobutanyl.

Preferably, the cross-linkable group is selected from the following structures:

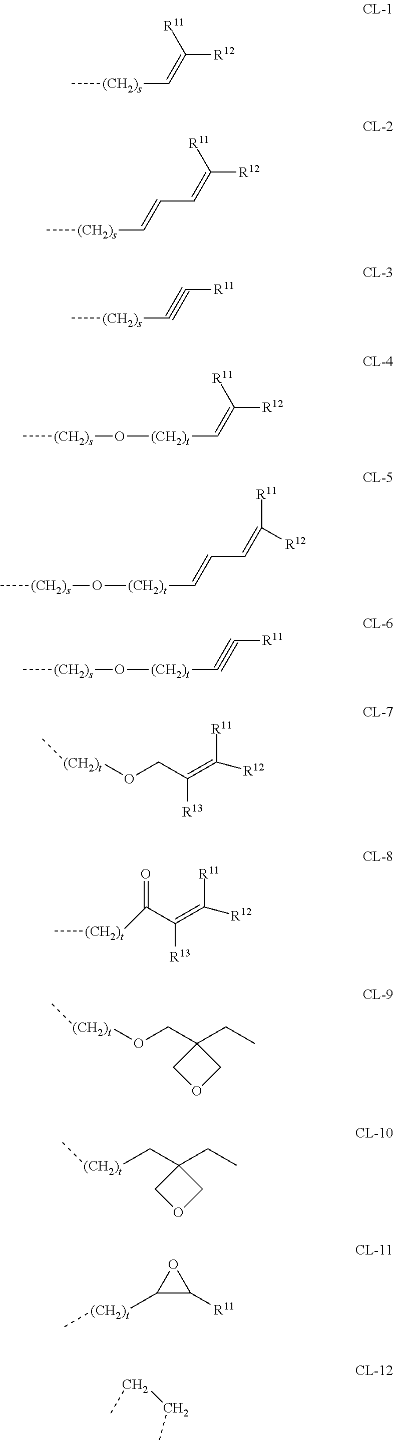

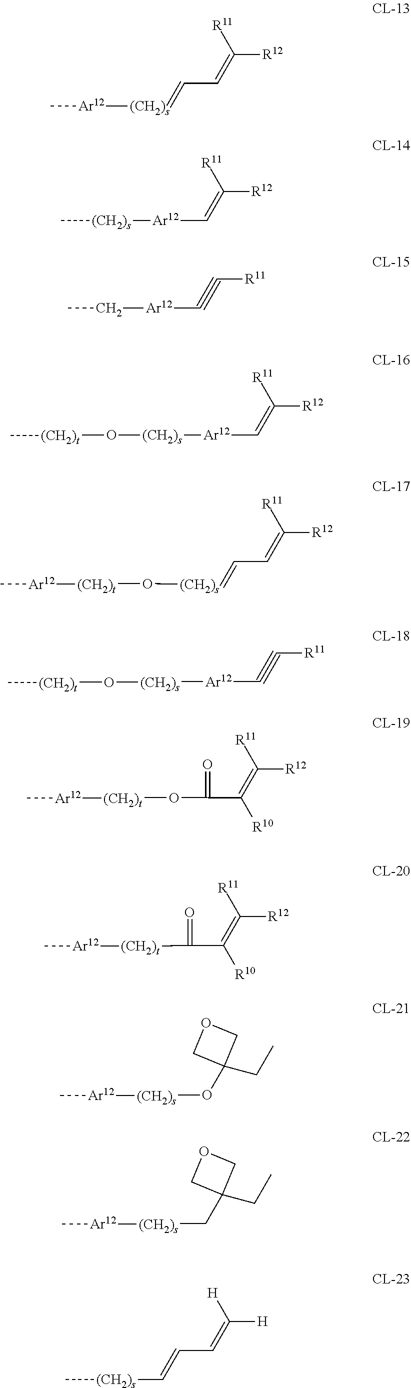

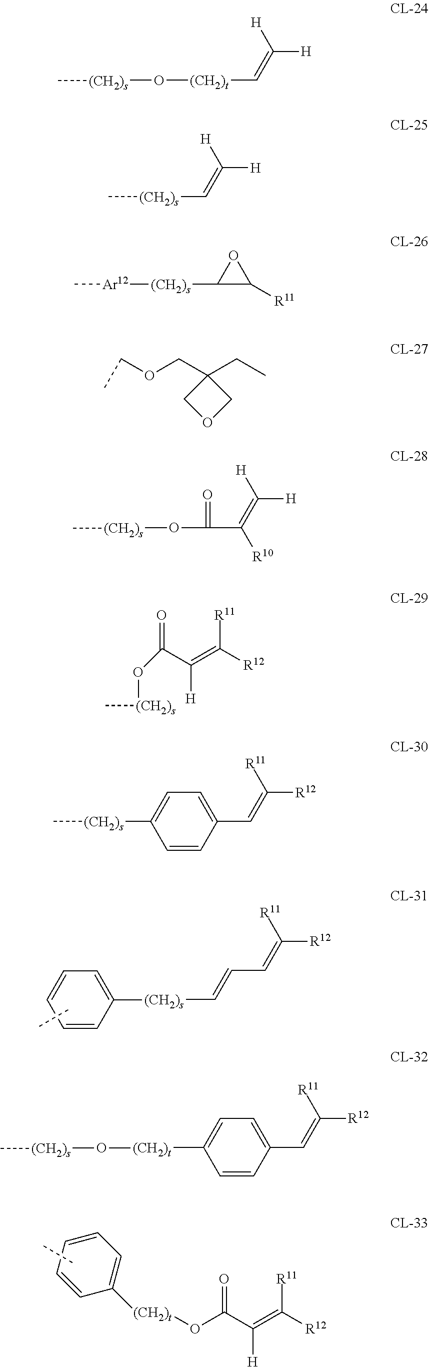

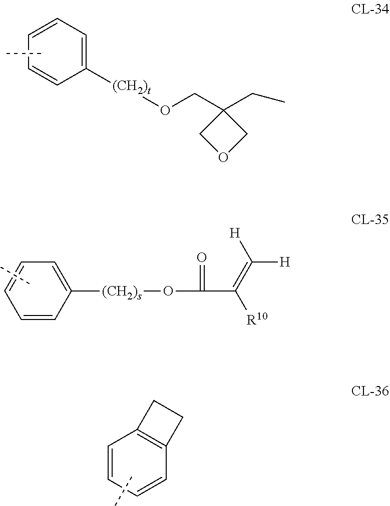

wherein each of s, t is an integer greater than 0; the dotted line represents a boned bond, R¹⁰ to R³ are identically defined as the above-mentioned R⁴, Ar¹² is identically defined as described above for the Ar¹ to Ar⁵.

In some more preferred embodiments, the cross-linkable structural units as described above are selected from the following structural general formulas:

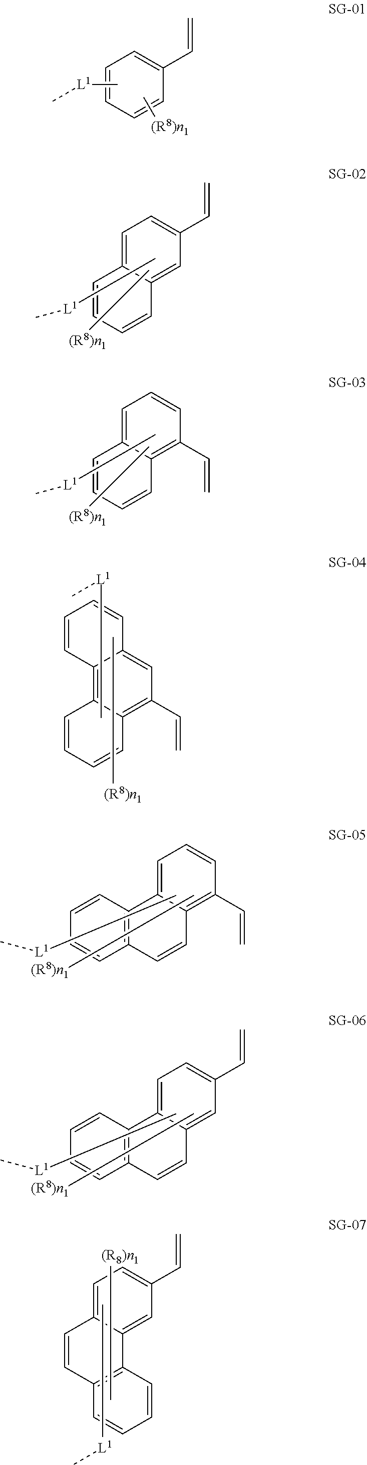

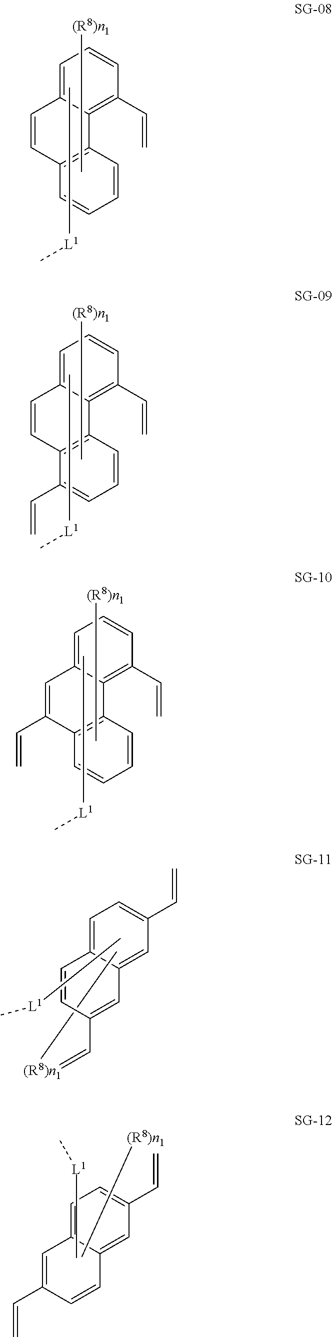

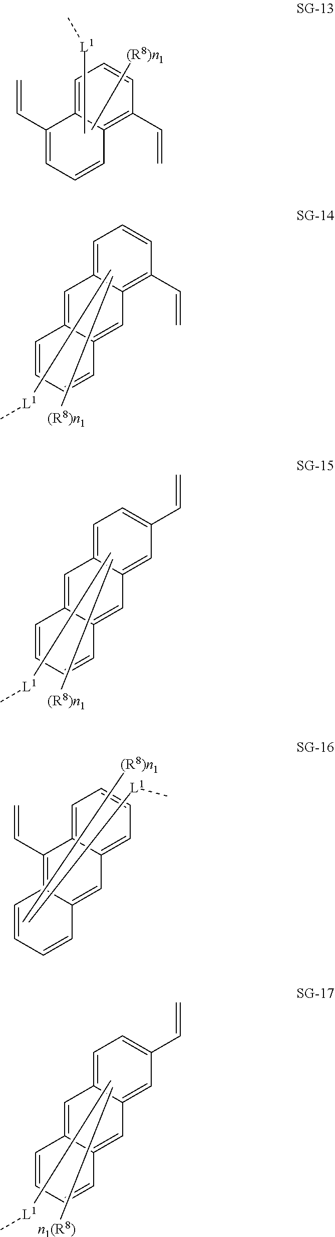

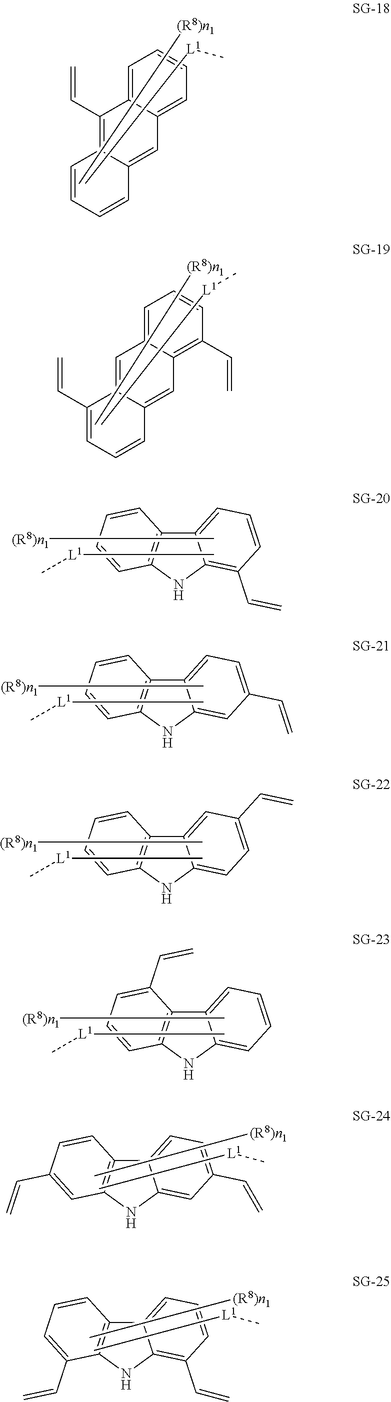

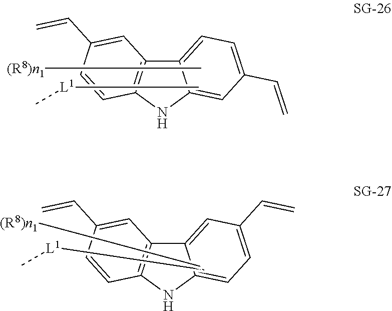

wherein n₁ is an integer greater than 0; L¹ represents a single bond or a linking group, and when representing as a linking group, it is an aryl or a heteroaryl group; The dotted bond indicated a bond bonded to the functional structural unit Ar.

The linking group L¹ is particularly preferably selected from the following structures:

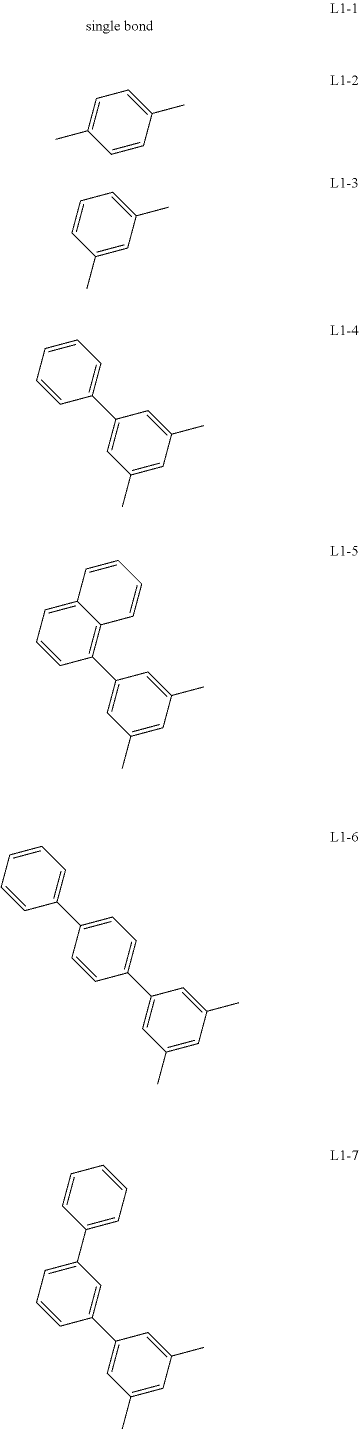

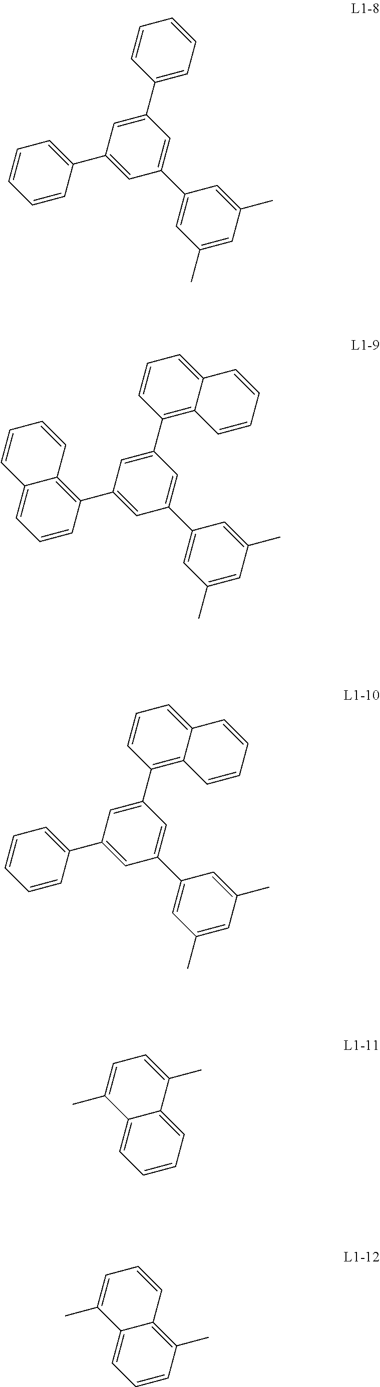

Furthermore, the individual H atoms or CH₂ groups as described herein can be substituted by the above-mentioned groups or R group, R is selected from the group consisting of C₁-C₄₀ alkyl groups, preferably from the group consisting of methyl, ethyl, n-propyl, isopropyl, cyclopropyl, n-butyl, isobutyl, sec-butyl, t-butyl, cyclobutyl, methylbutyl, n-pentyl, sec-pentyl, cyclopentyl, n-hexyl, cyclohexyl, n-heptyl, cycloheptyl, n-octyl, cyclooctyl, ethylhexyl, trifluoromethyl, pentafluoroethyl, trifluoroethyl, vinyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, and octenyl; and C₁-C₄₀ alkoxy groups, such as methoxy, trifluoromethoxy, ethoxy, n-propoxy, isopropoxy, n-butoxy, isobutoxy, sec-butoxy, tert-butoxy, and methylbutoxy.

In some embodiments, in the organic compound as described herein, the total percentage of the SP³ hybrid groups does not exceed 50% of the total molecular, more preferably does not exceed 30%, and most preferably does not exceed 20%. In organic electronic devices, the presence of less SP³ hybrid groups can effectively ensure the electrical stability of the compound, thereby ensuring the stability of the devices.

In some embodiments, in order to improve solubility and/or film-forming property, in the organic compound as described herein, the total percentage of the SP³ hybrid groups exceeds 20% of the total molecular, preferably exceeds 30%, more preferably exceeds 40%, and most preferably exceeds 50%.

In some embodiments, the organic compound is a color conversion material that can absorb the light of wavelength I and emit the light of wavelength II. Preferably, the wavelength II is larger than the wavelength I.

In some embodiments, the FWHM of the emission spectrum of the organic compound 50 nm, preferably 45 nm, more preferably 40 nm, particularly preferably 35 nm, and most preferably 30 nm.

Examples of suitable organic compounds as described herein are listed below, but not limited to:

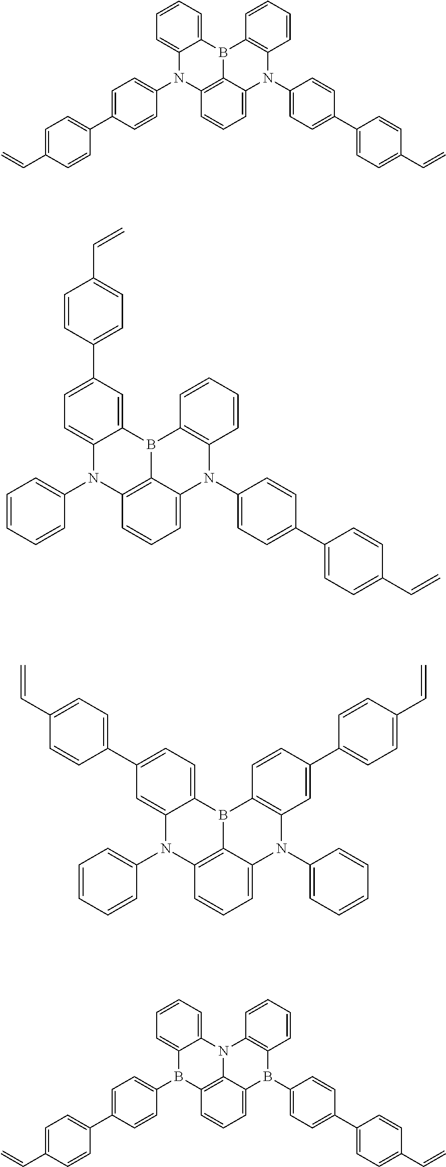

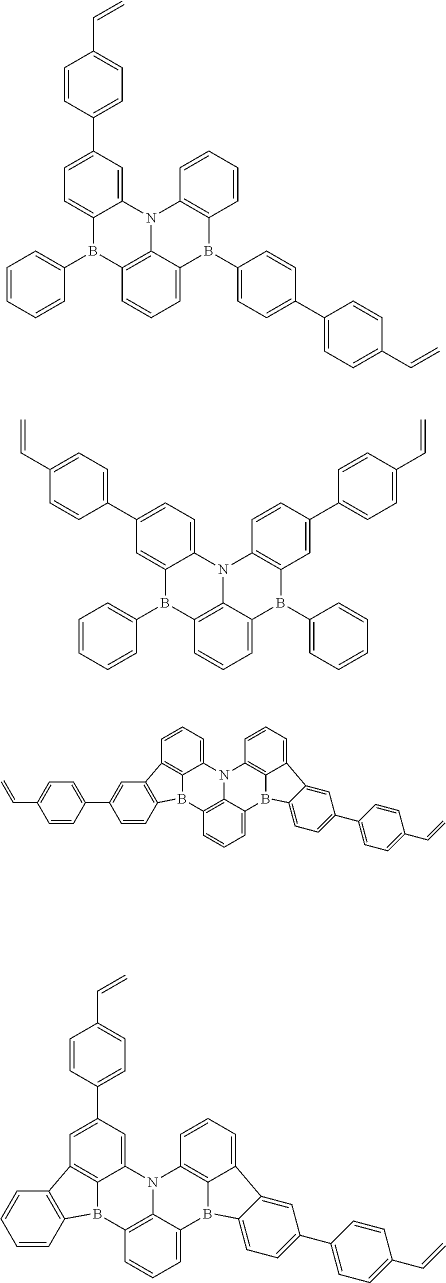

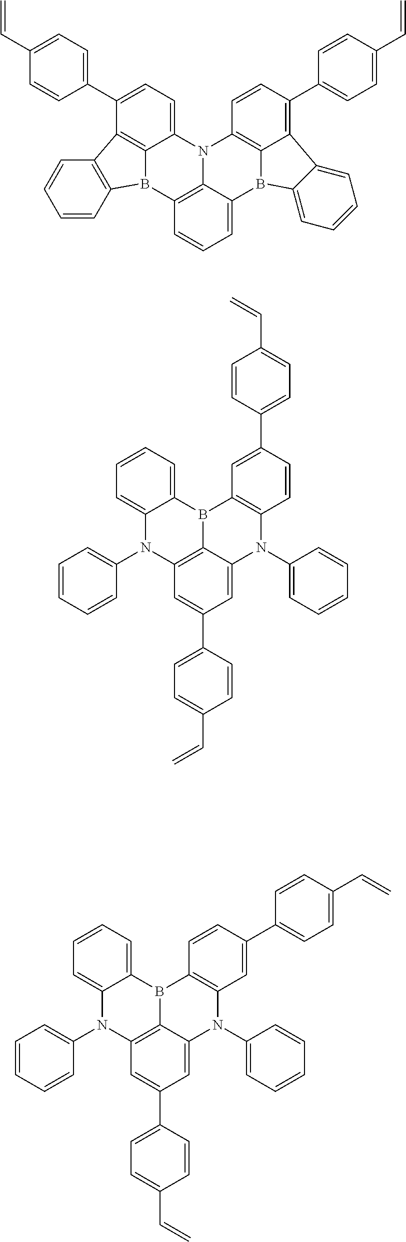 [SMILES: C=Cc1ccc(-c2ccc3c4c2-c2ccccc2B4c2cccc4c2N3c2ccc(-c3ccc(C=C)cc3)c3c2B4c2ccccc2-3)cc1 ; C=Cc1ccc(-c2ccc3c(c2)B2c4ccccc4N(c4ccccc4)c4cc(-c5ccc(C=C)cc5)cc(c42)N3c2ccccc2)cc1 ; C=Cc1ccc(-c2ccc3c(c2)N(c2ccccc2)c2cc(-c4ccc(C=C)cc4)cc4c2B3c2ccccc2N4c2ccccc2)cc1]

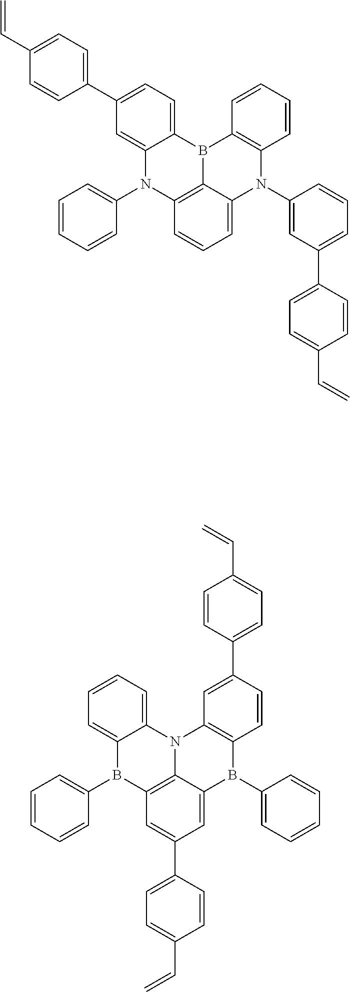 [SMILES: C=Cc1ccc(-c2cccc(N3c4ccccc4B4c5ccc(-c6ccc(C=C)cc6)cc5N(c5ccccc5)c5cccc3c54)c2)cc1 ; C=Cc1ccc(-c2cc3c4c(c2)B(c2ccccc2)c2ccc(-c5ccc(C=C)cc5)cc2N4c2ccccc2B3c2ccccc2)cc1]

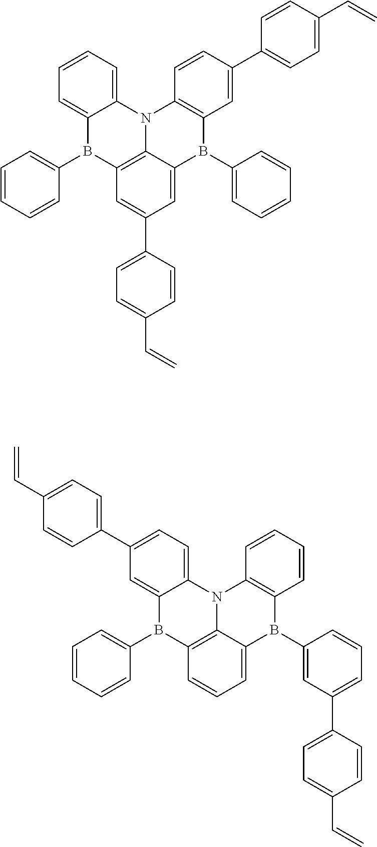 [SMILES: C=Cc1ccc(-c2ccc3c(c2)B(c2ccccc2)c2cc(-c4ccc(C=C)cc4)cc4c2N3c2ccccc2B4c2ccccc2)cc1 ; C=Cc1ccc(-c2cccc(B3c4ccccc4N4c5ccc(-c6ccc(C=C)cc6)cc5B(c5ccccc5)c5cccc3c54)c2)cc1]

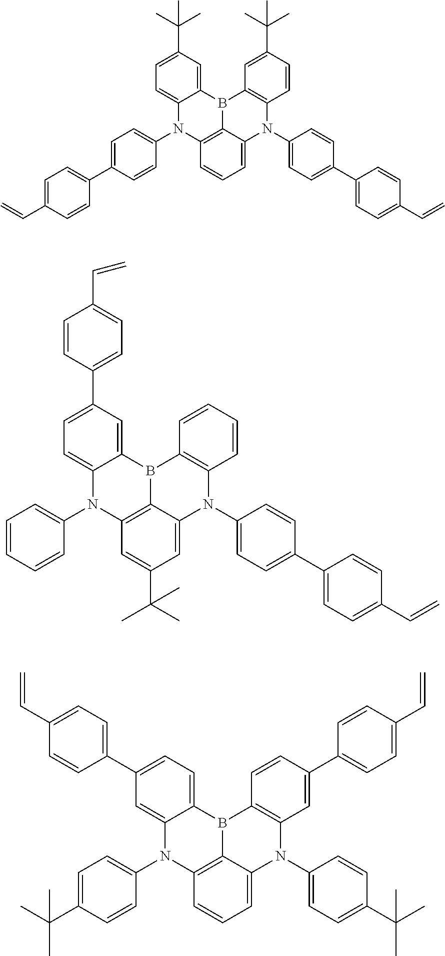 [SMILES: C=Cc1ccc(-c2ccc(N3c4ccc(C(C)(C)C)cc4B4c5cc(C(C)(C)C)ccc5N(c5ccc(-c6ccc(C=C)cc6)cc5)c5cccc3c54)cc2)cc1 ; C=Cc1ccc(-c2ccc(N3c4ccccc4B4c5cc(-c6ccc(C=C)cc6)ccc5N(c5ccccc5)c5cc(C(C)(C)C)cc3c54)cc2)cc1 ; C=Cc1ccc(-c2ccc3c(c2)N(c2ccc(C(C)(C)C)cc2)c2cccc4c2B3c2ccc(-c3ccc(C=C)cc3)cc2N4c2ccc(C(C)(C)C)cc2)cc1]

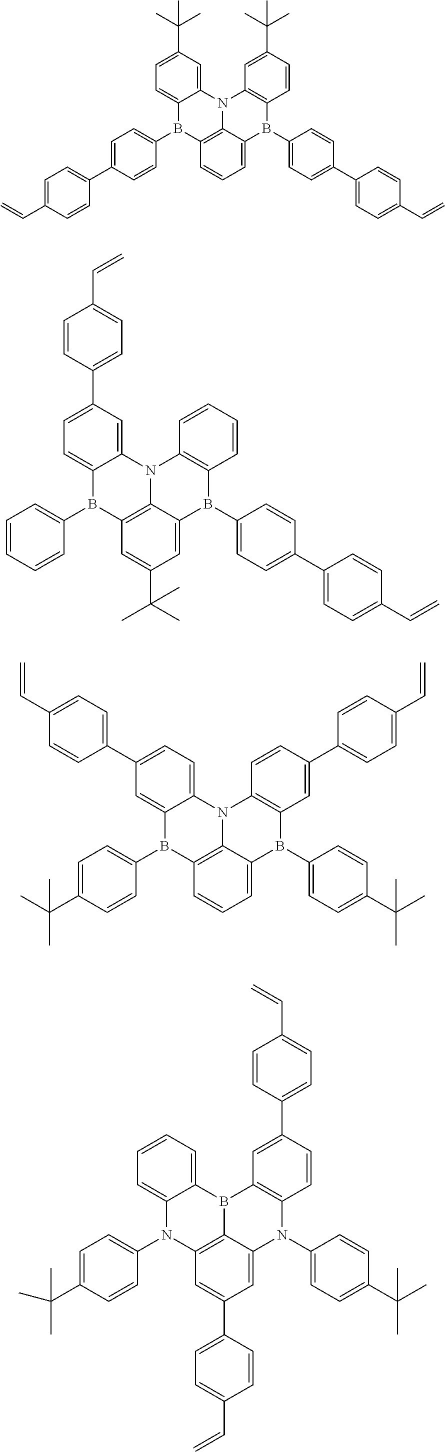

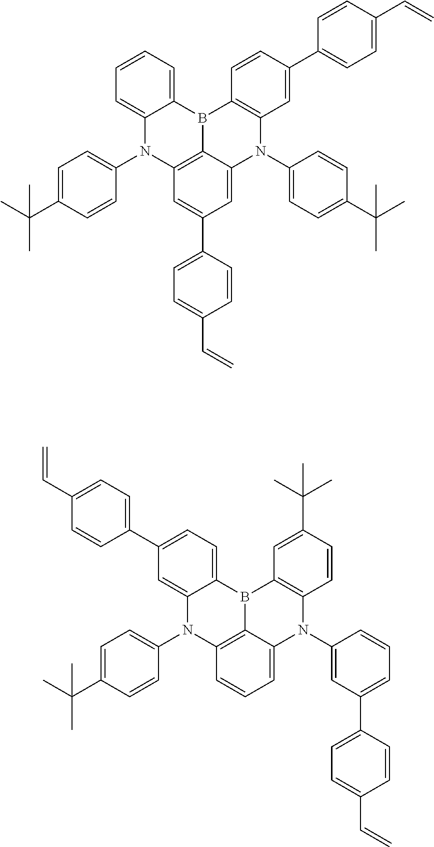 [SMILES: C=Cc1ccc(-c2ccc3c(c2)N(c2ccc(C(C)(C)C)cc2)c2cc(-c4ccc(C=C)cc4)cc4c2B3c2ccccc2N4c2ccc(C(C)(C)C)cc2)cc1 ; C=Cc1ccc(-c2cccc(N3c4ccc(C(C)(C)C)cc4B4c5ccc(-c6ccc(C=C)cc6)cc5N(c5ccc(C(C)(C)C)cc5)c5cccc3c54)c2)cc1]

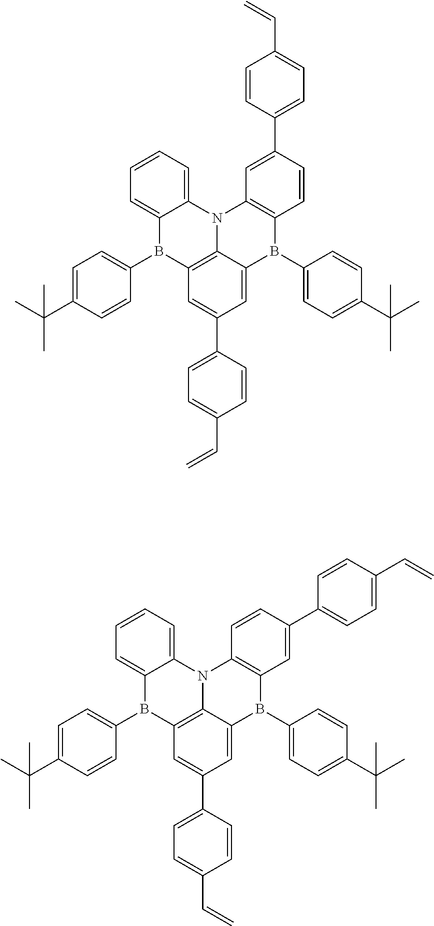

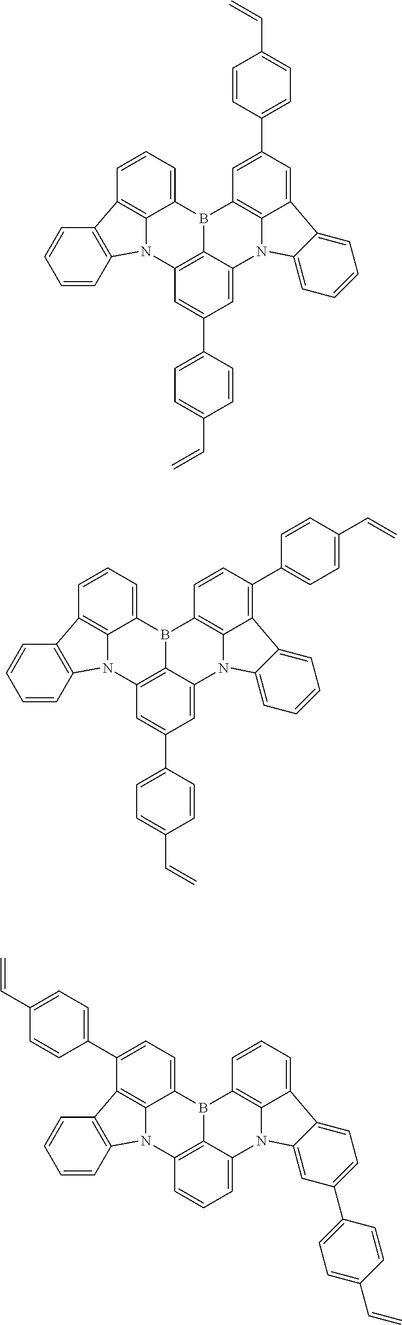 [SMILES: C=Cc1ccc(-c2cc3c4c(c2)-n2c5ccccc5c5cc(-c6ccc(C=C)cc6)cc(c52)B4c2cccc4c5ccccc5n-3c24)cc1 ; C=Cc1ccc(-c2cc3c4c(c2)-n2c5ccccc5c5c(-c6ccc(C=C)cc6)ccc(c52)B4c2cccc4c5ccccc5n-3c24)cc1 ; C=Cc1ccc(-c2ccc3c4cccc5c4n(c3c2)-c2cccc3c2B5c2ccc(-c4ccc(C=C)cc4)c4c5ccccc5n-3c24)cc1]

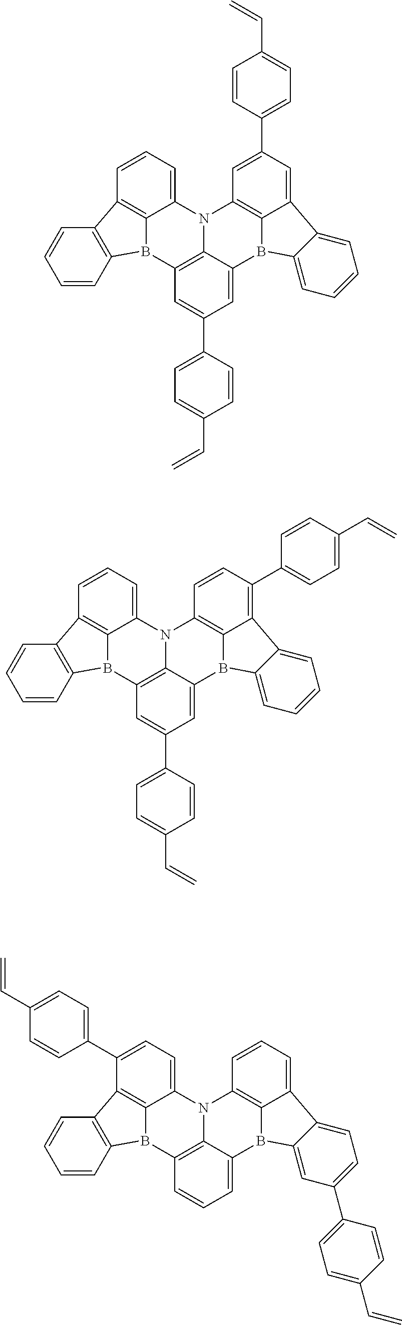 [SMILES: C=Cc1ccc(-c2cc3c4c(c2)B2c5ccccc5-c5cc(-c6ccc(C=C)cc6)cc(c52)N4c2cccc4c2B3c2ccccc2-4)cc1 ; C=Cc1ccc(-c2cc3c4c(c2)B2c5ccccc5-c5c(-c6ccc(C=C)cc6)ccc(c52)N4c2cccc4c2B3c2ccccc2-4)cc1 ; C=Cc1ccc(-c2ccc3c(c2)B2c4cccc5c4N(c4cccc-3c42)c2ccc(-c3ccc(C=C)cc3)c3c2B5c2ccccc2-3)cc1]

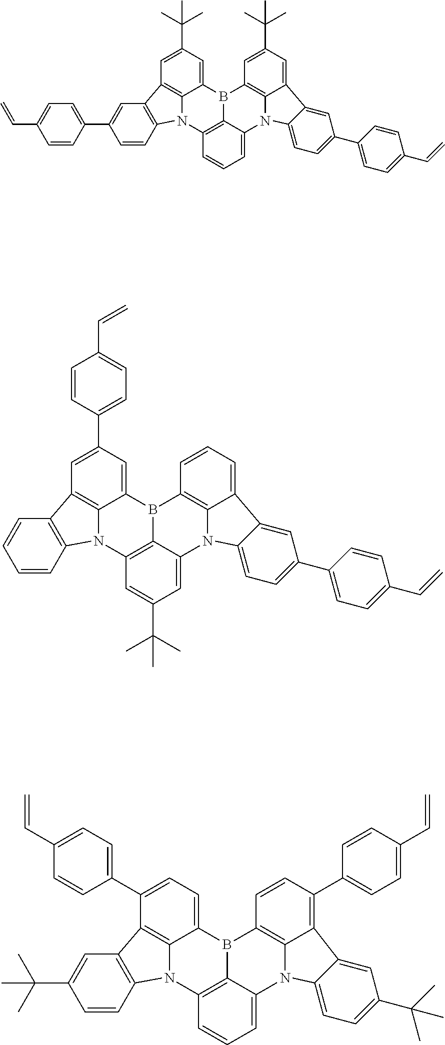

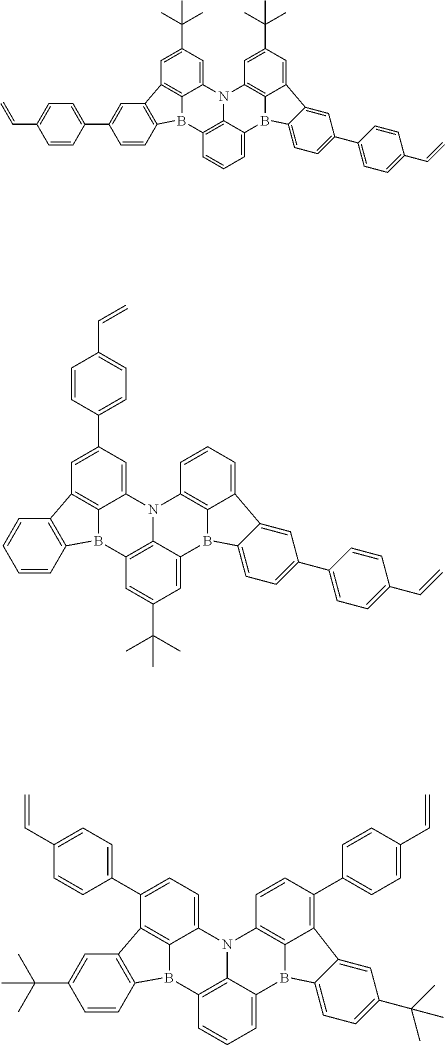

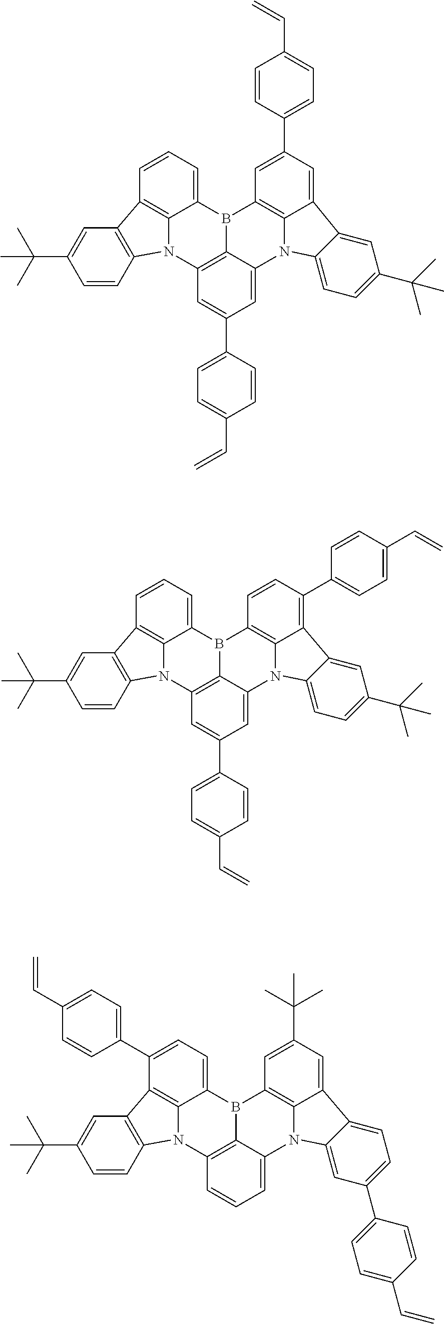

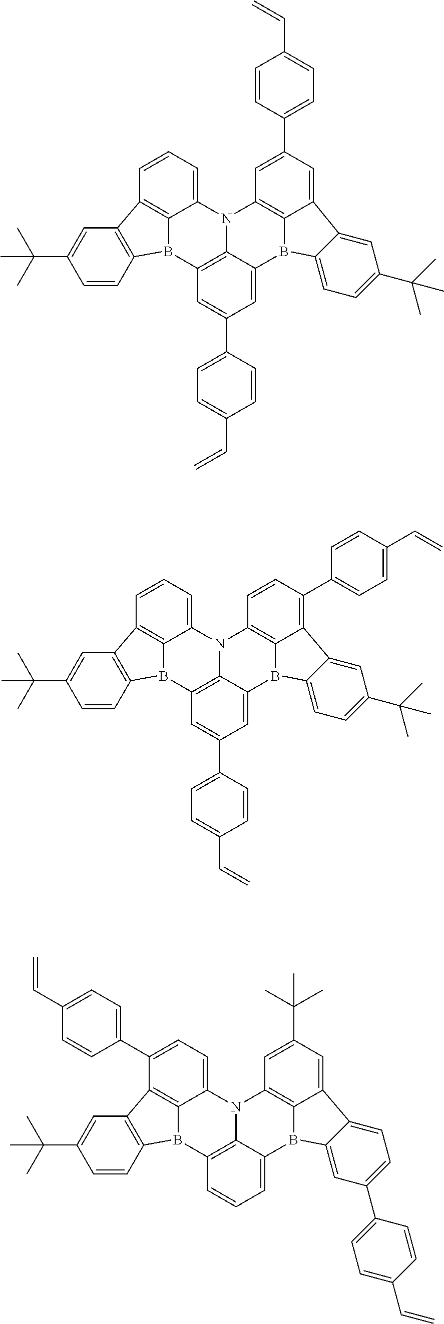

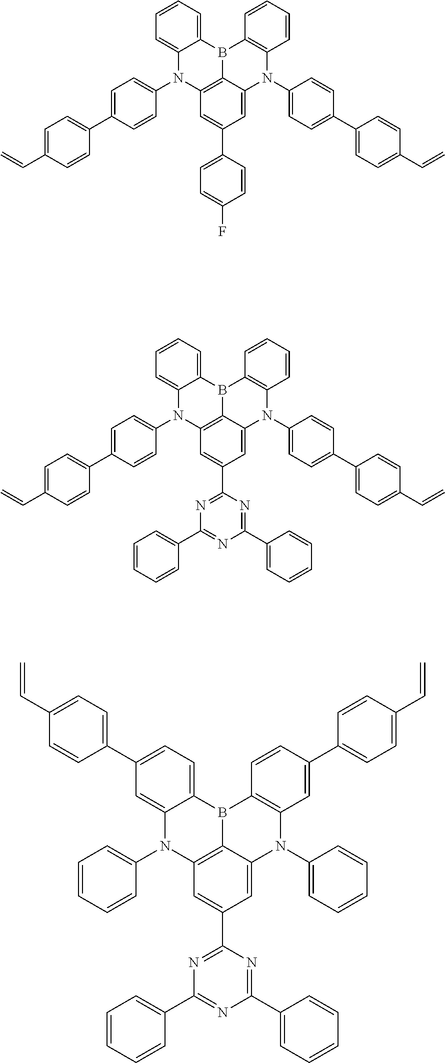

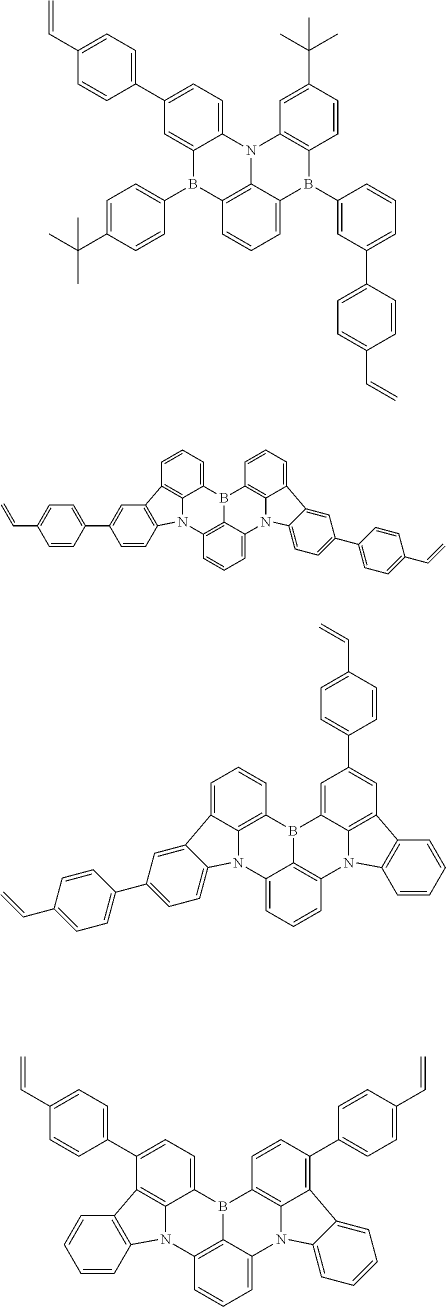

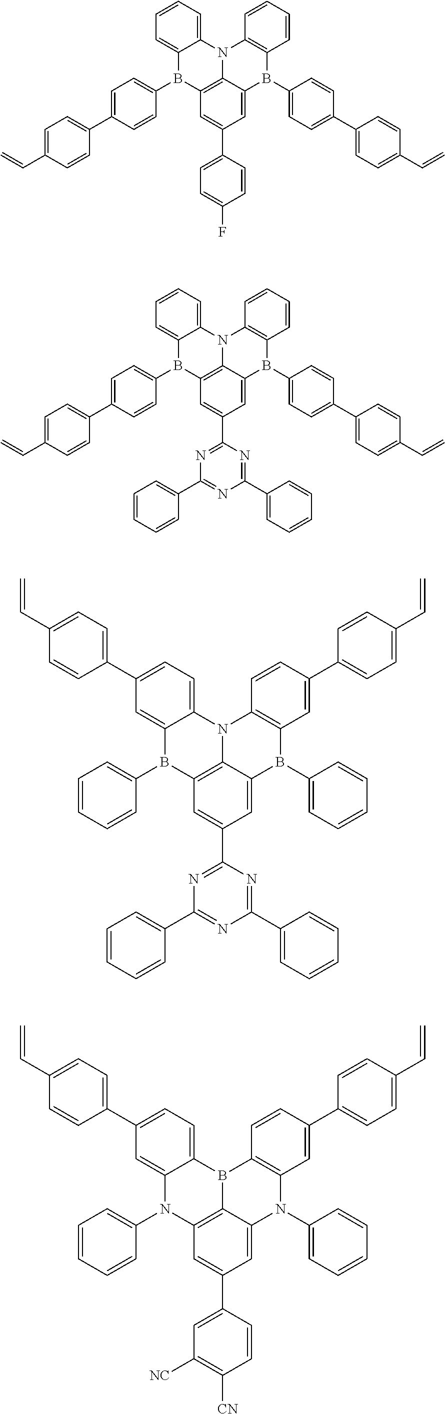

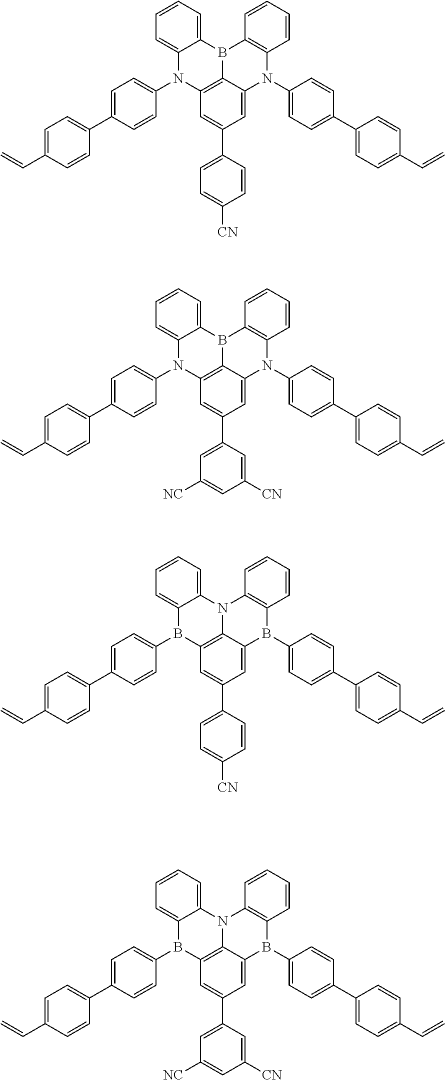

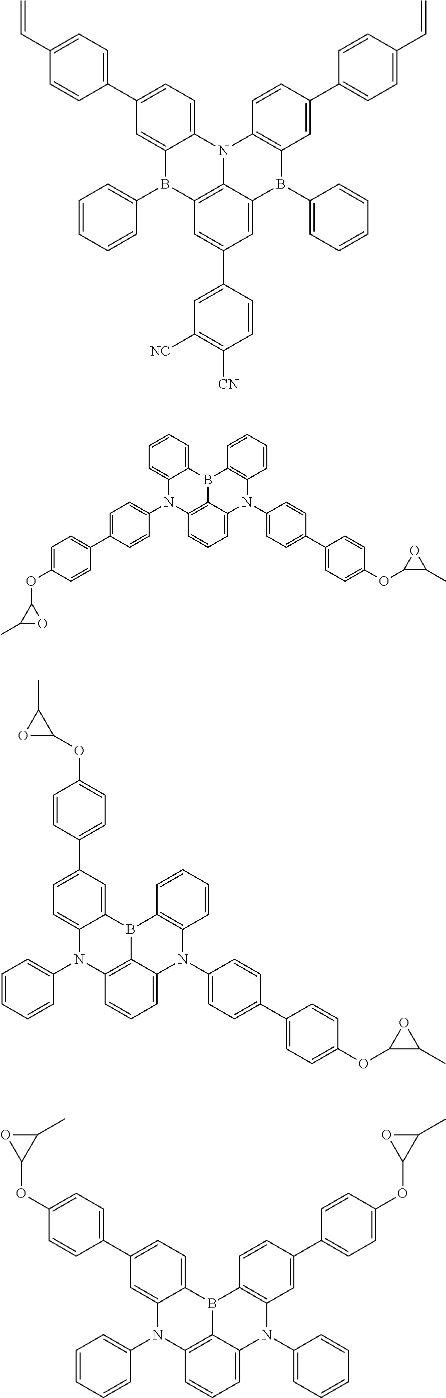

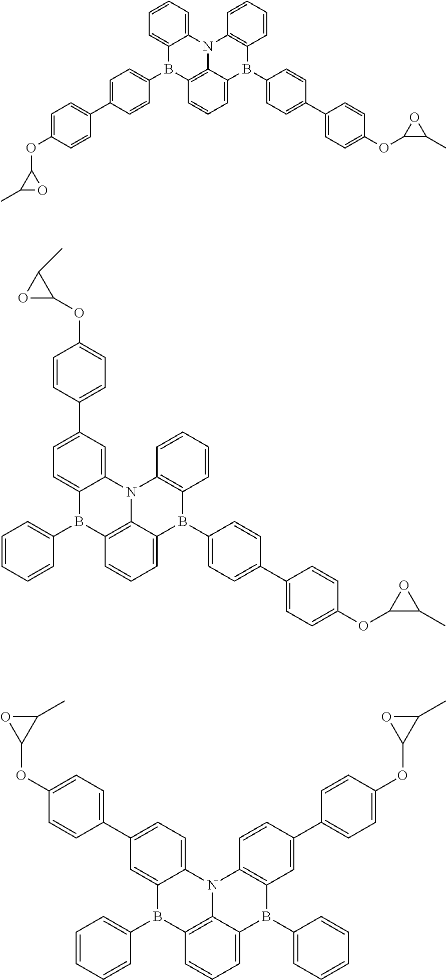

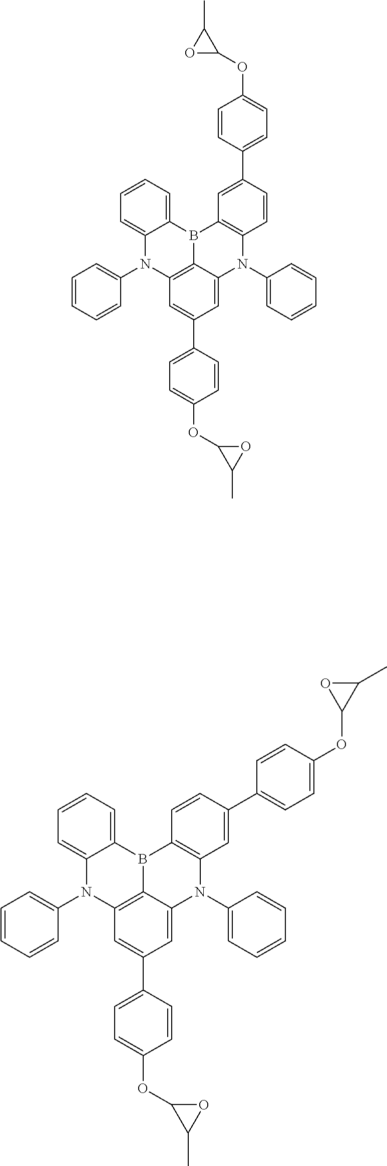 [SMILES: CC1OC1Oc1ccc(-c2ccc3c(c2)B2c4ccccc4N(c4ccccc4)c4cc(-c5ccc(OC6OC6C)cc5)cc(c42)N3c2ccccc2)cc1 ; CC1OC1Oc1ccc(-c2ccc3c(c2)N(c2ccccc2)c2cc(-c4ccc(OC5OC5C)cc4)cc4c2B3c2ccccc2N4c2ccccc2)cc1]

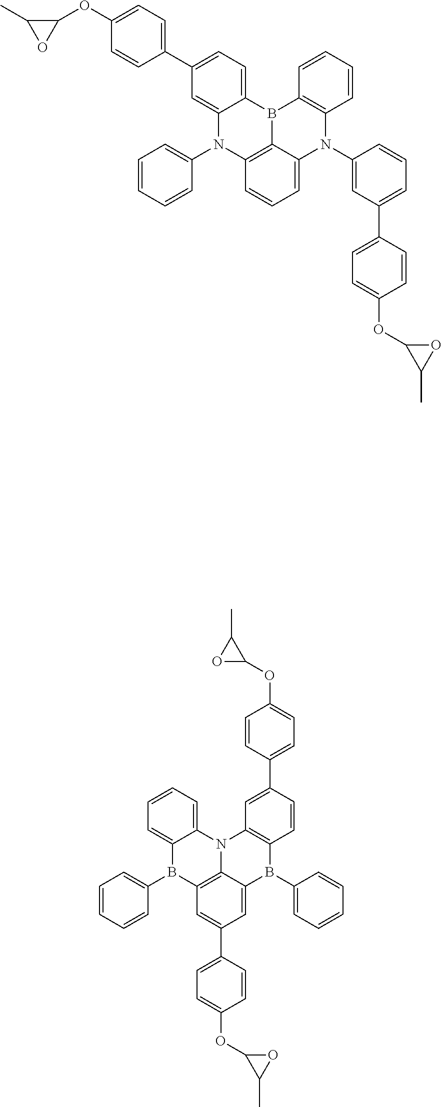 [SMILES: CC1OC1Oc1ccc(-c2cccc(N3c4ccccc4B4c5ccc(-c6ccc(OC7OC7C)cc6)cc5N(c5ccccc5)c5cccc3c54)c2)cc1 ; CC1OC1Oc1ccc(-c2cc3c4c(c2)B(c2ccccc2)c2ccc(-c5ccc(OC6OC6C)cc5)cc2N4c2ccccc2B3c2ccccc2)cc1]

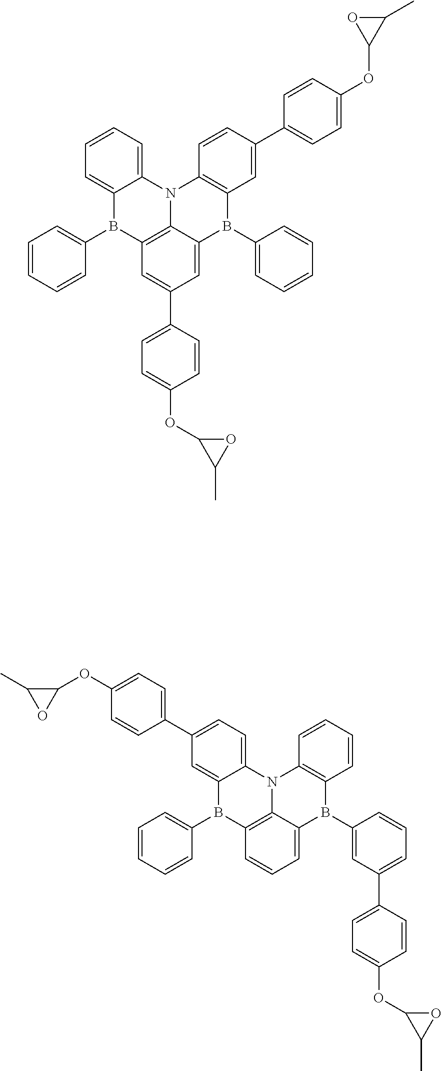

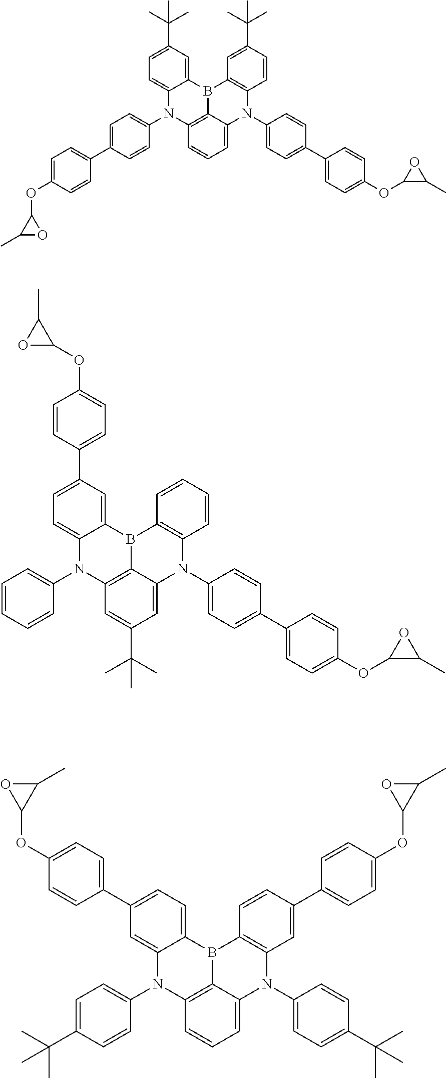

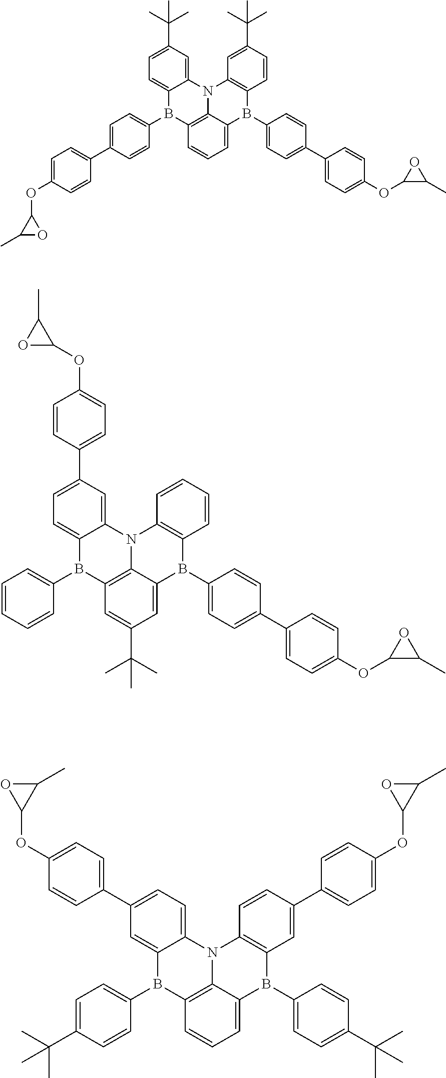

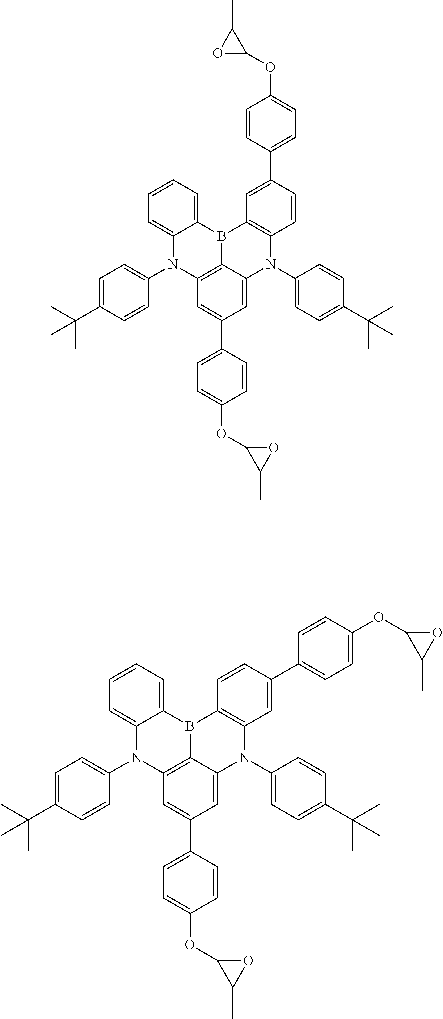

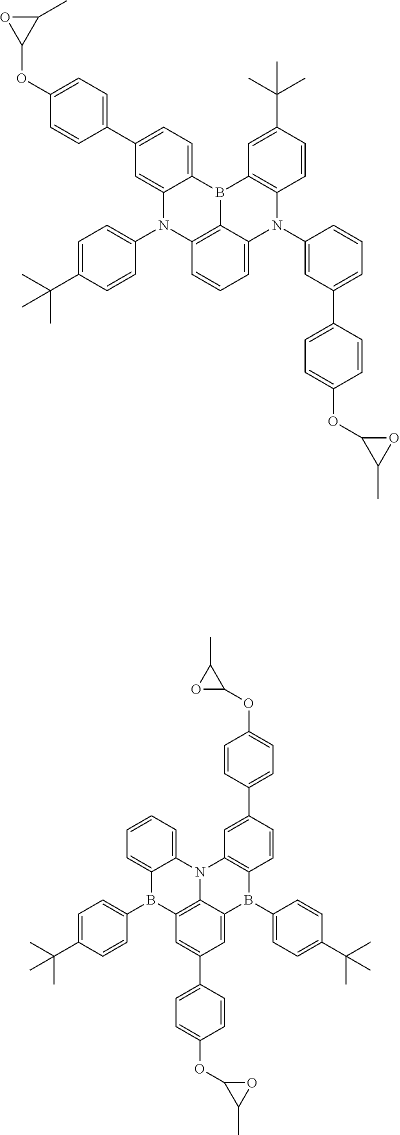 [SMILES: CC1OC1Oc1ccc(-c2cccc(N3c4ccc(C(C)(C)C)cc4B4c5ccc(-c6ccc(OC7OC7C)cc6)cc5N(c5ccc(C(C)(C)C)cc5)c5cccc3c54)c2)cc1 ; CC1OC1Oc1ccc(-c2cc3c4c(c2)B(c2ccc(C(C)(C)C)cc2)c2ccc(-c5ccc(OC6OC6C)cc5)cc2N4c2ccccc2B3c2ccc(C(C)(C)C)cc2)cc1]

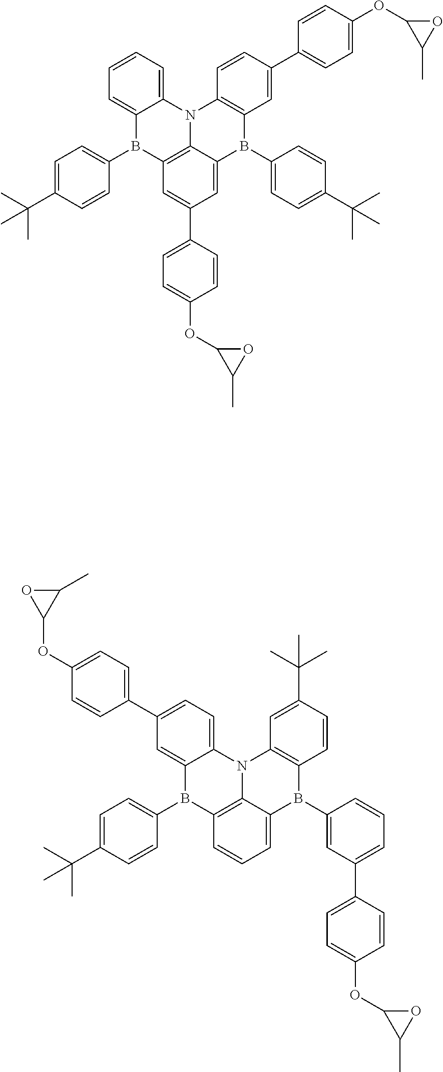 [SMILES: CC1OC1Oc1ccc(-c2ccc3c(c2)B(c2ccc(C(C)(C)C)cc2)c2cc(-c4ccc(OC5OC5C)cc4)cc4c2N3c2ccccc2B4c2ccc(C(C)(C)C)cc2)cc1 ; CC1OC1Oc1ccc(-c2cccc(B3c4ccc(C(C)(C)C)cc4N4c5ccc(-c6ccc(OC7OC7C)cc6)cc5B(c5ccc(C(C)(C)C)cc5)c5cccc3c54)c2)cc1]

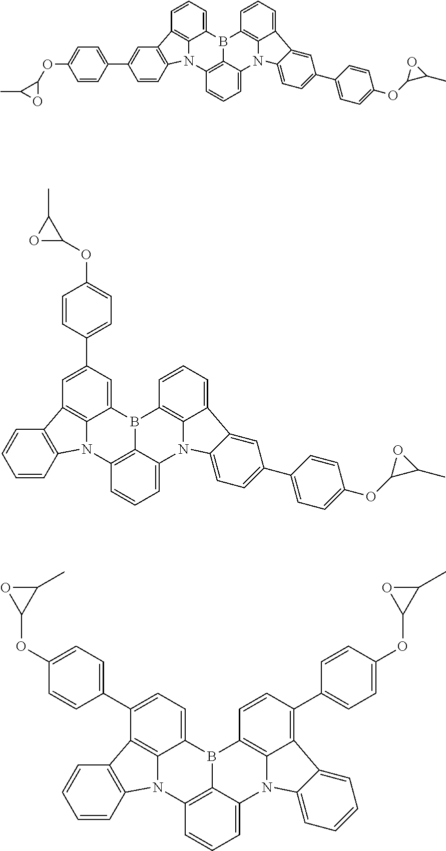

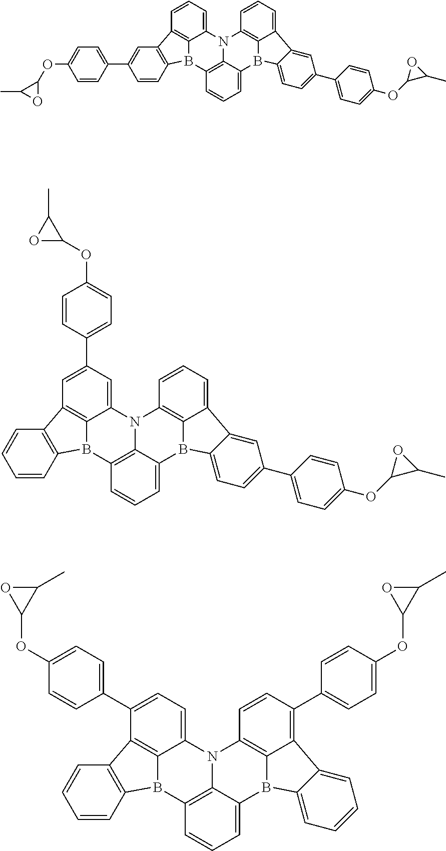

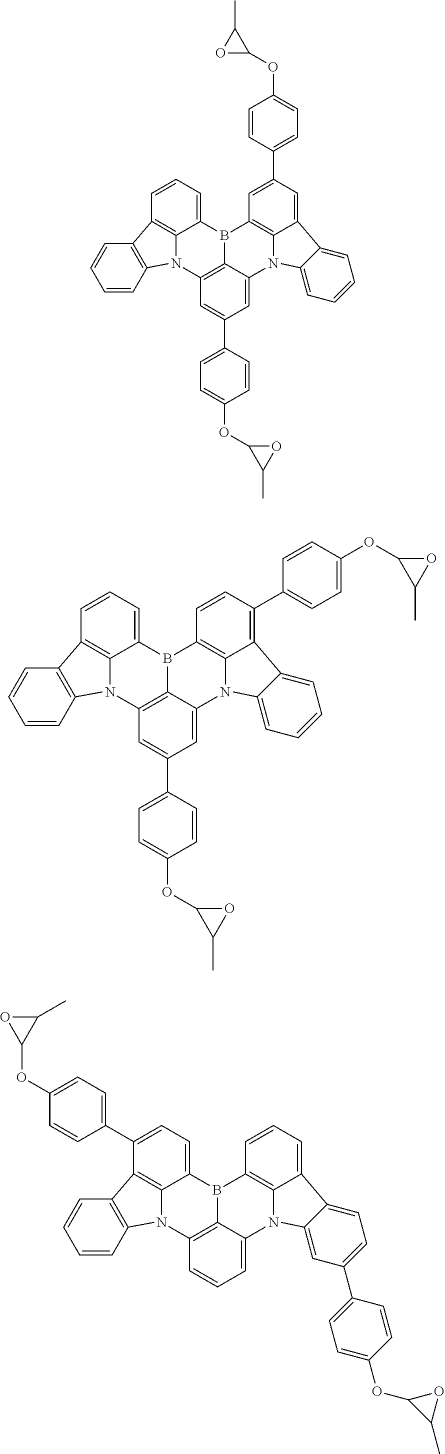 [SMILES: CC1OC1Oc1ccc(-c2cc3c4c(c2)-n2c5ccccc5c5cc(-c6ccc(OC7OC7C)cc6)cc(c52)B4c2cccc4c5ccccc5n-3c24)cc1 ; CC1OC1Oc1ccc(-c2cc3c4c(c2)-n2c5ccccc5c5c(-c6ccc(OC7OC7C)cc6)ccc(c52)B4c2cccc4c5ccccc5n-3c24)cc1 ; CC1OC1Oc1ccc(-c2ccc3c4cccc5c4n(c3c2)-c2cccc3c2B5c2ccc(-c4ccc(OC5OC5C)cc4)c4c5ccccc5n-3c24)cc1]

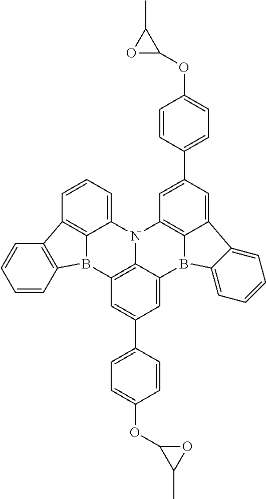 [SMILES: CC1OC1Oc1ccc(-c2cc3c4c(c2)B2c5ccccc5-c5cc(-c6ccc(OC7OC7C)cc6)cc(c52)N4c2cccc4c2B3c2ccccc2-4)cc1]

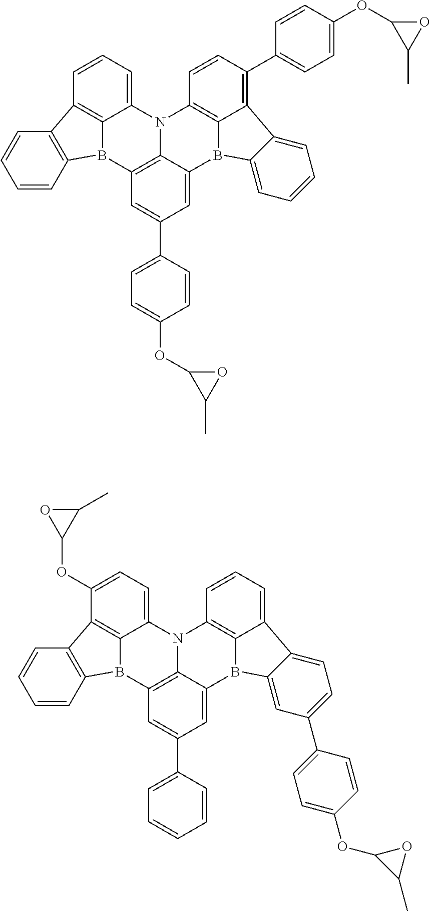 [SMILES: CC1OC1Oc1ccc(-c2cc3c4c(c2)B2c5ccccc5-c5c(-c6ccc(OC7OC7C)cc6)ccc(c52)N4c2cccc4c2B3c2ccccc2-4)cc1 ; CC1OC1Oc1ccc(-c2ccc3c(c2)B2c4cc(-c5ccccc5)cc5c4N(c4cccc-3c42)c2ccc(OC3OC3C)c3c2B5c2ccccc2-3)cc1]

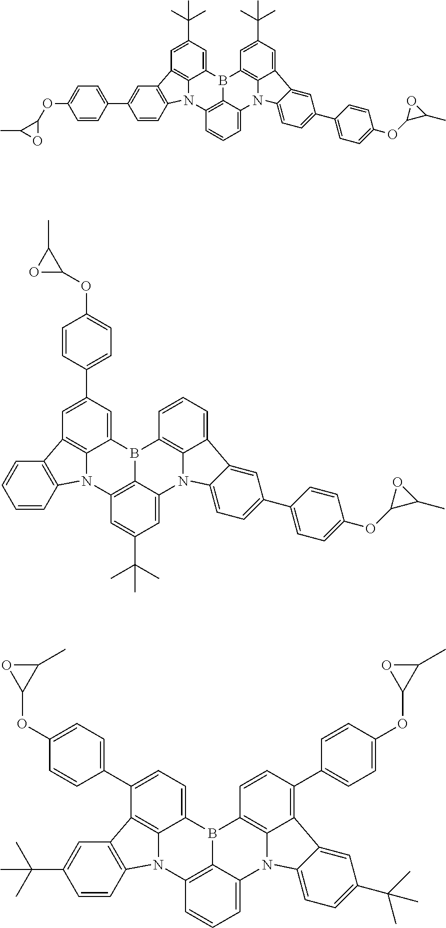

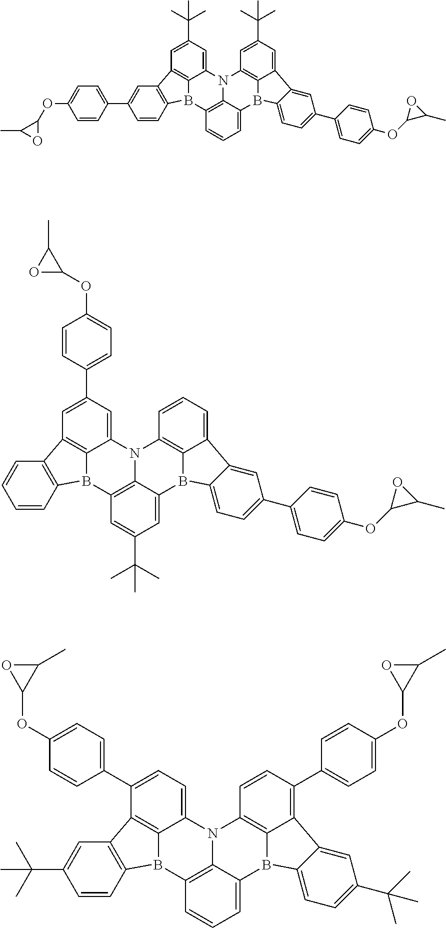

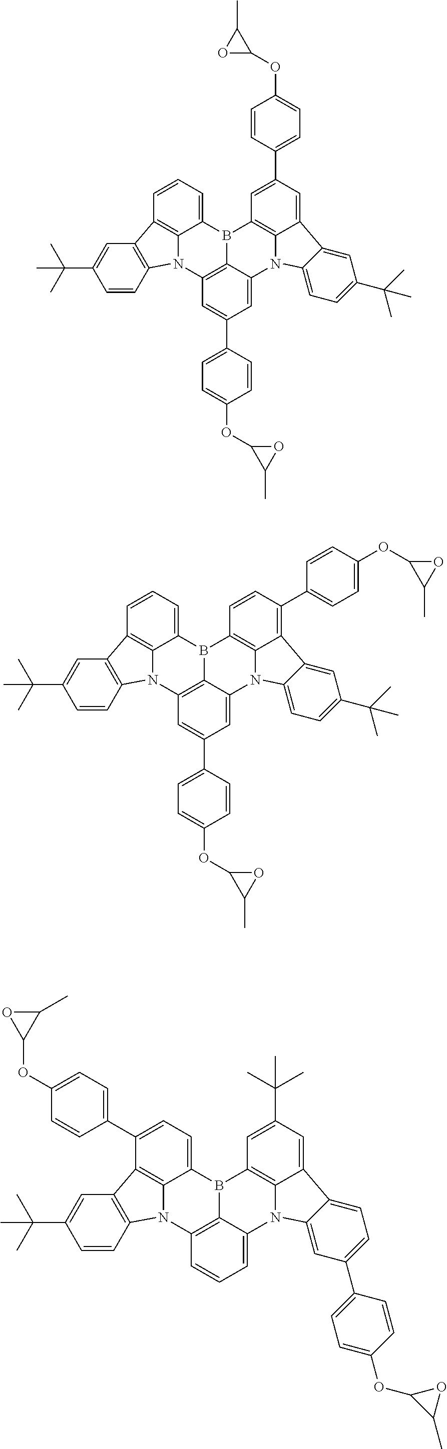

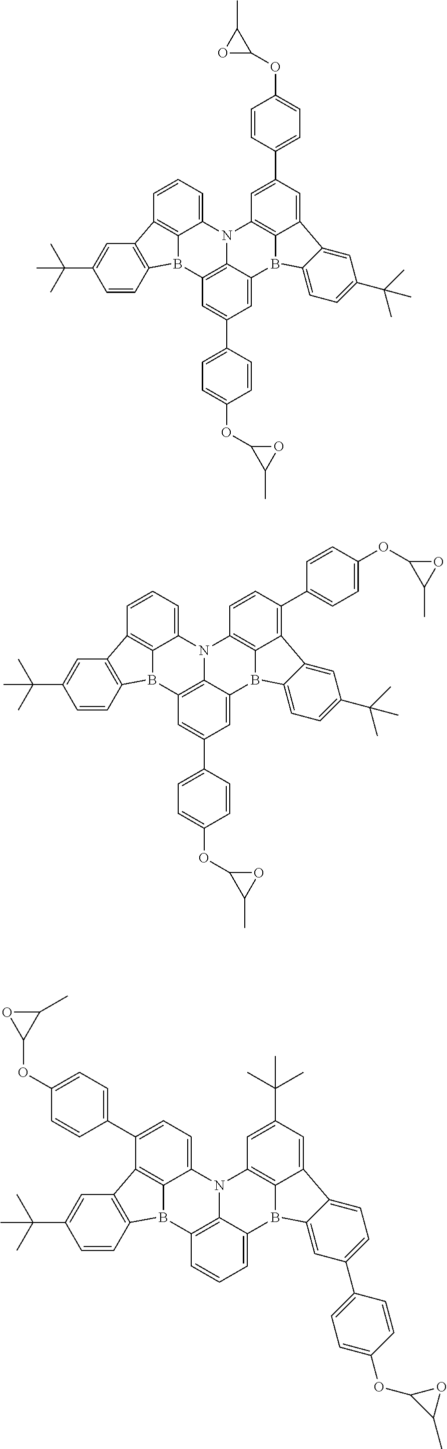

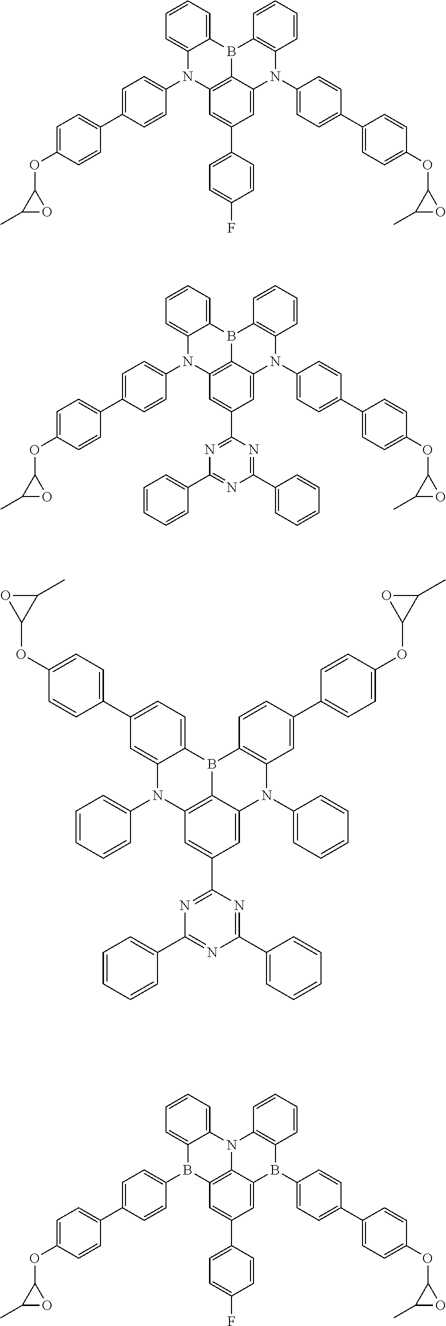

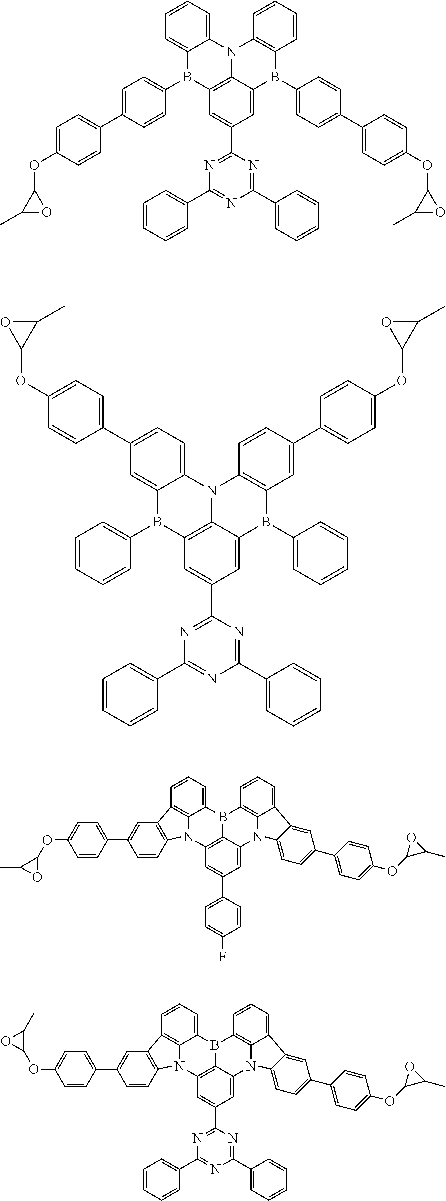

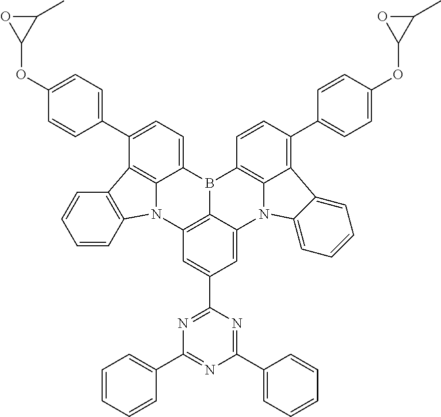 [SMILES: CC1OC1Oc1ccc(-c2ccc3c4c2c2ccccc2n4-c2cc(-c4nc(-c5ccccc5)nc(-c5ccccc5)n4)cc4c2B3c2ccc(-c3ccc(OC5OC5C)cc3)c3c5ccccc5n-4c23)cc1]

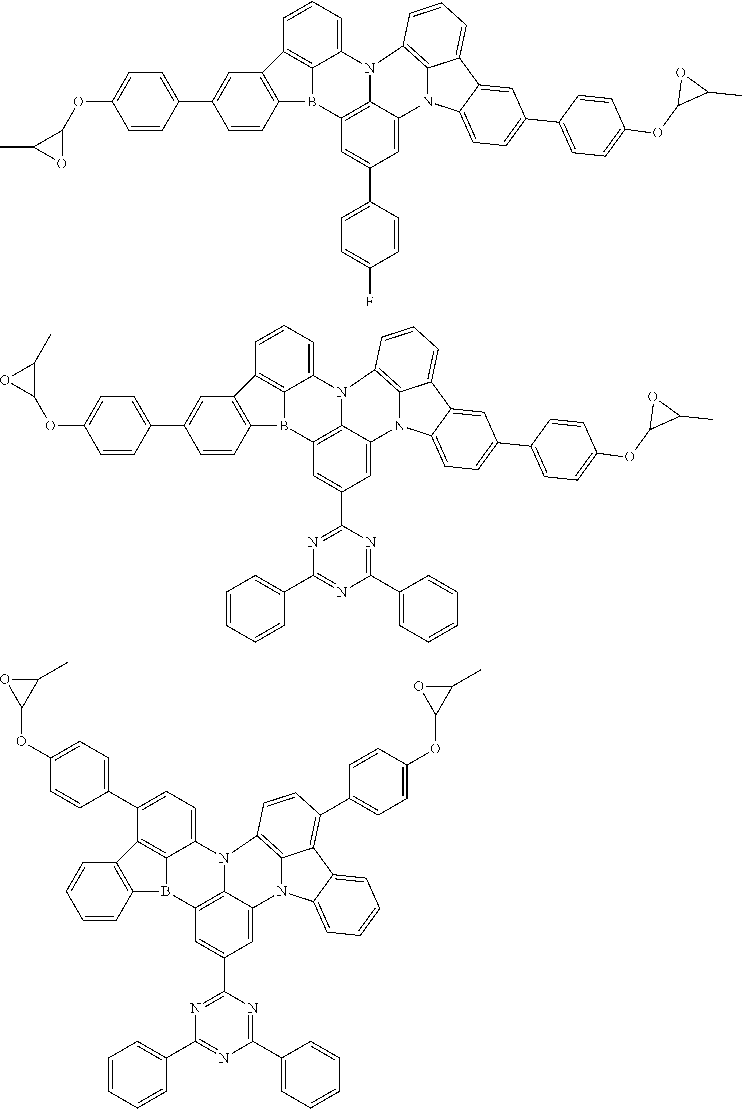

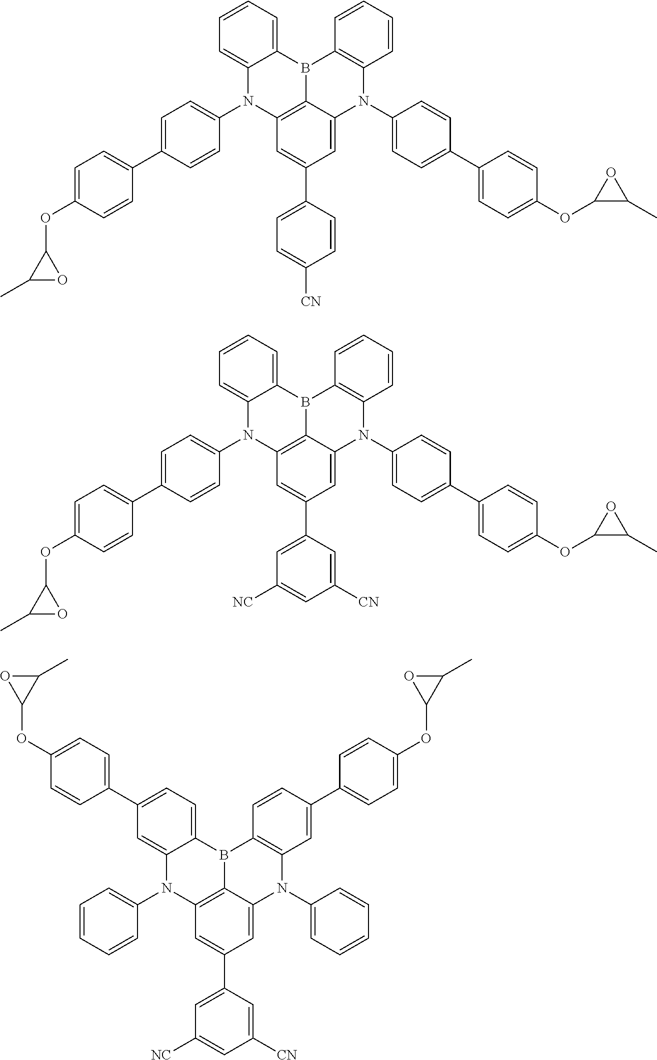

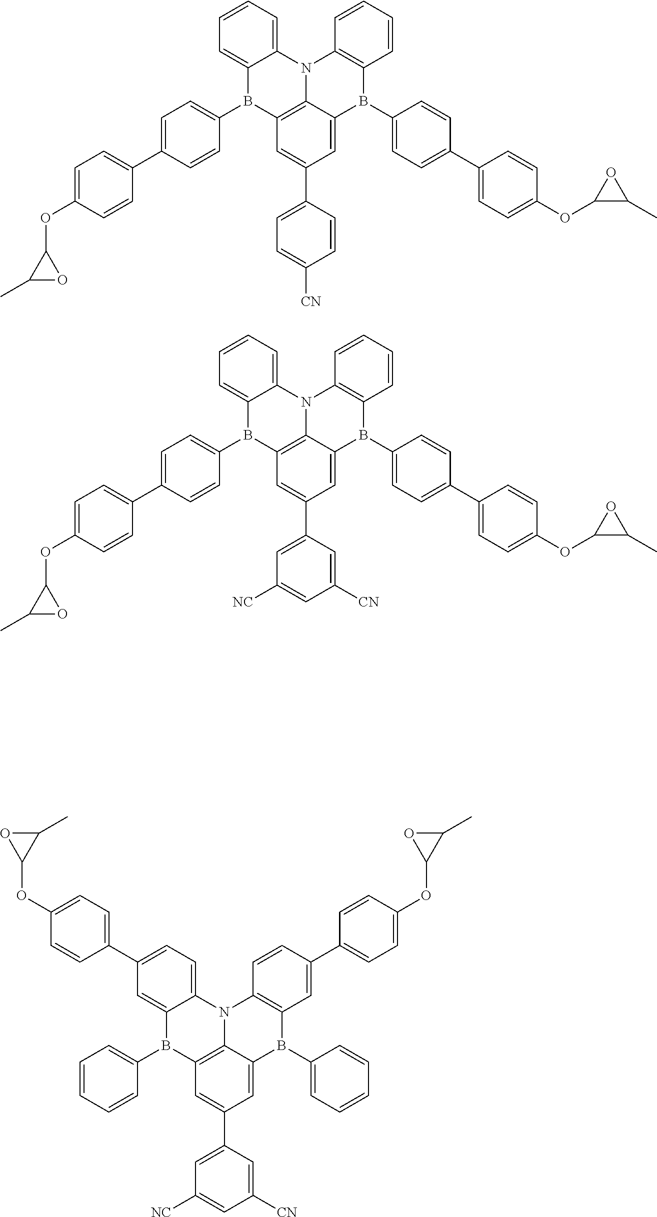

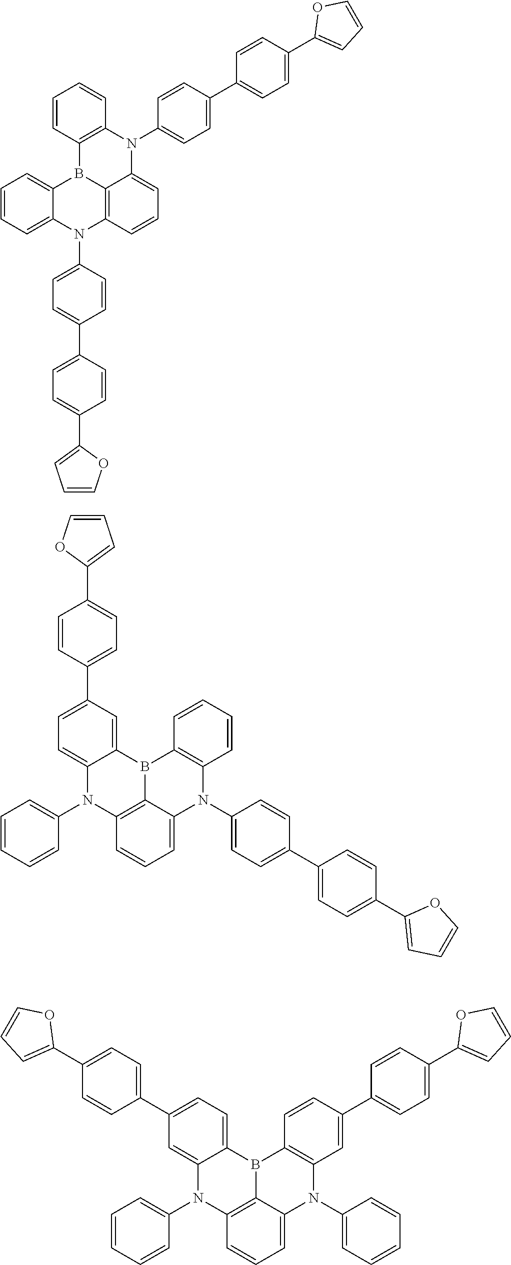

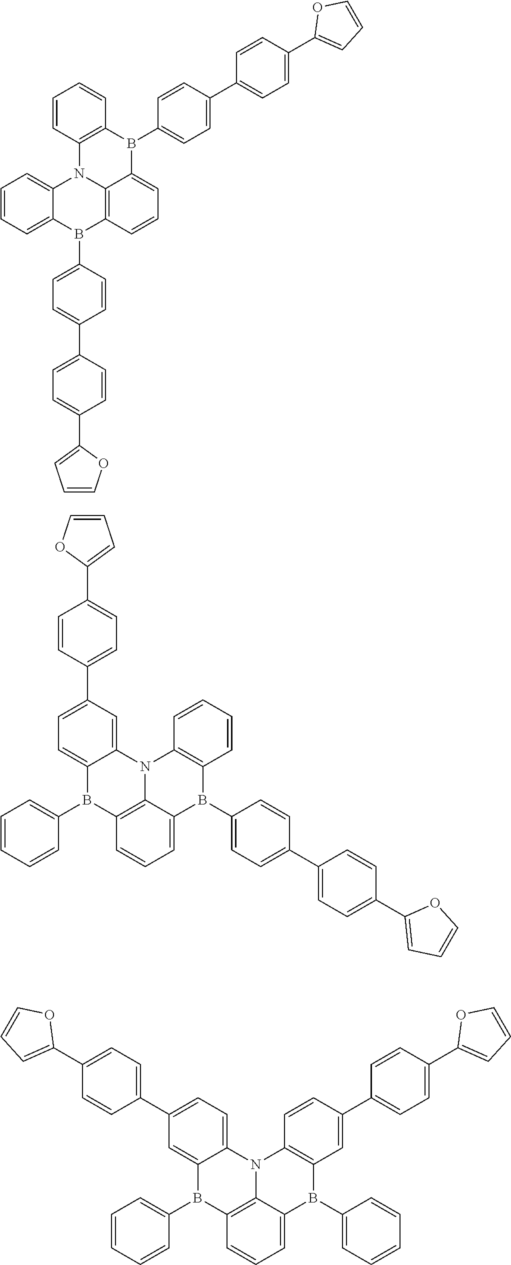

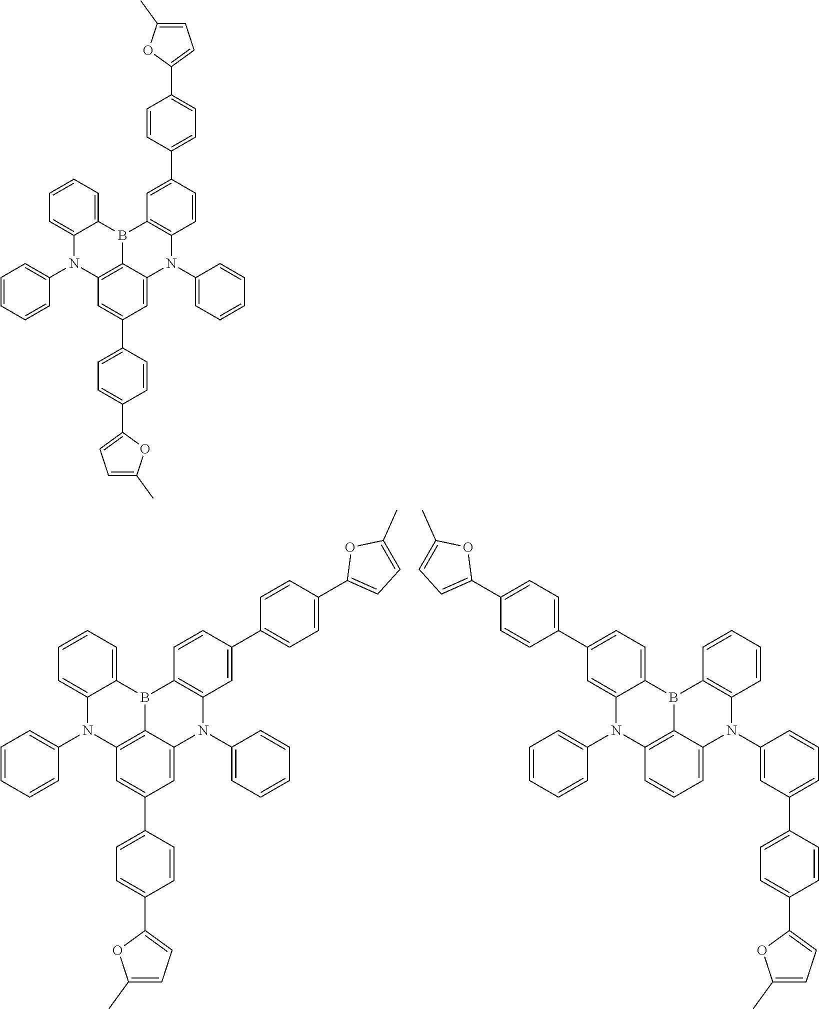

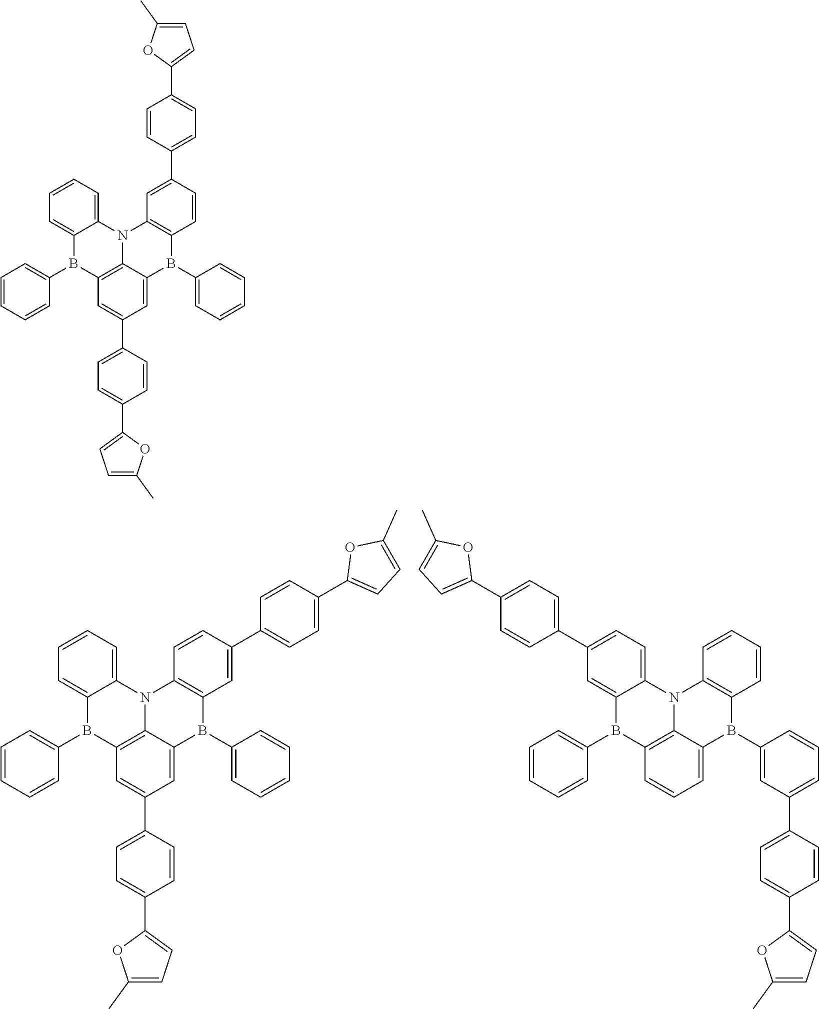

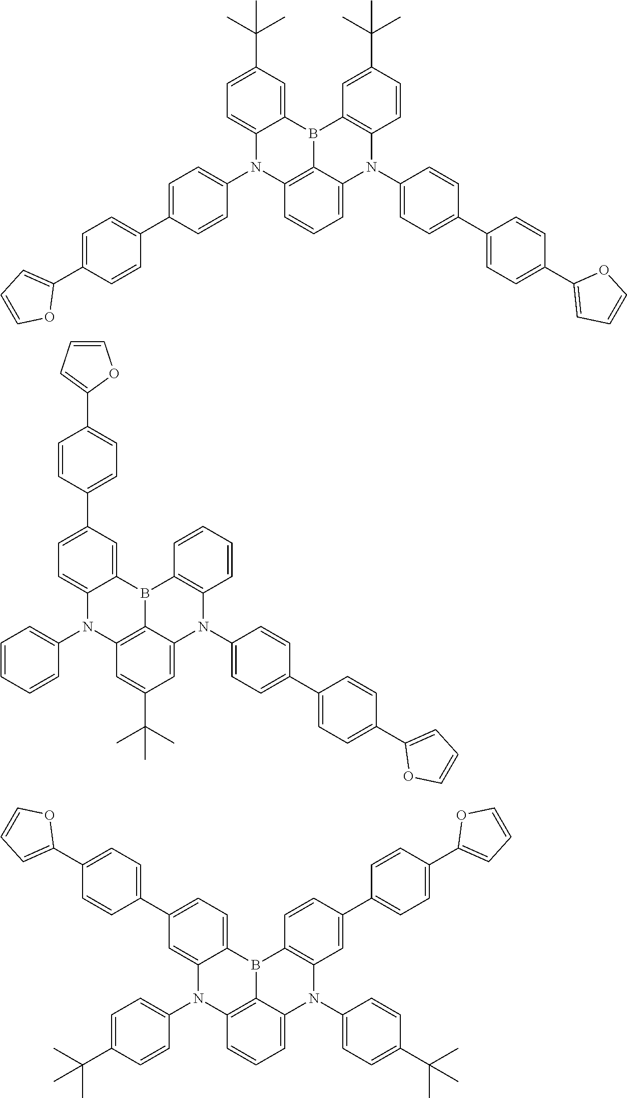

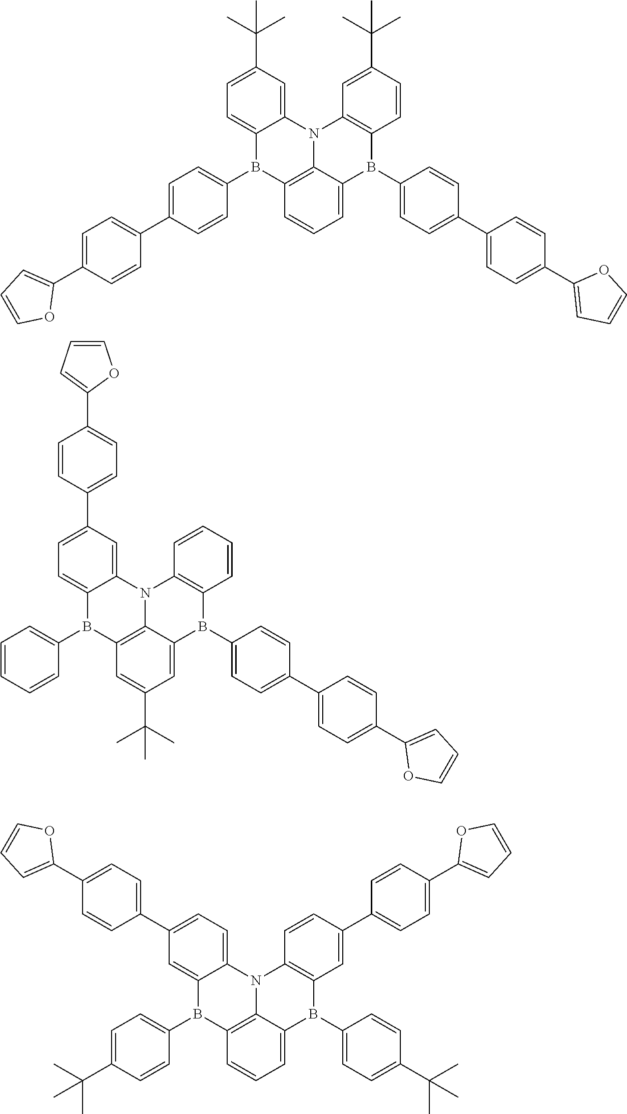

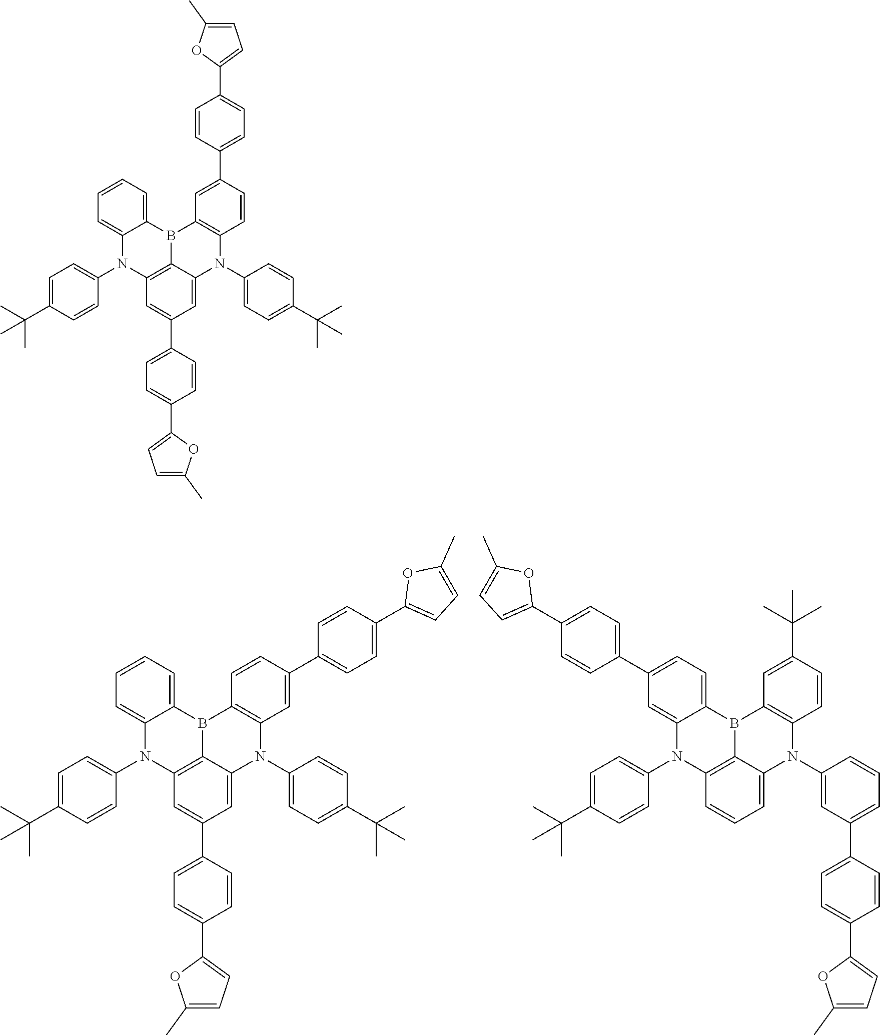

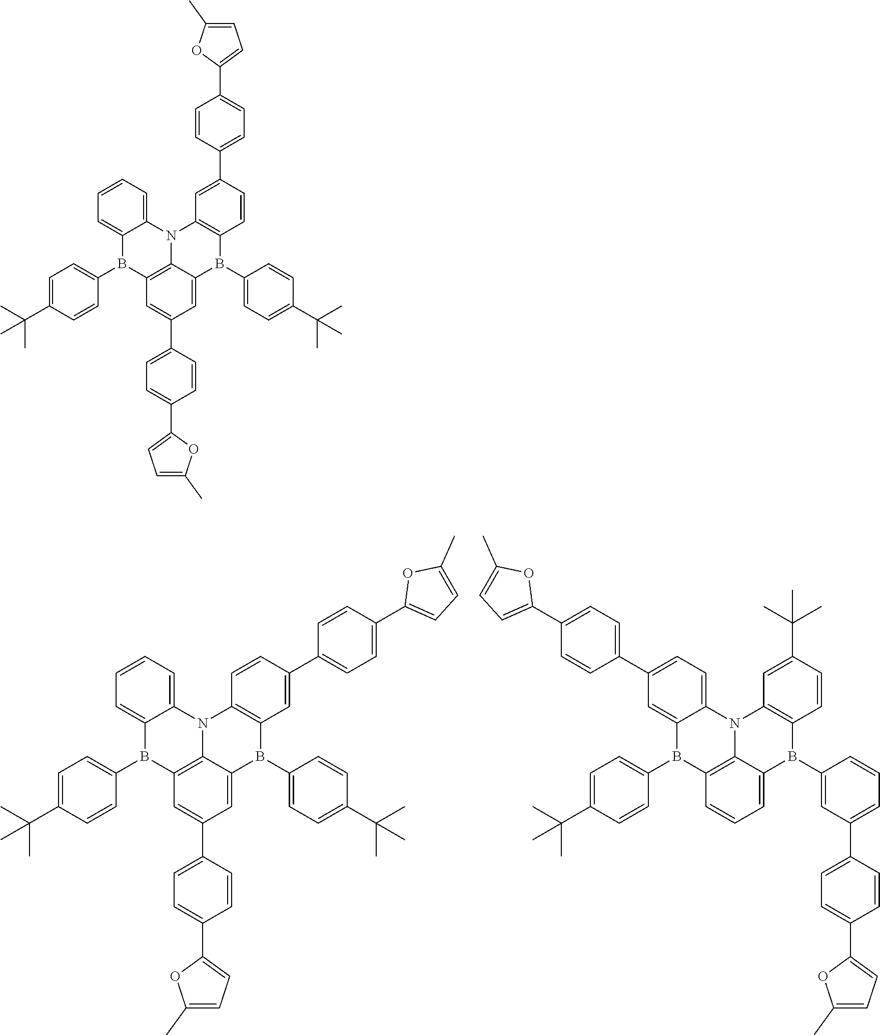

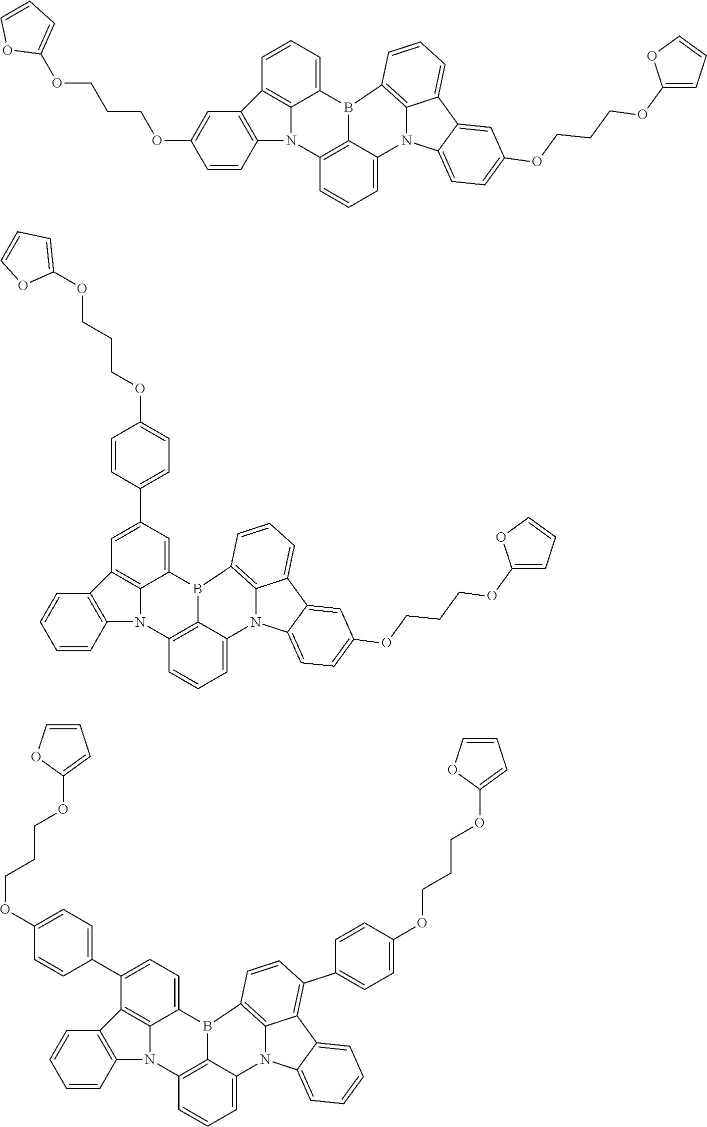 [SMILES: c1coc(OCCCOc2ccc3c(c2)c2cccc4c2n3-c2cccc3c2B4c2cccc4c5cc(OCCCOc6ccco6)ccc5n-3c24)c1 ; c1coc(OCCCOc2ccc(-c3cc4c5c(c3)c3ccccc3n5-c3cccc5c3B4c3cccc4c6cc(OCCCOc7ccco7)ccc6n-5c34)cc2)c1 ; c1coc(OCCCOc2ccc(-c3ccc4c5c3c3ccccc3n5-c3cccc5c3B4c3ccc(-c4ccc(OCCCOc6ccco6)cc4)c4c6ccccc6n-5c34)cc2)c1]

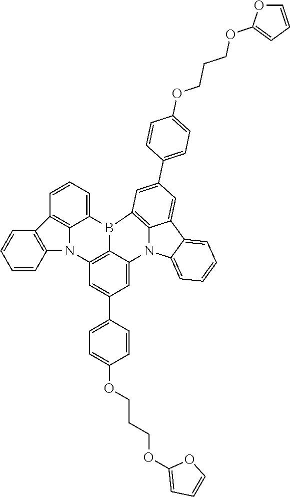 [SMILES: c1coc(OCCCOc2ccc(-c3cc4c5c(c3)-n3c6ccccc6c6cc(-c7ccc(OCCCOc8ccco8)cc7)cc(c63)B5c3cccc5c6ccccc6n-4c35)cc2)c1]

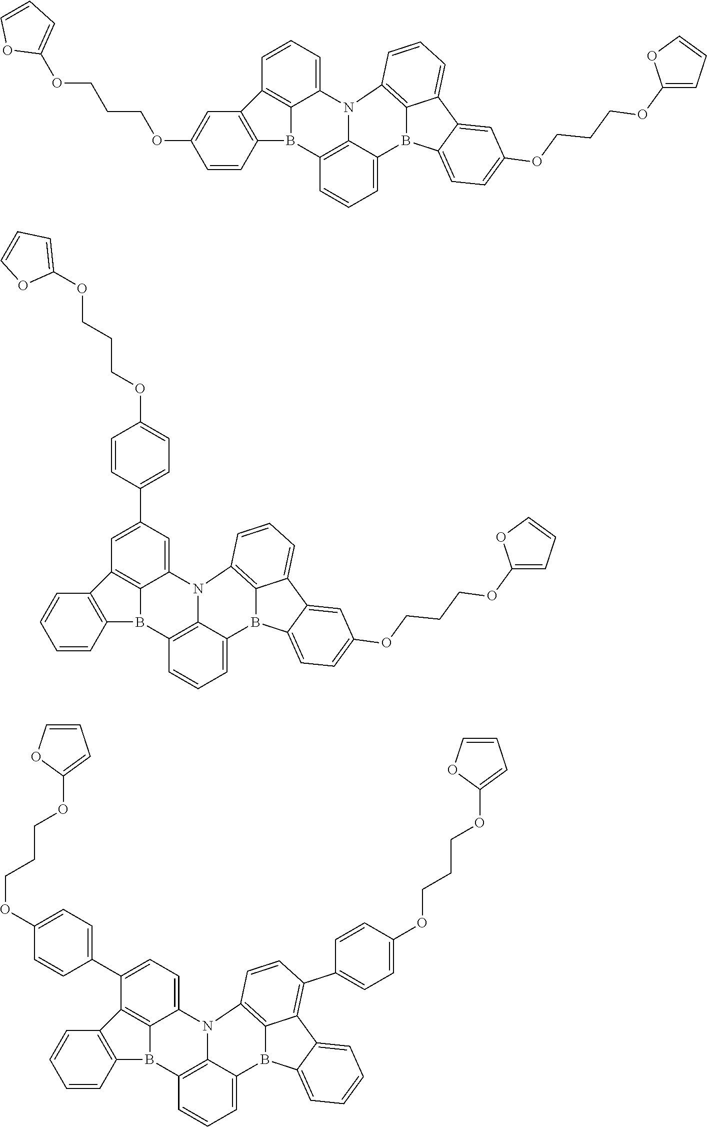 [SMILES: c1coc(OCCCOc2ccc3c(c2)-c2cccc4c2B3c2cccc3c2N4c2cccc4c2B3c2ccc(OCCCOc3ccco3)cc2-4)c1 ; c1coc(OCCCOc2ccc(-c3cc4c5c(c3)N3c6cccc7c6B(c6ccc(OCCCOc8ccco8)cc6-7)c6cccc(c63)B5c3ccccc3-4)cc2)c1 ; c1coc(OCCCOc2ccc(-c3ccc4c5c3-c3ccccc3B5c3cccc5c3N4c3ccc(-c4ccc(OCCCOc6ccco6)cc4)c4c3B5c3ccccc3-4)cc2)c1]

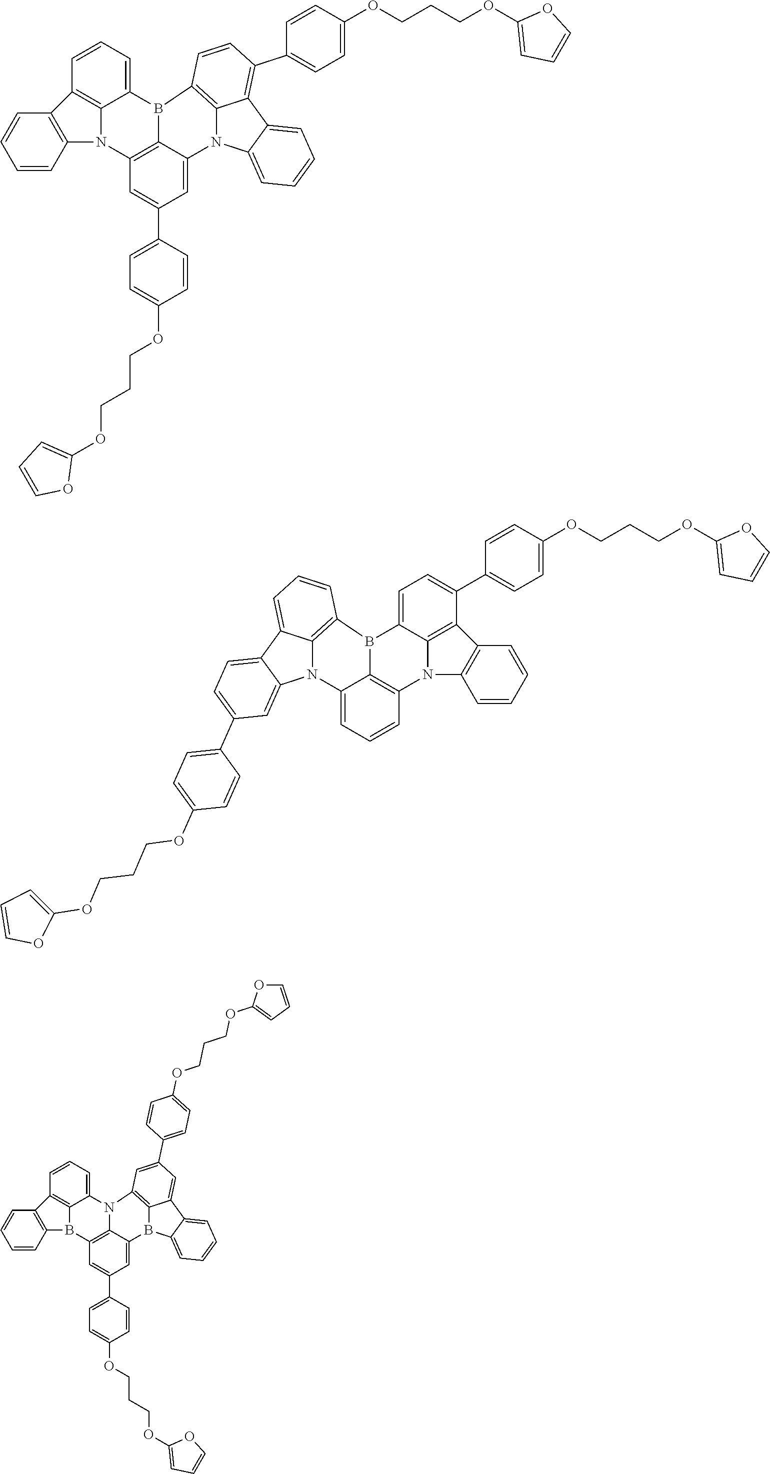 [SMILES: c1coc(OCCCOc2ccc(-c3cc4c5c(c3)-n3c6ccccc6c6c(-c7ccc(OCCCOc8ccco8)cc7)ccc(c63)B5c3cccc5c6ccccc6n-4c35)cc2)c1 ; c1coc(OCCCOc2ccc(-c3ccc4c5cccc6c5n(c4c3)-c3cccc4c3B6c3ccc(-c5ccc(OCCCOc6ccco6)cc5)c5c6ccccc6n-4c35)cc2)c1 ; c1coc(OCCCOc2ccc(-c3cc4c5c(c3)B3c6ccccc6-c6cc(-c7ccc(OCCCOc8ccco8)cc7)cc(c63)N5c3cccc5c3B4c3ccccc3-5)cc2)c1]

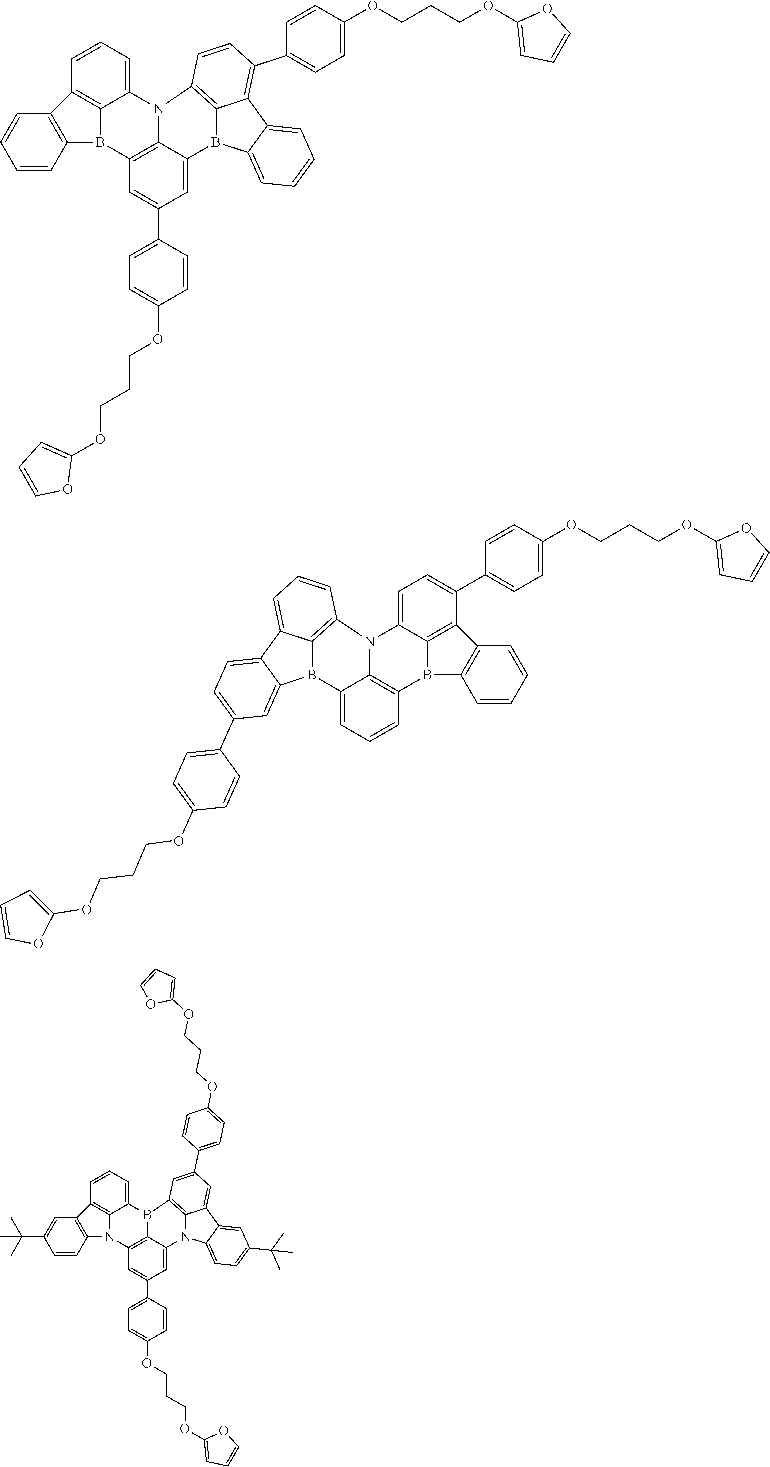 [SMILES: c1coc(OCCCOc2ccc(-c3cc4c5c(c3)B3c6ccccc6-c6c(-c7ccc(OCCCOc8ccco8)cc7)ccc(c63)N5c3cccc5c3B4c3ccccc3-5)cc2)c1 ; c1coc(OCCCOc2ccc(-c3ccc4c(c3)B3c5cccc6c5N(c5cccc-4c53)c3ccc(-c4ccc(OCCCOc5ccco5)cc4)c4c3B6c3ccccc3-4)cc2)c1 ; CC(C)(C)c1ccc2c(c1)c1cccc3c1n2-c1cc(-c2ccc(OCCCOc4ccco4)cc2)cc2c1B3c1cc(-c3ccc(OCCCOc4ccco4)cc3)cc3c4cc(C(C)(C)C)ccc4n-2c13]

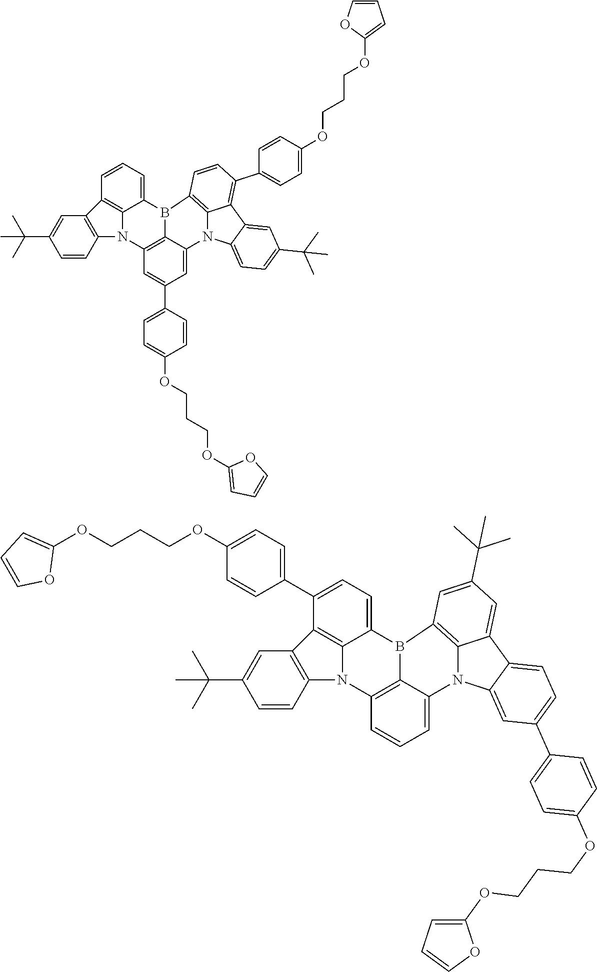

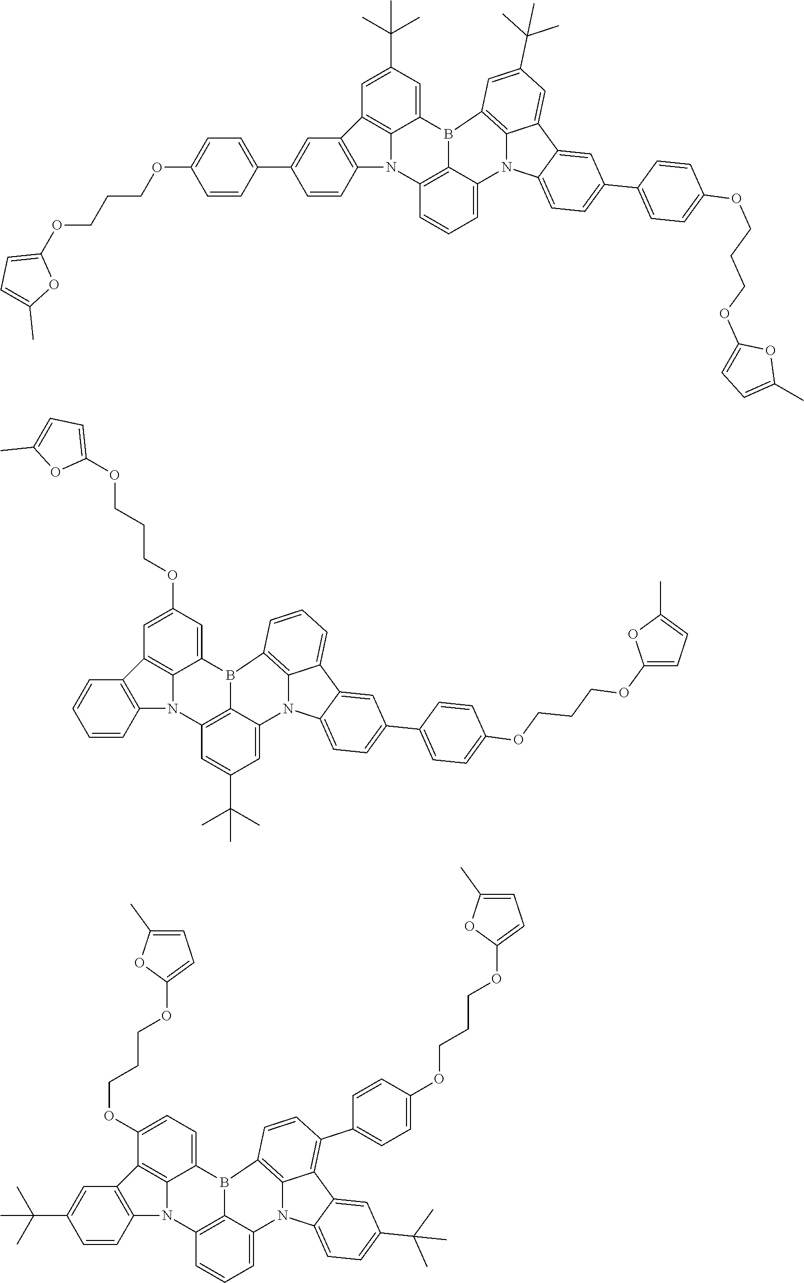

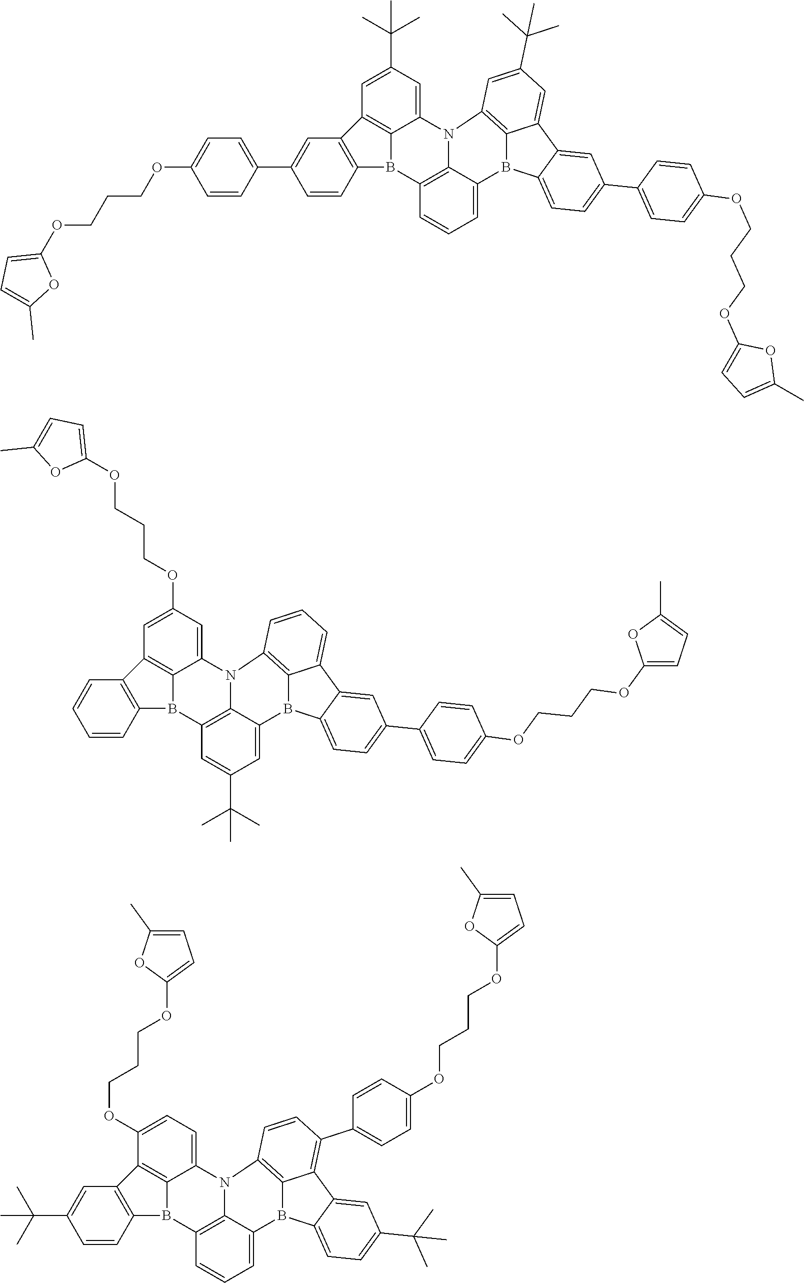

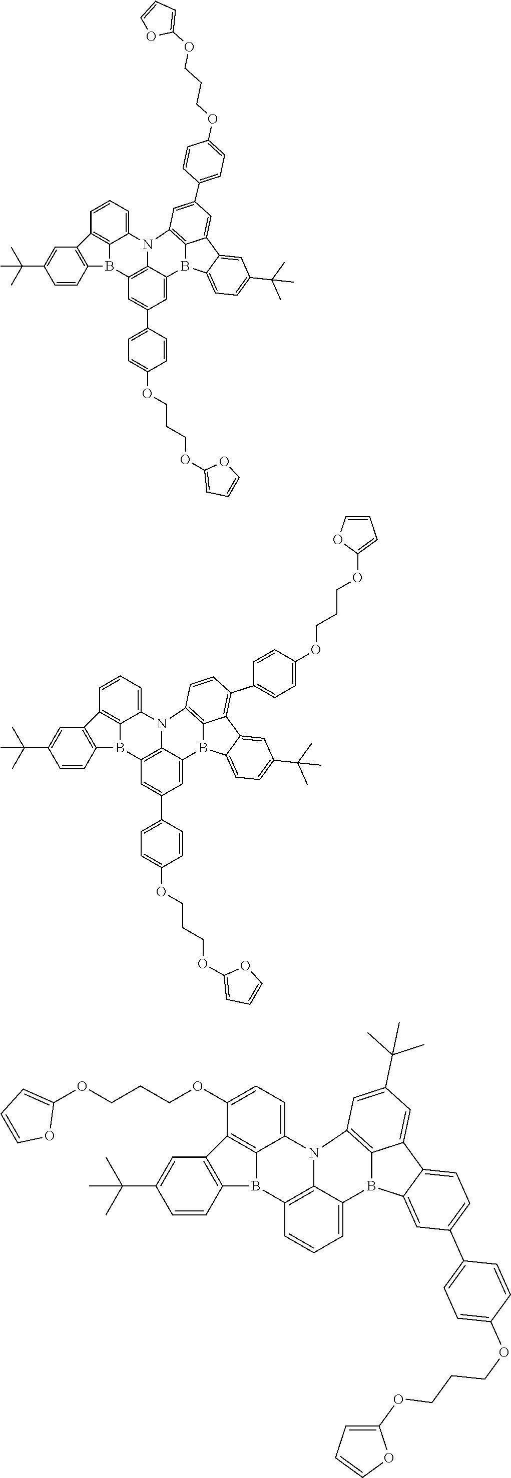 [SMILES: CC(C)(C)c1ccc2c(c1)-c1cccc3c1B2c1cc(-c2ccc(OCCCOc4ccco4)cc2)cc2c1N3c1cc(-c3ccc(OCCCOc4ccco4)cc3)cc3c1B2c1ccc(C(C)(C)C)cc1-3 ; CC(C)(C)c1ccc2c(c1)-c1cccc3c1B2c1cc(-c2ccc(OCCCOc4ccco4)cc2)cc2c1N3c1ccc(-c3ccc(OCCCOc4ccco4)cc3)c3c1B2c1ccc(C(C)(C)C)cc1-3 ; CC(C)(C)c1ccc2c(c1)-c1c(OCCCOc3ccco3)ccc3c1B2c1cccc2c1N3c1cc(C(C)(C)C)cc3c1B2c1cc(-c2ccc(OCCCOc4ccco4)cc2)ccc1-3]

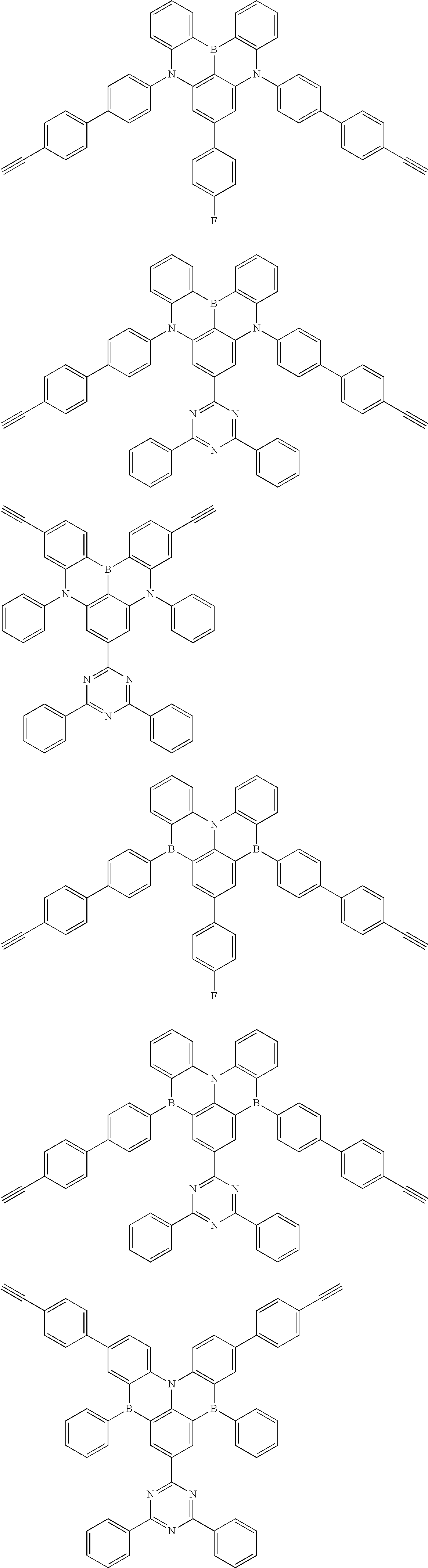

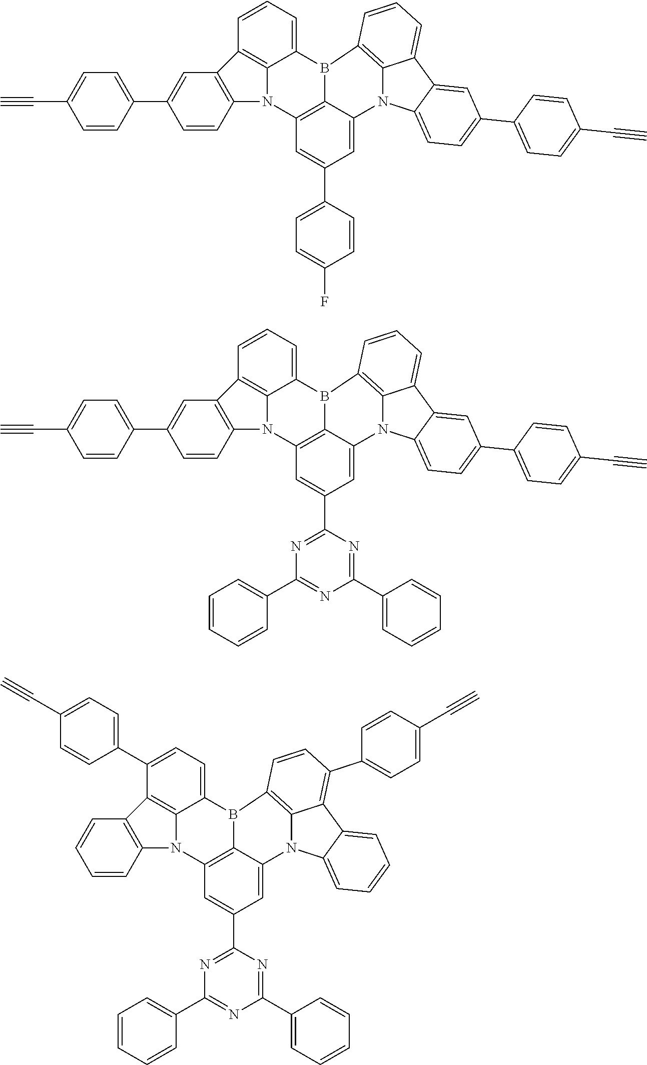

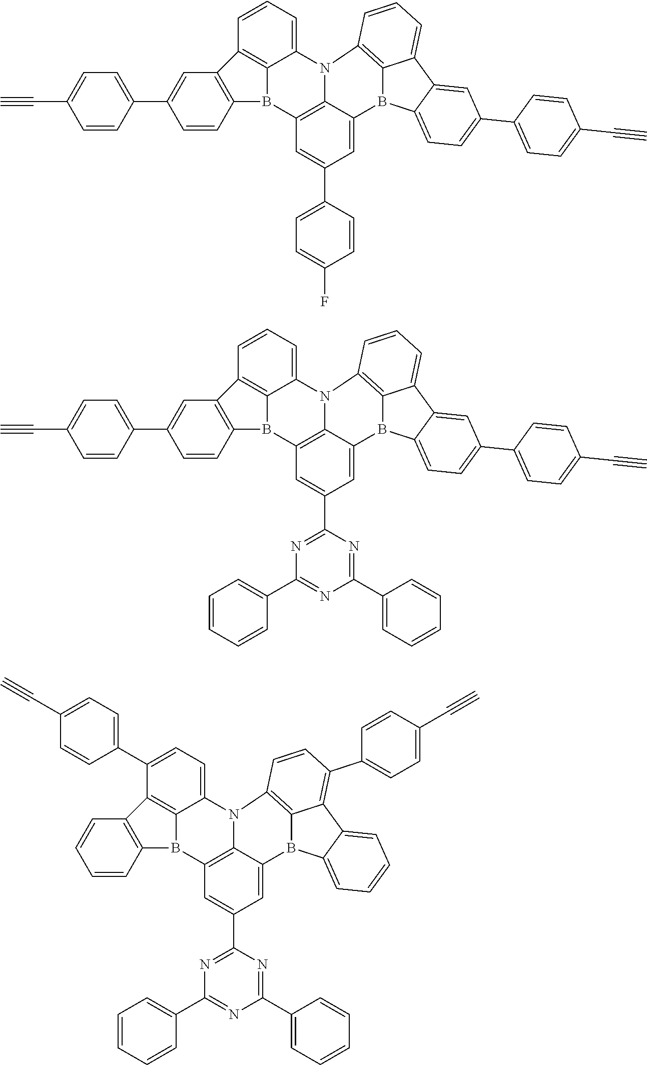

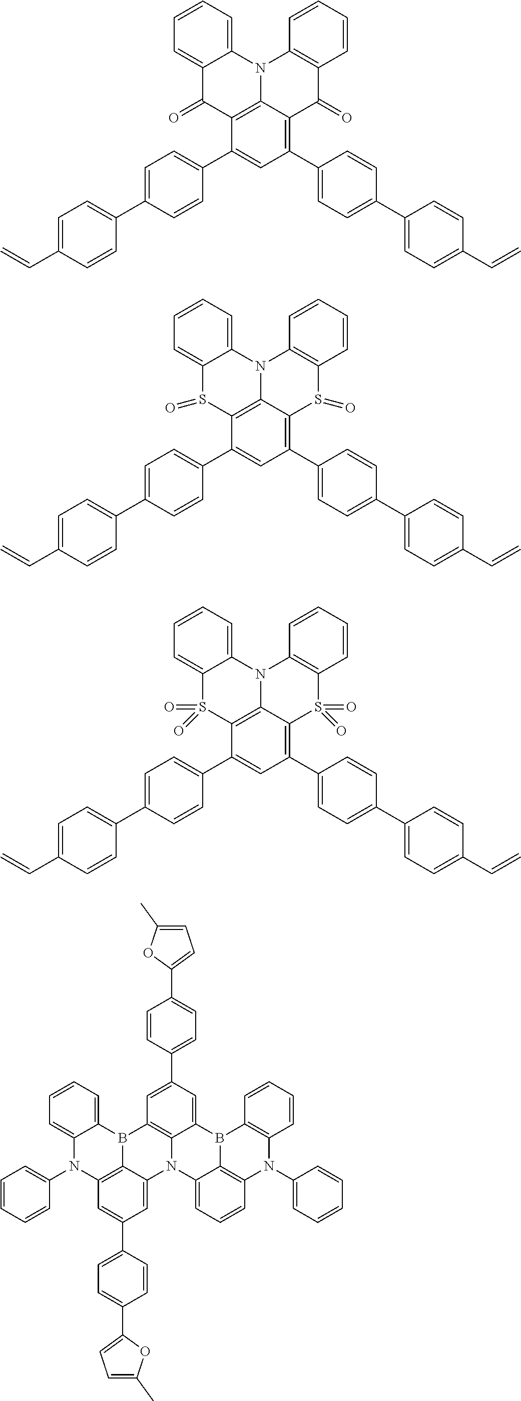

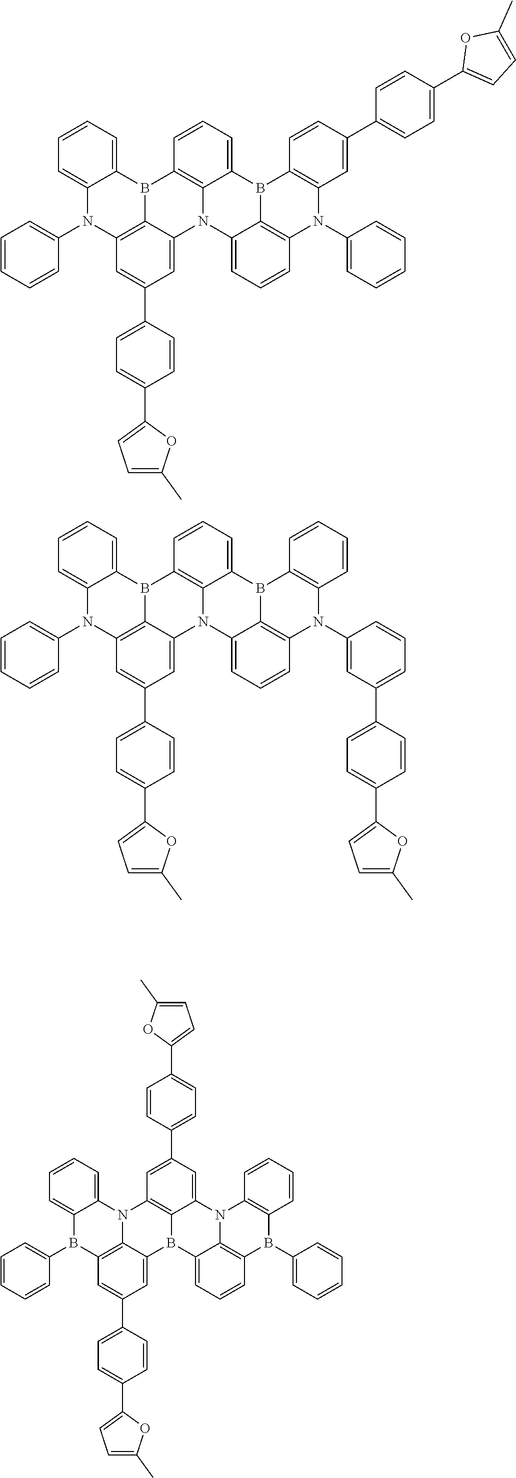

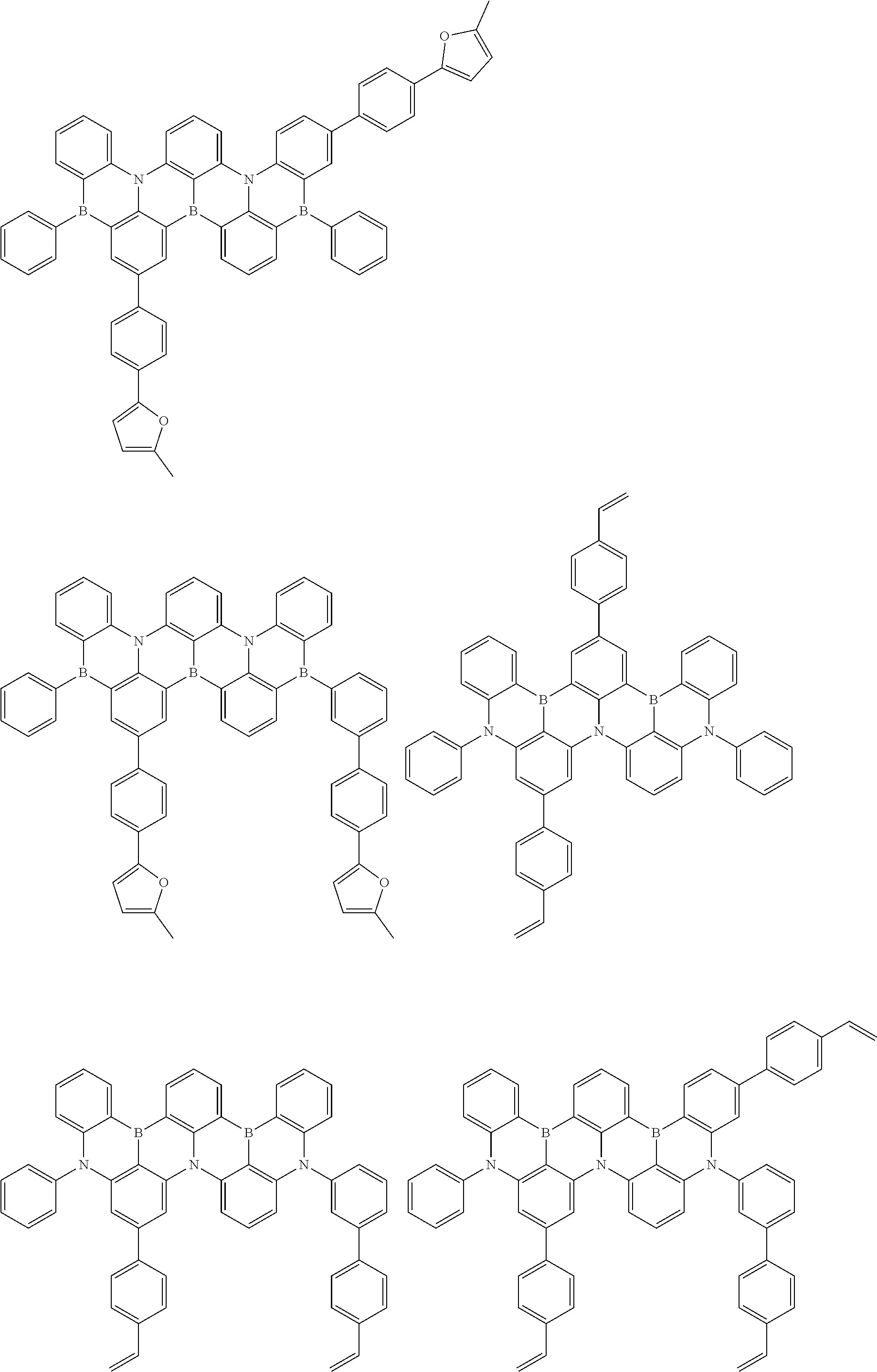

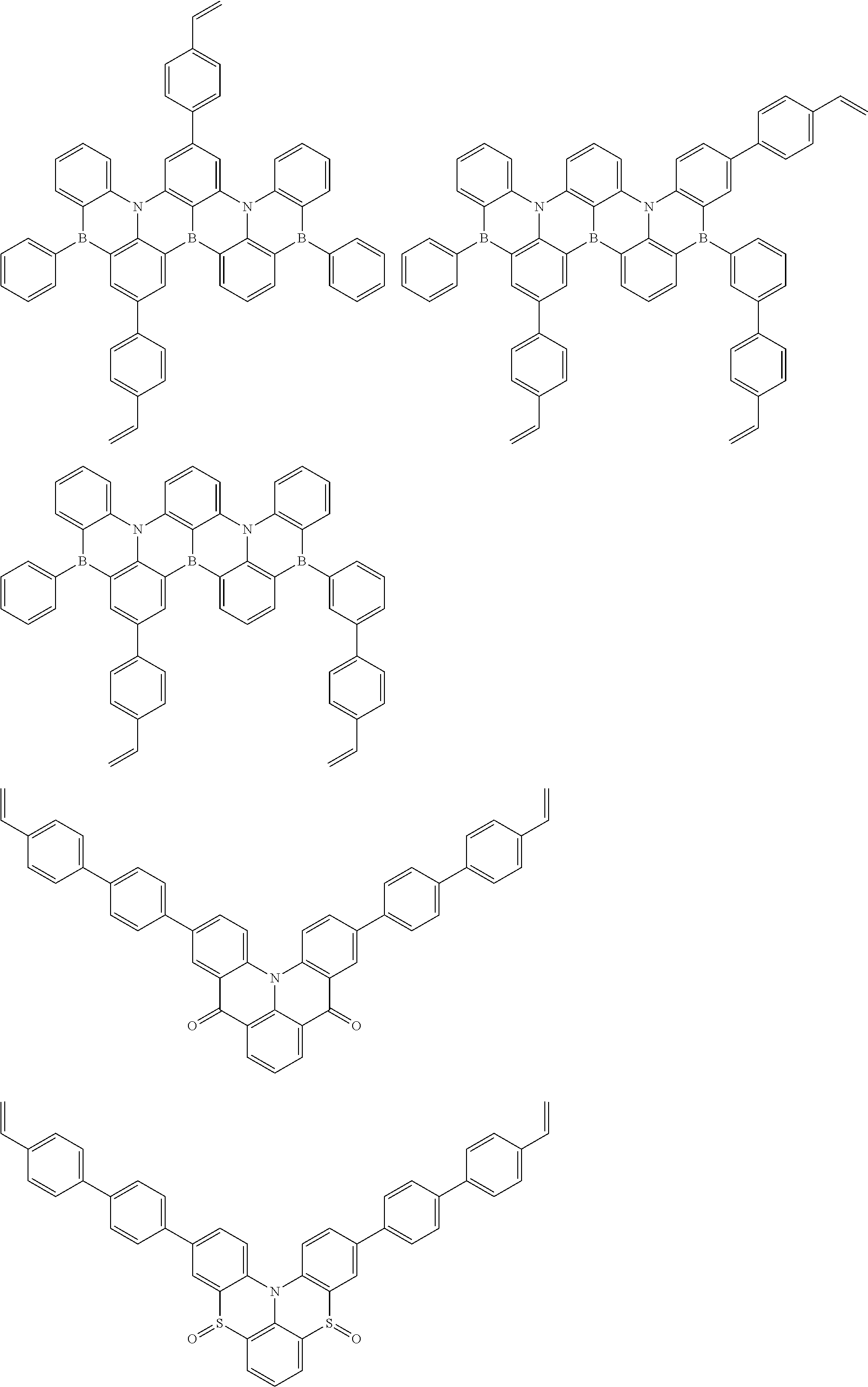

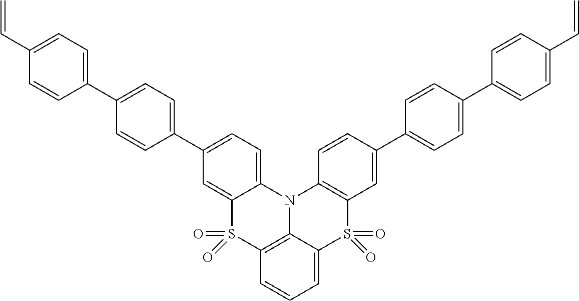 [SMILES: C=Cc1ccc(-c2ccc(-c3ccc4c(c3)S(=O)(=O)c3cccc5c3N4c3ccc(-c4ccc(-c6ccc(C=C)cc6)cc4)cc3S5(=O)=O)cc2)cc1]

In another aspect, the present disclosure also provides a method for the synthesis of organic compound according to the formula (1) or (2), wherein feedstocks containing active groups are used to carry out the reaction. These active feedstocks comprise at least one leaving group, such as bromine, iodine, boronic acid, or boronic ester. The appropriate reactions for forming C—C coupling are familiar to the person skilled in the art and are described in the literature, particularly appropriate and preferred coupling reactions are the SUZUKI, STILLE, Hartwig, and HECK coupling.

In yet another aspect, the present disclosure further provides a mixture, comprising at least one compound as described above and another organic functional material. The another organic functional material is selected from the group consisting of a hole-injection material (HIM), a hole-transport material (HTM), a hole-blocking material (HBM), an electron-injection material (EIM), an electron-transport material (ETM), an electron-blocking material (EBM), an organic host material (Host), a singlet emitting material (fluorescent emitting material), a triplet emitting material (phosphorescent emitting material), a thermally activated delayed fluorescence material (TADF material), and an organic dye. These organic functional materials are described in details, for example, in WO2010135519A1, US20090134784A1, and WO201110277A1. The entire contents of the these three documents are incorporated herein for reference.

In some embodiments, the mixture comprises an organic compound as described herein and a fluorescent host material (or singlet host material). The organic compound as described herein can be used here as dopant with the weight percentage ≤15 wt %, preferably 12 wt %, more preferably ≤9 wt %, particularly preferably 8 wt %, and most preferably 7 wt %.

In some embodiments, the mixture comprises an organic compound as described herein, another fluorescent emitter (or singlet emitter), and a fluorescent host material. In this embodiment, the organic compound as described herein can be used as co-emitter, and the weight ratio of which to another fluorescent emitter ranges from 1:20 to 20:1.

In yet another aspect, the present disclosure further provides another mixture, comprising at least one organic compound as described above and a polymer/an organic resin. The polymer or the organic resin can be selected from the group consisting of polyethylene, polypropylene, polystyrene, polycarbonate, polyacrylate, polyvinylpyrrolidone, polyvinyl alcohol, polyvinyl acetate, polyethylene glycol, polysiloxane, polyacrylonitrile, polyvinyl chloride, polyvinylidene chloride, polyethylene terephthalate, polybutylene terephthalate, polyvinyl butyrate, polyamide, polyoxymethylene, polyimide, polyether-ether-ketone, polysulfone, polyarylether, polyaramide, cellulose, modified cellulose, acetate fiber, nitrocellulose, and mixtures thereof.

For the purposes of the present disclosure, the organic resin refers to a resin prepolymer, or a resin formed after the prepolymer is crosslinked or cured.

The suitable organic resins of the present disclosure include, but not limited to: polystyrene, polyacrylate, polymethacrylate, polycarbonate, polyurethane, polyvinylpyrrolidone, polyvinyl acetate, polybutene, polyethylene glycol, polysiloxane, epoxy resin, polyvinyl alcohol, polyacrylonitrile, polyvinylidene chloride(PVDC), polystyrene-acrylonitrile(SAN), polybutylene terephthalate(PBT), polyethylene terephthalate(PET), polyvinyl butyrate(PVB), polyvinyl chloride(PVC), polyamide, polyoxymethylene, polyimide, polyetherimide, and mixtures thereof.

Further, the suitable organic resins of the present disclosure include, but not limited to, those formed by homopolymerization or copolymerization of the following monomers (resin prepolymers): styrene derivatives, acrylate derivatives, acrylonitrile derivatives, acrylamide derivatives, vinyl ester derivatives, vinyl ether derivatives, maleimide derivatives, conjugated diene derivatives.

Examples of styrene derivatives include, but not limited to alkylstyrenes, such as α-methylstyrene, o-, m-, p-methylstyrene, p-butylstyrene, especially 4-tert-butylstyrene, alkoxystyrene, such as p-methoxystyrene, p-butoxystyrene, p-tert-butoxystyrene.

Examples of acrylate derivatives include, but not limited to methyl acrylate, methyl methacrylate, ethyl acrylate, ethyl methacrylate, n-propyl acrylate, n-propyl methacrylate, isopropyl acrylate, isopropyl methacrylate, n-butyl acrylate, n-butyl methacrylate, isobutyl acrylate, isobutyl methacrylate, sec-butyl acrylate, sec-butyl methacrylate, tert-butyl acrylate, tert-butyl methacrylate, 2-hydroxyethyl acrylate, 2-hydroxyethyl methacrylate, 2-hydroxypropyl acrylate, 2-hydroxypropyl methacrylate, 3-hydroxypropyl acrylate, 3-hydroxypropyl methacrylate, 2-hydroxybutyl acrylate, 2-hydroxybutyl methacrylate, 3-hydroxybutyl acrylate, 3-hydroxybutyl methacrylate, 4-hydroxybutyl acrylate, 4-hydroxybutyl methacrylate, allyl acrylate, allyl methacrylate, benzyl acrylate, benzyl methacrylate, cyclohexyl acrylate, cyclohexyl methacrylate, phenyl acrylate, phenyl methacrylate, 2-methoxyethyl acrylate, 2-methoxyethyl methacrylate, 2-phenoxyethyl acrylate, 2-phenoxyethyl methacrylate, methoxydiethylene glycol acrylate, methoxydiethylene glycol methacrylate, methoxytriethylene glycol acrylate, methoxytriethylene glycol methacrylate, methoxypropylene glycol acrylate, methoxypropylene glycol methacrylate, methoxy dipropylene glycol acrylate, methoxydipropylene glycol methacrylate, isobornyl acrylate, isobornyl methacrylate, dicyclopentadiene acrylate, dicyclopentadiene methacrylate, adamantane (meth) acrylate, norbornene (meth) acrylate, 2-hydroxy-3-phenoxypropyl acrylate, 2-hydroxy-3-phenoxypropyl methacrylate, glyceryl monoacrylate, glyceryl monostearate, 2-aminoethyl acrylate, 2-aminoethyl methacrylate, 2-dimethylaminoethyl acrylate, 2-dimethylaminoethyl methacrylate, N,N-dimethylaminoethyl(meth) acrylic acid, N,N-diethylaminoethyl (meth) acrylate, 2-aminopropyl acrylate, 2-aminopropyl methacrylate, 2-dimethylaminopropyl acrylate, 2-dimethylaminopropyl methacrylate, 3-aminopropyl acrylate, 3-aminopropyl methacrylate, N, N-dimethyl-1,3-propane diamine (meth) acrylate, 3-dimethylaminopropyl acrylate, 3-dimethylaminopropyl methacrylate, glycidyl acrylate, and glycidyl methacrylate.

Examples of acrylonitrile derivatives include, but not limited to acrylonitrile, methacrylonitrile, α-chloroacrylonitrile, and vinylidene cyanide.

Examples of acrylamide derivatives include, but not limited to acrylamide, methacrylamide, α-chloroacrylamide, N-2-hydroxyethyl acrylamide, and N-2-hydroxyethyl methacrylamide.

Examples of vinyl ester derivatives include, but not limited to vinyl acetate, vinyl propionate, vinyl butyrate, and vinyl benzoate.

Examples of vinyl ether derivatives include, but not limited to vinyl methyl ether, vinyl ethyl ether, and allyl glycidyl ether.

Examples of maleimide derivatives include, but not limited to maleimide, benzylmaleimide, N-phenylmaleimide, and N-cyclohexylmaleimide.

Examples of conjugated diene derivatives include, but not limited to 1,3-butadiene, isoprene, and chloroprene.

The homopolymers or copolymers can be prepared by free radical polymerization, cationic polymerization, anionic polymerization, or organometallic catalytic polymerization (for example Ziegler-Natta catalysis). The process of polymerization can be suspension polymerization, emulsion polymerization, solution polymerization, or bulk polymerization.

The average molar mass Mn (as determined by GPC) of the organic resins is generally in the range from 10 000 to 1 000 000 g/mol, preferably in the range from 20 000 to 750 000 g/mol, more preferably in the range from 30 000 to 500 000 g/mol.

In some embodiments, the organic resin is a thermosetting resin or an UV curable resin. In some embodiments, the organic resin is cured by a method that will enable roll-to-roll processing.

Thermoset resins require curing in which they undergo an irreversible process of molecular cross-linking, which makes the resin non-fusible. In some embodiments, the thermosetting resin is an epoxy resin, a phenolic resin, a vinyl resin, a melamine resin, a urea-formaldehyde resin, an unsaturated polyester resin, a polyurethane resin, an allyl resin, an acrylic resin, a polyamide resin, a polyamide-imide resin, a phenol-amide polycondensation resin, an urea-melamine polycondensation resin, or combinations thereof.

In some embodiments, the thermosetting resin is an epoxy resin. The epoxy resins are easy to cure and do not give off volatiles or generate by-products from a wide range of chemicals. The epoxy resins can also be compatible with most substrates and tend to readily wet surfaces.

See also Boyle, M. A. et al., “Epoxy Resins”, Composites, Vol. 21, ASM Handbook, pages 78-89 (2001).

In some embodiments, the organic resin is a silicone thermosetting resin. In some embodiments, the silicone thermosetting resin is OE6630A or OE6630B (Dow Corning Corporation (Auburn, Mich.)).

In yet another aspect, the present disclosure further provides a formulation, comprising at least one compound or mixture as described above, and at least one organic solvent.

In some embodiments, the formulation as described herein is a solution.

In some embodiments, the formulation as described herein is a dispersion.

The formulation in embodiments of the present disclosure may comprise the organic compound of 0.01 to 20 wt %, preferably 0.1 to 20 wt %, more preferably 0.2 to 20 wt %, and most preferably 1 to 15 wt %.

Using the formulation as described herein can be fabricated to the color conversion layer by inkjet printing, transfer printing, photolithography, etc.. In this case, the color conversion material as described herein needs to be dissolved alone or together with other materials in an organic solvent, to form inks. The mass concentration of the color conversion material as described herein in the ink is not less than 0.1 wt %. The color conversion ability of the color conversion layer can be tuned by modifying the concentration of the color conversion material in the ink and the thickness of the color conversion layer. In general, the higher the concentration of the color conversion material or the thickness of the layer, the higher the color conversion efficiency of the color conversion layer would be.

Other materials that can be added into the ink include but not limited to the following materials: polyethylene, polypropylene, polystyrene, polycarbonate, polyacrylate, polyvinyl pyrrolidone, polyvinyl alcohol, polyvinyl acetate, polyethylene glycol, polysiloxane, polyacrylonitrile, polyvinyl chloride, polyvinylidene chloride, polyethylene terephthalate, polybutylene terephthalate, polyvinyl butyrate, polyamide, polyoxymethylene, polyimide, polyether-ether-ketone, polysulfone, polyarylether, polyaramide, cellulose, modified cellulose, acetate fiber, nitrocellulose, and mixtures thereof.

In some embodiments, in the formulation as described herein, the solvent is selected from the group consisting of aromatics, heteroaromatics, esters, aromatic ketones, aromatic ethers, aliphatic ketones, aliphatic ethers, alicyclics, olefins, inorganic ester compounds such as boronic esters and phosphoric esters, and mixtures of two or more of them.

In some embodiments, the formulation as described herein comprising at least 50 wt % of the aromatic or heteroaromatic solvent; preferably at least 80 wt %; particularly preferably at least 90 wt %.

Examples of aromatic or heteroaromatic solvents as described herein include, but not limited to: 1-tetralone, 3-phenoxytoluene, acetophenone, 1-methoxynaphthalene, p-diisopropylbenzene, amylbenzene, tetrahydronaphthalene, cyclohexylbenzene, chloronaphthalene, 1,4-dimethylnaphthalene, 3-isopropylbiphenyl, p-methylisopropylbenzene, dipentylbenzene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, 1-methylnaphthalene, 1,2,4-trichlorobenzene, 1,3-dipropoxybenzene, 4,4-difluorodiphenylmethane, diphenyl ether, 1,2-dimethoxy-4-(1-propenyl) benzene, diphenylmethane, 2-phenylpyridine, 3-phenylpyridine, 2-phenoxymethyl ether, 2-phenoxytetrahydrofuran, ethyl-2-naphthyl ether, N-methyldiphenylamine, 4-isopropylbiphenyl, α,α-dichlorodiphenylmethane, 4-(3-phenylpropyl)pyridine, benzyl benzoate, 1,1-bis(3,4-dimethylphenyl) ethane, 2-isopropylnaphthalene, dibenzyl ether, and the like.

In some embodiments, the suitable and preferred organic solvents include aliphatics, alicyclics, aromatics, amines, thiols, amides, nitriles, esters, ethers, polyethers, alcohols, diols, or polyols.

In some embodiments, the alcohol represents an organic solvent of the suitable class. The preferred alcohol includes alkylcyclohexanol, especially methylated aliphatic alcohol, naphthol, and the like.

The solvent can be a cycloalkane, such as decahydronaphthalene.

The solvent can be used alone or as a mixture of two or more organic solvents.

In some embodiments, the formulation as described herein comprises an organic functional compound as described above and at least one organic solvent, and further comprising another organic solvent. Examples of the another organic solvent include (but not limited to): methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4 dioxane, acetone, methyl ethyl ketone, 1,2 dichloroethane, 3-phenoxytoluene, 1,1,1-trichloroethane, 1,1,2,2-tetrachloroethane, ethyl acetate, butyl acetate, dimethylformamide, dimethylacetamide, dimethylsulfoxide, tetrahydronaphthalene, decalin, indene, and/or mixtures thereof.

In some embodiments, the particularly suitable solvent for the present disclosure is a solvent having Hansen solubility parameters in the following ranges: δ_{d} (dispersion force) is in the range of 17.0-23.2 MPa½, especially in the range of 18.5-21.0 MPa½. δₚ (polarity force) is in the range of 0.2-12.5 MPa½, especially in the range of 2.0-6.0 MPa½δₕ (hydrogen bonding force) is in the range of 0.9-14.2 MPa½, especially in the range of 2.0-6.0 MPa½.

In the formulation as described herein, the boiling point parameter of the organic solvent should be taken into account when selecting the organic solvent. In the present disclosure, the boiling points of the organic solvents usually ≥150° C.; preferably ≥180° C.; more preferably ≥200° C.; further more preferably ≥250° C.; and most preferably ≥275° C. or 300° C. The boiling points in these ranges are beneficial in terms for preventing nozzle clogging of the inkjet printhead. The organic solvent can be evaporated from the solution system to form a functional material film.

In some embodiments, the formulation as described herein, wherein:

1) the viscosity in the range of 1 cps to 100 cps at 25° C.; and

2) the surface tension in the range of 19 dyne/cm to 50 dyne/cm at 25° C.

In the formulation as described herein, the surface tension parameter of the organic solvent should be taken into account when selecting the organic solvent. The suitable surface tension parameters of the ink are suitable for the particular substrate and specific printing method. For example, for inkjet printing, in some embodiments, the surface tension of the organic solvent at 25° C. is in the range of 19 dyne/cm to 50 dyne/cm, further in the range of 22 dyne/cm to 35 dyne/cm, and still further in the range of 25 dyne/cm to 33 dyne/cm.

In some embodiments, the surface tension of the ink as described herein at 25° C. is in the range of 19 dyne/cm to 50 dyne/cm; further in the range of 22 dyne/cm to 35 dyne/cm; and still further in the range of 25 dyne/cm to 33 dyne/cm.

In the formulation as described herein, the viscosity parameters of the ink of the organic solvent should be taken into account when selecting the organic solvent. The viscosity can be adjusted by different methods, such as by the selection of suitable organic solvent and the concentration of functional materials in the ink. In some embodiments, the viscosity of the organic solvent is less than 100 cps, further less than 50 cps, and still further 1.5 to 20 cps. The viscosity herein refers to the viscosity during printing at the ambient temperature that is generally at 15-30° C., further 18-28° C., still further 20-25° C., especially 23-25° C. The formulation thus prepared will be particularly suitable for inkjet printing.

In some embodiments, the formulation as described herein has a viscosity at 25° C. in the range of about 1 cps to 100 cps; especially in the range of 1 cps to 50 cps; and particularly in the range of 1.5 cps to 20 cps.

The ink obtained from the organic solvent satisfying the above-mentioned boiling point parameter, surface tension parameter and viscosity parameter can form a functional material film with uniform thickness and composition property.

Salts are difficult to be purified, and contains impurities, which may often influence the opto-electronic performance of the device. In some embodiments, for the purposes of the present disclosure, the formulation or mixture as described herein does not comprise any salts, and the formulation or mixture preferably does not comprise any organic acid salts formed by organic acids and metals. In terms of cost, the present disclosure preferably excludes organic acid salts with transition metals or lanthanide elements.

In yet another aspect, the present disclosure further provides an organic functional material film comprising an organic compound or a mixture as described above. Preferably, the organic functional material film is made from a formulation as described above.

In yet another aspect, the present disclosure further provides a method for preparing the organic functional material film, as shown in the following steps:

1) Prepare a formulation as described herein.

2) The formulation is coated on a substrate by printing or coating to form a film, the method of printing or coating is selected from the group consisting of inkjet printing, nozzle printing, typographic printing, screen printing, dip coating, spin coating, blade coating, roller printing, torsional roll printing, planographic printing, flexographic printing, rotary printing, spray printing, brush or pad printing, slit die coating.

3) The obtained film is heated at least 50° C., optionally in combination with ultraviolet irradiation, to allow the film to undergo a crosslinking reaction and be cured.

The thickness of the organic functional material film is generally 50 nm-200 m, preferably 100 nm-150 m, more preferably 500 nm-100 m, still more preferably 1 m-50 m, and most preferably 1 m-20 m.

In some embodiments, the organic functional material film has a thickness of 20 nm to 20 m, preferably less than 15 m, more preferably less than 10 m, even more preferably less than 8 m, particularly preferably less than 6 m, further preferably less than 4 m, and most preferably less than 2 m.

In yet another aspect, a further purpose of the present disclosure is to provide uses of the above organic compound and mixture thereof in optoelectronic devices.

In some embodiments, the optoelectronic device may be selected from an organic light emitting diode (OLED), an organic photovoltaic cell (OPV), an organic light emitting electrochemical cell (OLEEC), an organic field effect transistor (OFET), an organic light emitting field effect transistor, an organic laser, an organic spintronic device, an organic sensor, or an organic plasmon emitting diode.

In yet another aspect, the present disclosure further provides an optoelectronic device comprising one of the organic compound, mixture, or an organic functional material film as described above.

In some embodiments, the optoelectronic device can be selected from organic light emitting diode (OLED), organic photovoltaic cell (OPV), organic light emitting electrochemical cell (OLEEC), organic field effect transistor (OFET), organic light emitting field effect transistor, organic laser, organic spintronic device, organic sensor, or organic plasmon emitting diode.

Preferably, the optoelectronic device is an electroluminescent device, such as an organic light emitting diode (OLED), an organic light emitting electrochemical cell (OLEEC), an organic light emitting field effect transistor, a perovskite light emitting diode (PeLED), and a quantum dot light emitting diode (QD-LED), wherein one of the functional layers comprises one of the organic compound or the mixture as described above. The functional layer may be selected from a hole injection layer, a hole transport layer, an electron injection layer, an electron transport layer, a light emitting layer, or a cathode passivation layer (CPL).

In some embodiments, the optoelectronic device is an electroluminescent device, comprising two electrodes, and the functional layer is located on the same side of the two electrodes.

In some embodiments, the optoelectronic device comprises a light emitting unit and a color conversion layer, wherein the color conversion layer comprises one of the organic compound or the mixture as described above.

In some embodiments, the light emitting unit is selected from a solid-state light emitting device. The solid-state light emitting device is preferentially selected from a LED, an organic light emitting diode (OLED), an organic light emitting electrochemical cell (OLEEC), an organic light emitting field effect transistor, a perovskite light emitting diode (PeLED), or a quantum dot light emitting diode (QD-LED).

In some embodiments, the light emitting unit emits blue light, which is converted into green light or red light by the color conversion layer.

In yet another aspect, the present disclosure further provides a display, comprising at least three pixels of red, green and blue, wherein the blue pixel comprises a blue light emitting unit, and the pixel of red and green comprises a blue light emitting unit and a corresponding color conversion layer of red and green.

The present disclosure will be described below in conjunction with the preferred embodiments, but the present disclosure is not limited to the following embodiments. It should be understood that the scope of the present disclosure is covered by the scope of the claims of the present disclosure, and those skilled in the art should understand that certain changes may be made to the embodiments of the present disclosure.

### Specific Embodiment

### Example 1: Synthesis of Compound 1

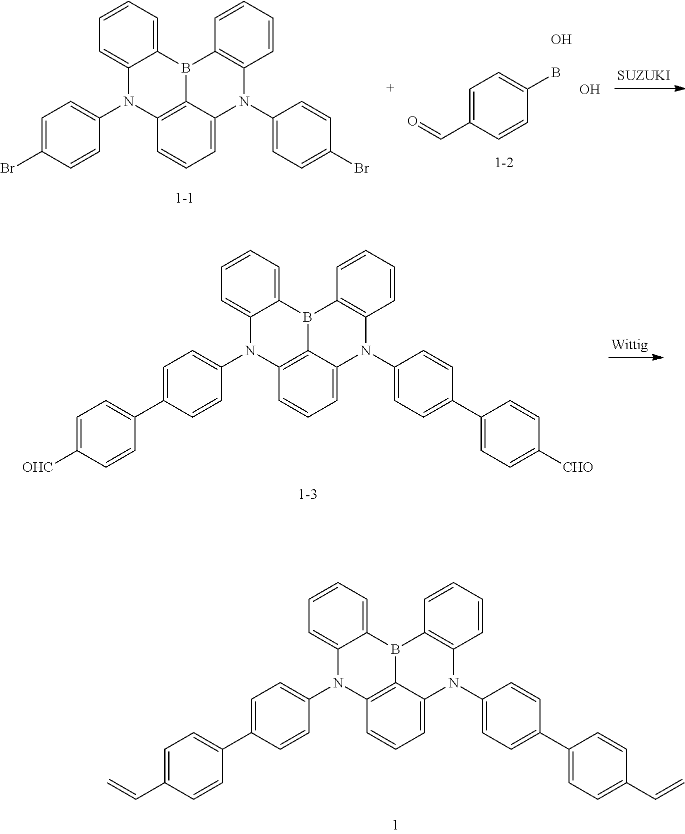

Synthesis of intermediate 1-3 by the classical SUZUKI reaction is as follows: 10.00 mmol of intermediate 1-1, 10.05 mmol of intermediate 1-2, and 20.00 mmol of potassium carbonate were added in turn to a 500 ml three-necked flask under N₂ atmosphere protection, 200 ml of toluene was poured in, and 0.3 mol of catalyst Pd(PPh₃)₄ was added under stirring, then heating reflux reaction, TLC tracking reaction. After the reaction was complete, the reaction solution was cooled to the room temperature, washed with water and dichloromethane each three times.

The organic phases were mixed and anhydrous Na₂SO₄ were added to dry, then filtered, spun off the solvent to obtain the crude product, purified by fast chromatography column to obtain the product 6.87 mmol (yield: 68.7%), and dried in a vacuum environment for use. MS(ASAP)=628.2.

Synthesis of compound 1: 5.0 mmol of compound 1-3 obtained above were dissolved in 200 ml of dry tetrahydrofuran (THF) solution under nitrogen atmosphere protection. The reaction solution was stirred at −78° C. 8.0 mmol of methylene triphenylphosphine (Wittig's reagent) was added dropwise, then gradually heated to room temperature after the addition, and continued to stir at room temperature overnight. Water was added to quench the reaction and the reaction solution was extracted with dichloromethane. The organic phase was washed with water, collected and finally the organic phases were mixed, dried with anhydrous Na₂SO₄, filtered, and evaporated to remove the solvent. The resulting product was purified via slica column chromatography with an eluent of dichloromethane: petroleum ether-1:2, and finally 4.55 mmol of compound 1 was obtained (yield: 91.0%), and further vacuum-dried for use. MS(ASAP)=624.2.

### Example 2: Synthesis of Compound 2

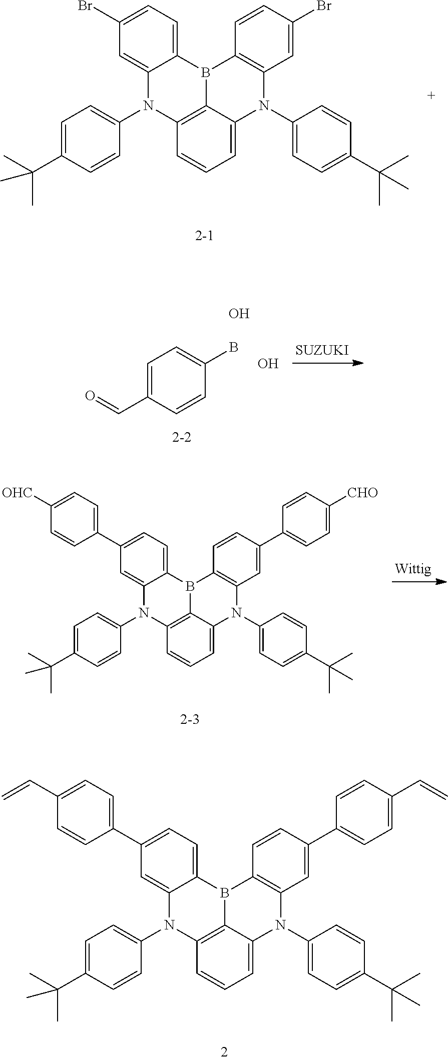

Synthesis of intermediate 2-3: The synthetic method was similar to the synthetic method of intermediate 1-3 in compound 1, using classical SUZUKI reaction, yield: 72.9%. Vacuum-dried for use. MS (ASAP)=740.4.

Synthesis of Compound 2: The synthetic method was similar to the synthetic method of the compound 1, and a WITTIG reagent is used to form a final product (yield: 88.4%), dried in a vacuum environment for use. MS(ASAP)=746.4.

### Example 3: Synthesis of Compound 3

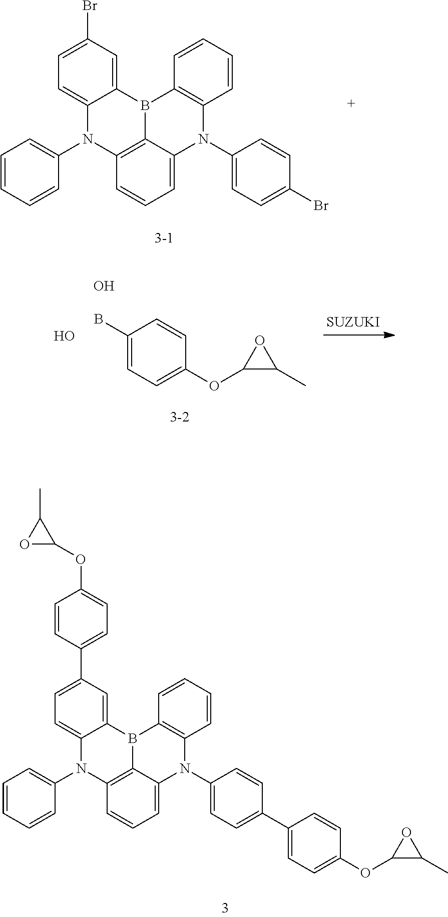

Synthesis of Compound 3: The synthetic method was similar to the synthetic method of intermediate 1-3 in the compound 1, using classical SUZUKI reaction, yield: 81.3%. MS(ASAP)=716.3.

### Example 4: Synthesis of Compound 4

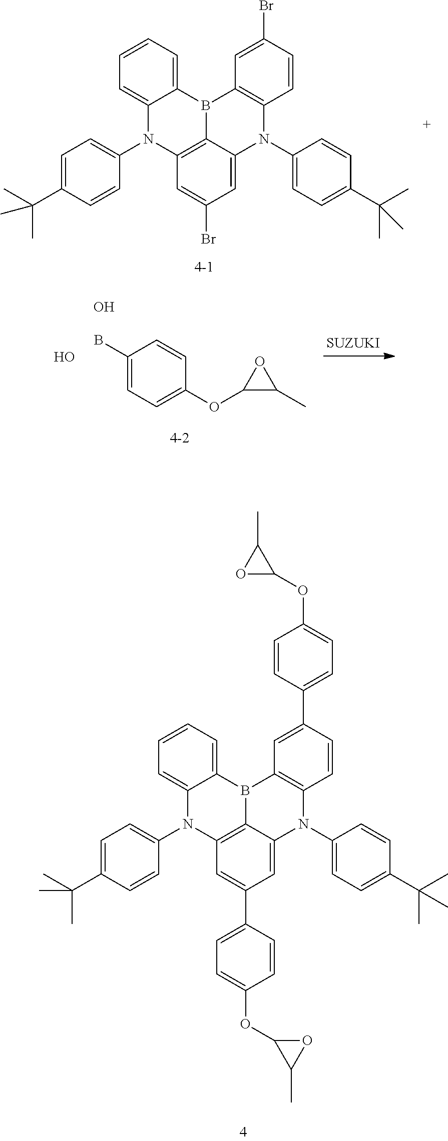

Synthesis of Compound 4: The synthetic method was similar to the synthetic method of intermediate 1-3 in the compound 1, using classical SUZUKI reaction, yield: 82.5%. MS(ASAP)=828.3.

### Example 5: Synthesis of Compound 5

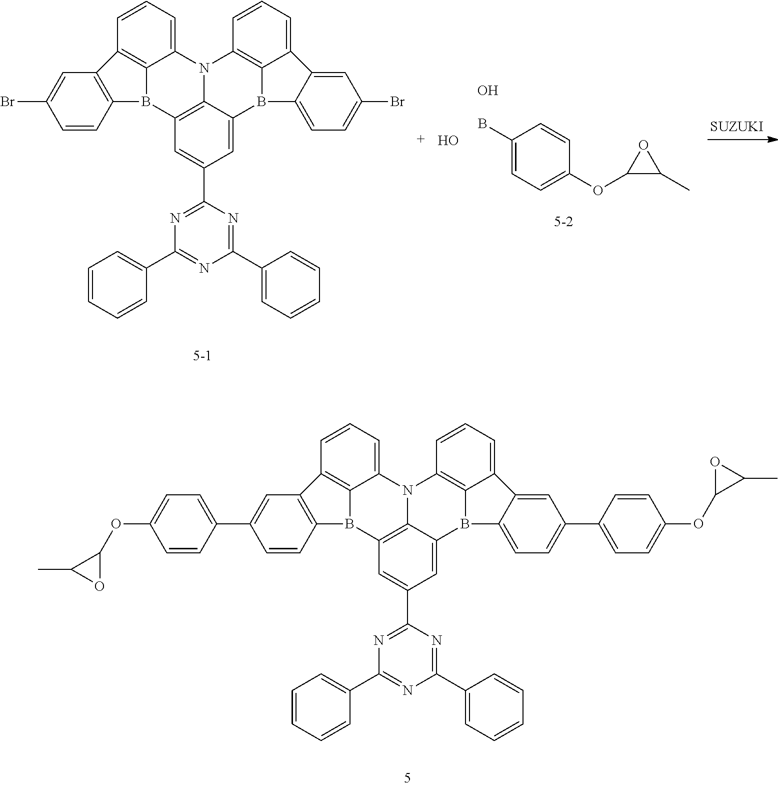

Synthesis of Compound 5: The synthetic method was similar to the synthetic method of intermediate 1-3 in the compound 1, using classical SUZUKI reaction, yield: 76.4%. MS(ASAP)=940.3.

### Example 6: Synthesis of Compound 6

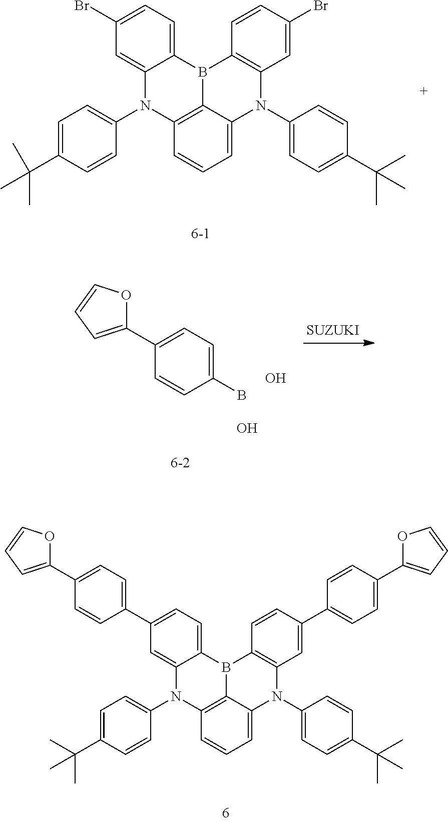

Synthesis of Compound 6: The synthetic method was similar to the synthetic method of intermediate 1-3 in the compound 1, using classical SUZUKI reaction, yield: 80.2%. MS(ASAP)=816.4.

### Example 7: Synthesis of Compound 7

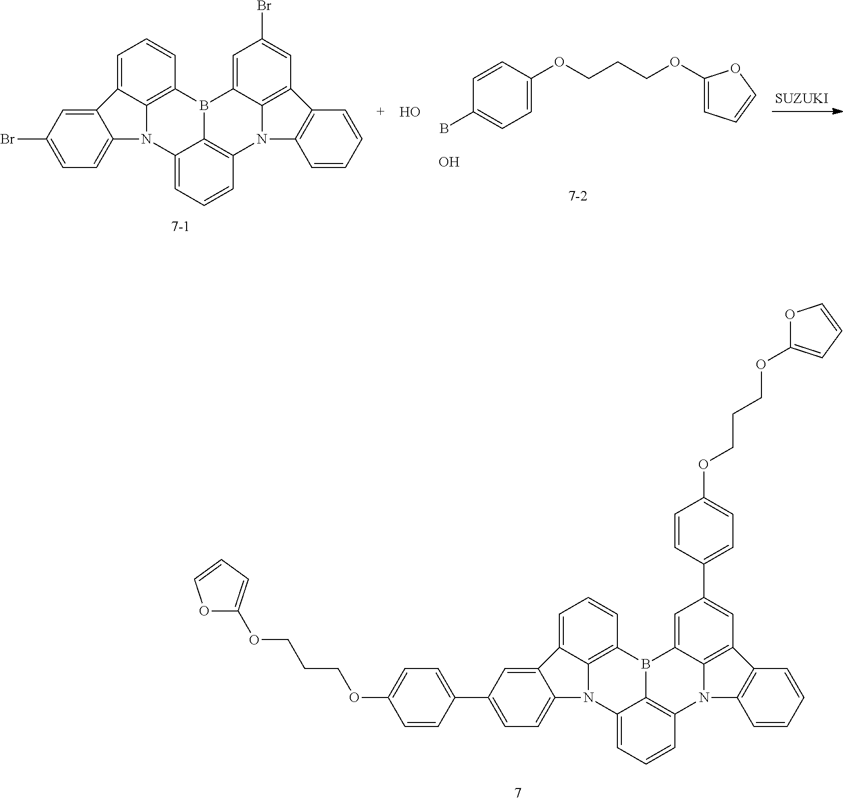

Synthesis of Compound 7: The synthetic method was similar to the synthetic method of intermediate 1-3 in the compound 1, using classical SUZUKI reaction, yield: 82.1%. MS(ASAP)=848.3.

### Example 8: Synthesis of Compound 8

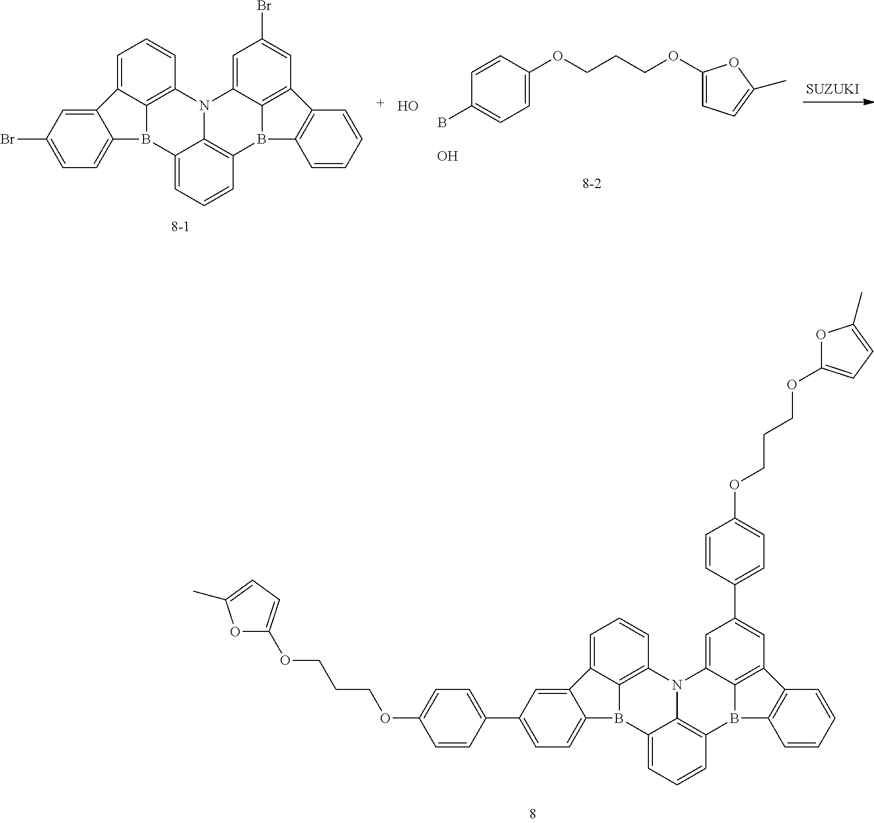

Synthesis of Compound 8: The synthetic method was similar to the synthetic method of intermediate 1-3 in the compound 1, using classical SUZUKI reaction, yield: 88.6%. MS(ASAP)=873.3.

### Example 9: Synthesis of Compound 9

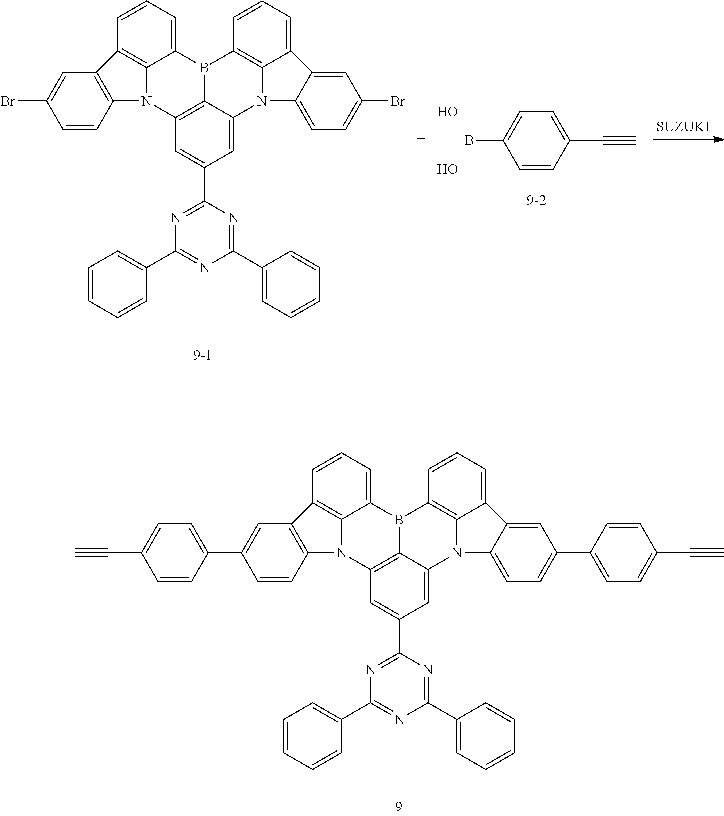

Synthesis of Compound 9: The synthetic method was similar to the synthetic method of intermediate 1-3 in the compound 1, using classical SUZUKI reaction, yield: 85.4%. MS(ASAP)=847.3.

### Example 10: Synthesis of Compound 10

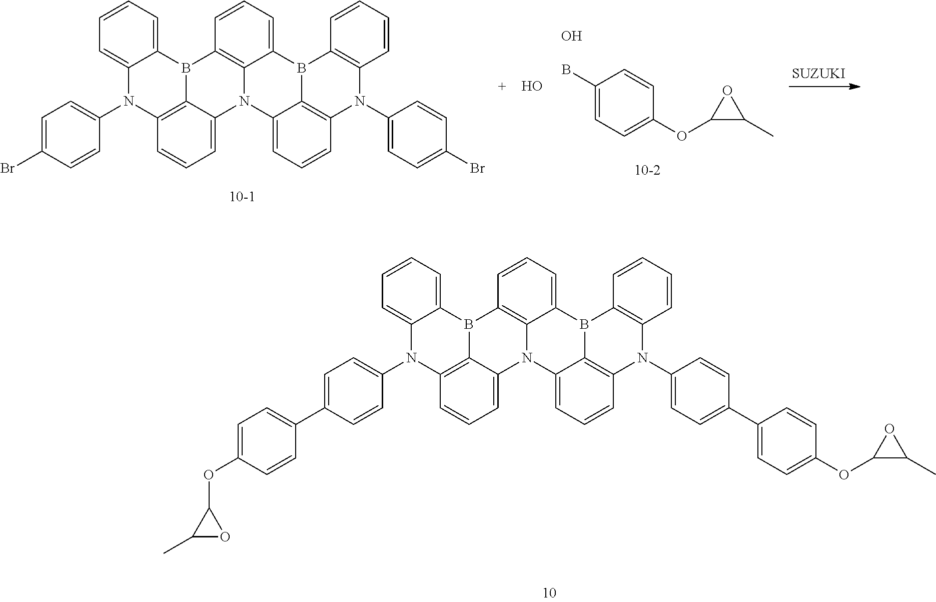

Synthesis of Compound 10: The synthetic method was similar to the synthetic method of intermediates 1-3 in the compound 1, using classical SUZUKI reaction, yield: 88.2%. MS(ASAP)=891.3.

### Example 11: Synthesis of Compound 11

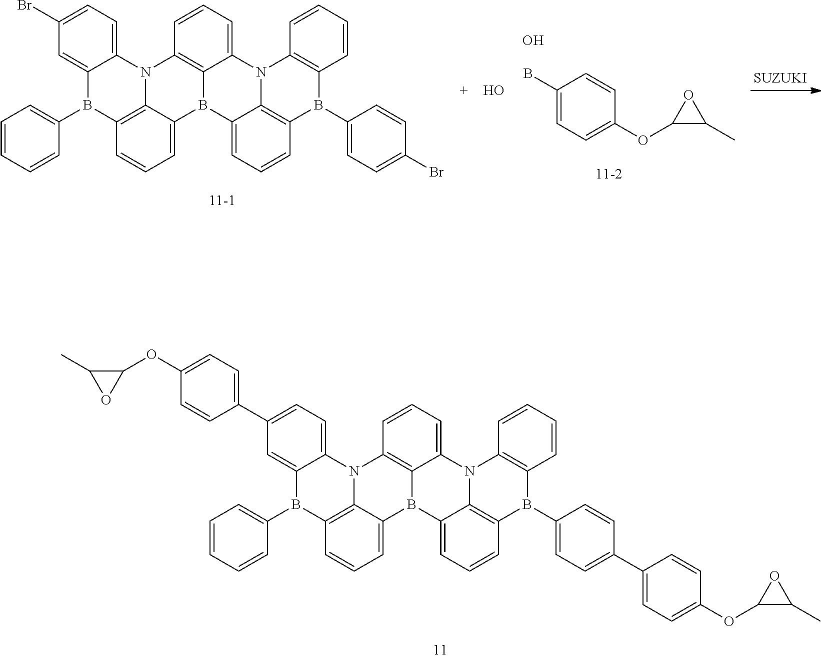

Synthesis of Compound 11: The synthetic method was similar to the synthetic method of intermediate 1-3 in the compound 1, using classical SUZUKI reaction, yield: 85.1%. MS(ASAP)=888.4.

### Example 12: Synthesis of Compound 12

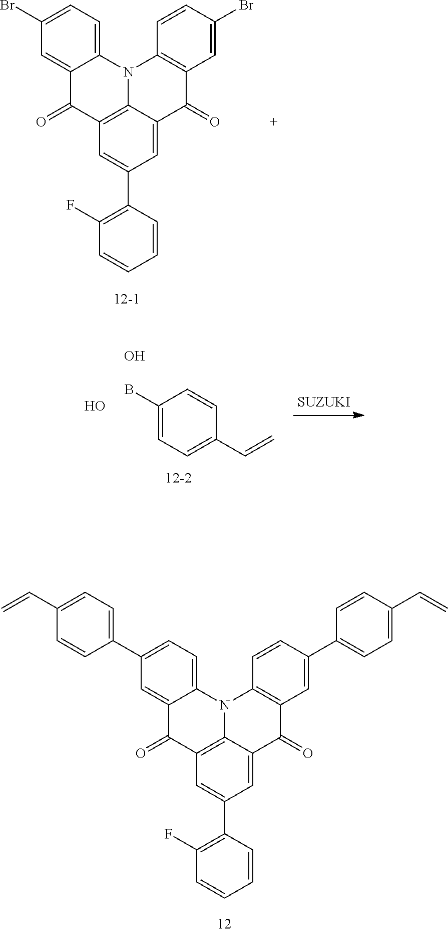

Synthesis of Compound 12: The synthetic method was similar to the synthetic method of intermediate 1-3 in the compound 1, using classical SUZUKI reaction, yield: 76.5%. MS(ASAP)=595.2.

The method for preparing the color conversion layer

The blue color conversion material, green color conversion material and red color conversion material as described above were dissolved in a mixture solvent of tetrahydronaphthalene: toluene=3:2 in the ratio of 50 mg/ml, 50 mg/ml, and 50 mg/ml respectively. At the same time, 15 mg/ml of the polystyrene, 5 mg/ml of silicon dioxide nanospheres of 3-5 m in diameter were added to the solution to form the ink. Through slit coating using the ink, a film with a thickness of about 100 m was formed on the surface of the electroluminescent device or a thin film as a color conversion layer for red, green and blue colors. The OD (optical density) of the above obtained color conversion layers are all greater than 4. The combination of blue or near-ultraviolet light-emitting sources can be fully converted the blue or near-ultraviolet light to green or red light.

The blue color conversion material, green color conversion material and red color conversion material as described above were dissolved in a mixture solvent of tetrahydronaphthalene: toluene=3:2 in the ratio of 50 mg/ml, 50 mg/ml, and 50 mg/ml respectively. A film was formed by blade or spin coating, and was baked on a hot plate at 100° C. for 10 minutes, while cross-linked with 365 nm UV light for 1-3 minutes, so that a color conversion film of 100-500 nm can be obtained.

A compound with only one cross-linkable group were also synthesized in the present disclosure, according to the above method to prepare the color conversion layer.

The resulting film cannot be completely cross-linked to form a cured film.

In addition, it is also found in the present disclosure that, compared with a corresponding compound without a cross-linkable group, the compound as described herein, i. e., a compound with one or more cross-linkable groups are better mixed with a prepolymer of a resin, and has better solubility and film-forming property, thus allowing higher quality films.

The technical features of the above-described embodiments can be combined in any ways. For the sake of brevity, not all possible combinations of the technical features of the above-described embodiments have been described. However, as long as there are no contradictions in the combination of these technical features, they should be considered to be within the scope of this specification.

What described above are several embodiments of the present disclosure, and they are specific and in details, but not intended to limit the scope of the present disclosure. It will be understood that improvements can be made without departing from the concept of the present disclosure, and all these modifications and improvements are within the scope of the present disclosure. The scope of the present disclosure shall be subject to the appended claims.

What is claimed is:

1. An organic compound, comprising a structural unit of formula (1) or (2), 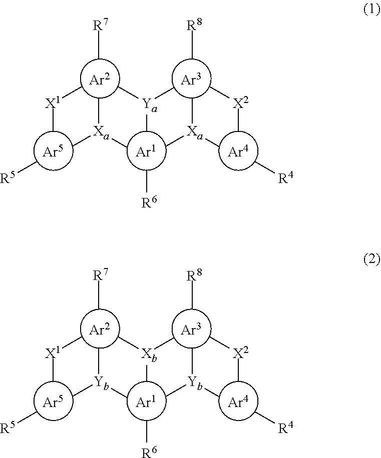
wherein:
each of Ar¹, Ar², Ar³ is independently an aromatic group containing 5 to 24 ring atoms, or a heteroaromatic group containing 5 to 24 ring atoms;
each of Ar⁴ and Ar⁵ is independently null, an aromatic group containing 5 to 24 ring atoms, or a heteroaromatic group containing 5 to 24 ring atoms;
each of Yₐ and Y_{b} is independently B, P═O, C(R⁹), Si(R⁹);
when neither Ar⁴ nor Ar⁵ is null, each of Xₐ and X_{b} is independently N, C(R⁹), Si(R⁹);
when Ar⁴ and/or Ar⁵ is null, each of the corresponding Xₐ and Y_{b} is independently N(R⁹), C(R⁹R¹⁰), Si(R⁹R¹⁰), C═O, O, C═N(R⁹), C═C(R⁹R¹⁰), P(R⁹), P(═O)R⁹, S, S═O, or SO₂;
each of X¹, X² is independently null or a bridging group;
R⁴ to R¹⁰ are each independently selected from the group consisting of —H, -D, —F, —Cl, —Br, —I, —CN, —NO₂, —CF₃, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, a trifluoromethyl group, Cl, Br, F, a substituted/unsubstituted aromatic/heteroaromatic group containing 5 to 40 ring atoms, an aryloxy/heteroaryloxy group containing 5 to 40 ring atoms, an arylamine/heteroarylamine group containing 5 to 40 ring atoms, a disubstituted unit in any position of the above substituents and any combination thereof, wherein one or more of the substituent groups can form a monocyclic or polycyclic aliphatic or aromatic ring system with each other and/or with the ring bonded to the groups;
wherein the organic compound comprises at least one cross-linkable group.

2. The organic compound of claim 1, comprising a structural unit of formula (1a) or (2a):

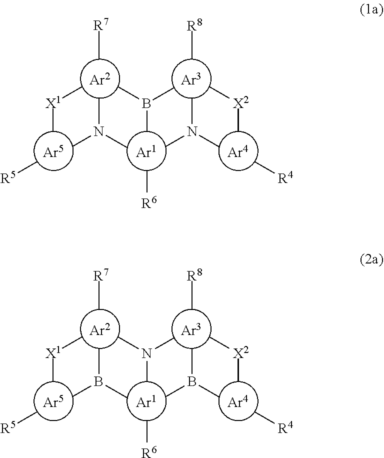

3. The organic compound of claim 1, wherein the compound comprises a structural unit represented by one of the following formulas (1b)-(1e), (2b)-(2e):

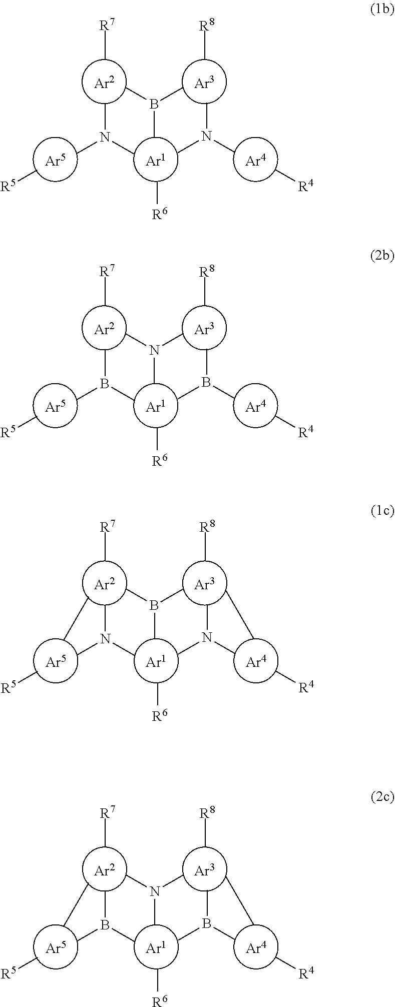

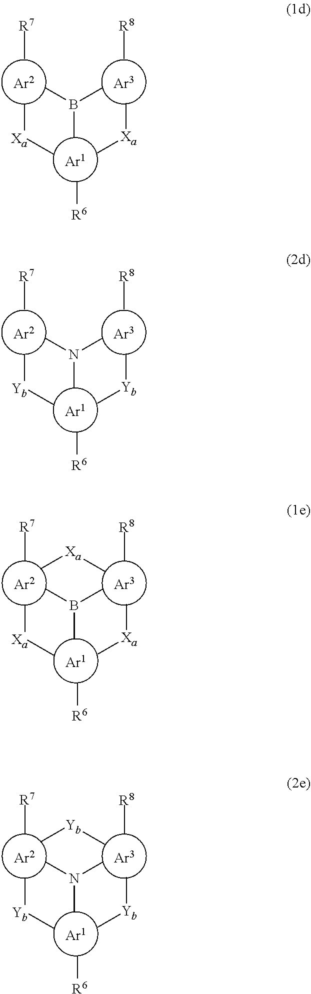

4. The organic compound of claim 1, wherein the cross-linkable group is selected from the group consisting of: 1) linear/cyclic alkenyl, linear dienyl, linear alkynyl; 2) enoxy, dienoxy; 3) acrylic; 4) propylene oxide, ethylene Oxideoxide; 5) silanyl; 6) cyclobutanyl.

5. The organic compound of claim 1, the at least one cross-linkable group is selected from the group consisting of: 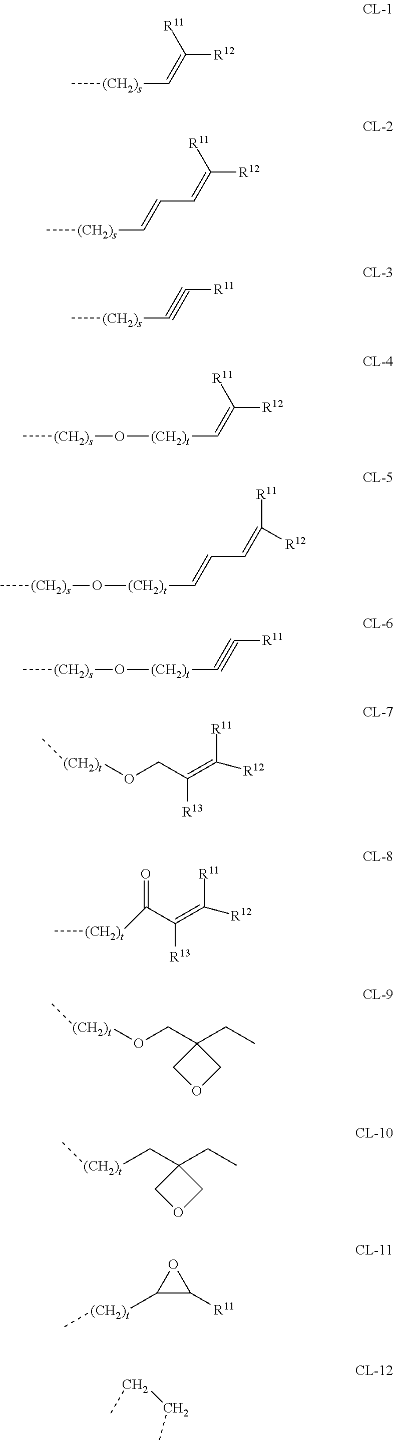 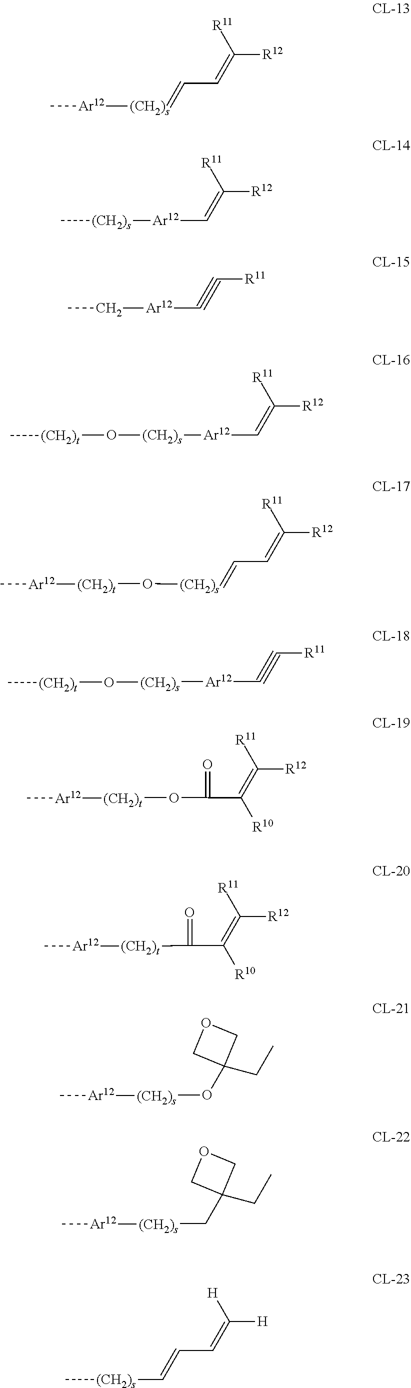 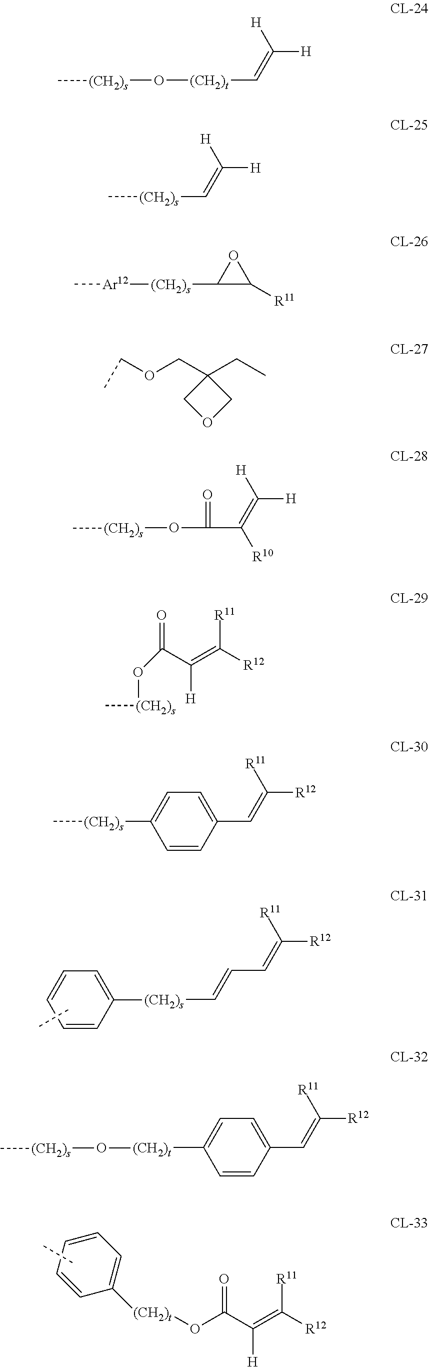 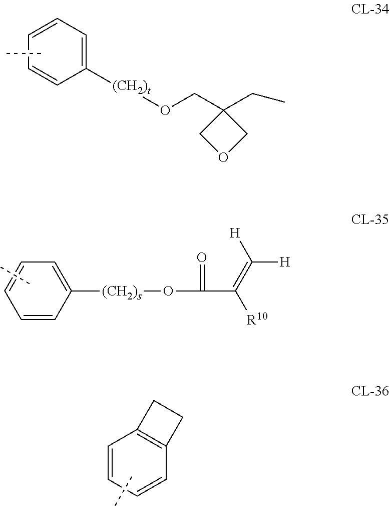
wherein each of s, t is an integer greater than 0; the dotted line represents a boned bond, R¹⁰ to R¹³ are identically defined as R⁴ in claim 1, and Ar¹² is defined as Ar¹ in claim 1.

6. The organic compound of claim 1, wherein each of Ar¹, Ar², Ar³, Ar⁴, and Ar⁵ in the formula (1) or (2) is each independently selected from one of the following structural formulas or any combination thereof:

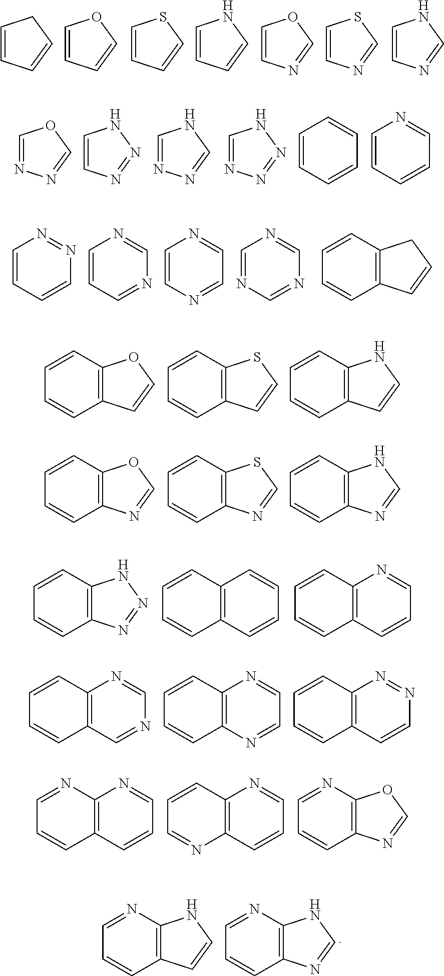

7. A formulation, comprising at least one organic compound according to claim 1, and at least one organic solvent.

8. A formulation, comprising at least one organic compound according to claim 2, and at least one organic solvent.

9. A formulation, comprising at least one organic compound according to claim 3, and at least one organic solvent.

10. A formulation, comprising at least one organic compound according to claim 4, and at least one organic solvent.

11. A formulation, comprising at least one organic compound according to claim 5, and at least one organic solvent.

12. A formulation, comprising at least one organic compound according to claim 6, and at least one organic solvent.

13. The formulation of claim 7, wherein the organic solvent is selected from the group consisting of aromatics, heteroaromatics, esters, aromatic ketones, aromatic ethers, aliphatic ketones, aliphatic ethers, alicyclics, olefins, inorganic ester compounds such as boronic esters and phosphoric esters, and mixtures of two or more thereof.

14. An organic functional material film, comprising the organic compound according to claim 1.

15. An organic functional material film prepared using the formulation according to claim 7.

16. An optoelectronic device, comprising the organic compound according to claim 1.

17. An optoelectronic device, comprising the organic functional material film according to claim 14.

18. An optoelectronic device, comprising the organic functional material film according to claim 15.
